(19) United States
(12) Patent Application Publication
(10) Pub. No.: US 2026/0150488 A1
(43) Pub. Date: May 28, 2026

(54) INDACENE AND AZAINDACENE COMPOUNDS AND HIGHER HOMOLOGUES AND THE USE THEREOF

(71) Applicant: CREDOXYS GMBH, Dresden (DE)

(72) Inventors: Sascha Dorok, Dresden (DE); Marcus Papmeyer, Nossen (DE); Arno Schneeweis, Dortmund (DE)

(21) Appl. No.: 19/123,419

(22) PCT Filed: Oct. 27, 2023
(86) PCT No.: PCT/EP2023/080103

§ 371 Date: Apr. 23, 2025

(30) Foreign Application Priority Data
Oct. 31, 2022 (EP) 22204731.8

(51) Int. Cl. H10K 50/12; H10K 85/20; H10K 85/30; H10K 85/60

(52) U.S. Cl. CPC H10K 50/12; H10K 85/211; H10K 85/381; H10K 85/626; H10K 85/633; H10K 85/636; H10K 85/654; H10K 85/655; H10K 85/656; H10K 85/6572; H10K 85/6576

(57) ABSTRACT

The present invention relates to compounds of formula (I) as well as to their use as organic doping agent, as transport layer as absorbing layer, as charge injection layer, as organic semiconductor itself, organic semiconductive matrix material or as hole transport layer. The invention also relates to organic semiconductive materials, electronic components, organic field-effect transistor, semiconductor unit and electroluminescent arrangement in which the compounds of formula (I) are used.

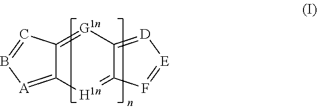

The present invention relates to compounds of formula (I) as well as to their use as organic doping agent, as transport layer as absorbing layer, as charge injection layer, as organic semiconductor itself, organic semiconductive matrix material or as hole transport layer. The invention also relates to to organic semiconductive materials, electronic components, organic field-effect transistor, semiconductor unit and electroluminescent arrangement in which the compounds of formula (I) are used.

### BACKGROUND OF THE INVENTION

Organic electronics focuses on the development, characterization and application of new materials, both based on small organic molecules and polymers with certain desired electronic properties for the production of electronic components. These comprise e.g. organic field effect transistors (OFETs) such as organic thin film transistors (OTFTs), organic electroluminescent devices such as organic light emitting diodes (OLEDs), organic solar cells (OSCs), e.g. exciton solar cells, dye-sensitized solar cells (DSSCs) or perovskite solar cells, electrophotography, e.g. photoconductive materials in organic photoconductors (OPCs), organic optical detectors, organic photoreceptors, light-emitting electrochemical cells (LECs) and organic laser diodes.

It is known that organic semiconductor matrices can be heavily influenced regarding their electrical conductivity by doping. Such organic semiconductive matrix materials can be formed by either from compounds with good electron donor properties (p-conductor) or from compounds with good electron acceptor properties (n-conductor). In contrast to inorganic semiconductors, organic semiconductors have a very low intrinsic charge carrier concentration. Organic semi-conductor matrix materials are therefore usually doped in order to achieve good semiconductor properties. For n-doping strong electron donors (n dopants) are used, which transfer an electron to the LUMO of the semiconductor matrix (n-doping), resulting in a free electron on the matrix (SOMO). For p-doping strong electron acceptors (p-dopants) are used, which remove an electron from the HOMO of the semiconductor matrix (p-doping), resulting in a hole. In other words, for p-doping the LUMO of the dopant must be below the HOMO-energy of the matrix. The dopant acts as an acceptor and leaves a mobile hole (SOMO) in the matrix.

H. Hopf, Angew. Chem. (2013), 125, 12446-12449 describes in very general terms the applicability of pentalenes as components for new electronic materials. In particular unsymmetric Benzopentalenes are mentioned for their redox properties and a low HOMO/LUMO gap.

Whereas the non-alternating 8π-electron hydrocarbon system of the unsubstituted pentalene has only a low delocalization energy, a combination of donor and acceptor substituents can lead to a delocalization of the double bonds similar to benzene. In the sense of the present application the formulae of the pentalene compounds depict only one resonance structure (Lewis structure), but shall encompass all the canonical forms (so-called resonance hybrids).

LeGoff described in Tedrahedon Letters (1964), 19, 1161-1164 discloses stable derivatives of pseudoaromatic s-indacens. Hafner et al. describes in Angew. Chem. (1986), 98, 646-648 synthesis and properties of 1,3,5,7-tetra-tert-buryl-s-indacene. Closs et al. describes in Angew. Chem. Int. Ed (1987), 10, 1037-1039 the synthesis of 2,6-diaza-s-indacenes. In particular, Closs et al., discloses 1,3,5,7-tetrakis(diethylamino)-2,6-diaza-s-indacene (compound 5), compound 4 and compound 7. The latter two compounds (4 and 7) are not encompassed by the present invention.

Bird et al, Tetrahedron 54 (1998) 10179-10189 reports on calculations of theoretical polycyclic aromatic systems. A synthetic route is not described. Furthermore, there are no hints whether the calculated structures can be synthesized. It is unclear whether the mentioned compounds just fragments or adducts, since there is no bonds between the radicals and the the main skeleton. Bonds are shown as a line that connects one atom to another.

It has been known for several years that organic semiconductors can be heavily influenced regarding their electrical conductivity by doping. Such organic semi-conductive matrix materials can be built up either from compounds with good electron donor properties or from compounds with good electron acceptor properties. Strong electron acceptors such as tetracyanoquinonedimethane (TCNQ) or 2,3,5,6-tetrafluoro-tetracyano-1,4-benzoquinonedimethane (F4TCNQ) have become known for the doping of electron donor materials (hole transport materials=HTM). The acceptor molecules generate so-called holes by electron transfer processes in electron donor-like base materials (HTM) and the conductivity of the base material is more or less significantly changed depending on the number and mobility of the holes. For example, N,N′-perarylated benzidines such as TPD or N,N′,N″-perarylated starburst compounds such as the substance TDATA, or, however, also certain metal phthalocyanines, such as in particular zinc phthalocyanine ZnPc are known as matrix material with hole transport properties. Such kind of electron acceptor compounds are e.g. described in EP2180029 A1, which regards the use of radialene compounds as doping agents for an organic semiconductive matrix material.

On the other hand, strong electron donor compounds have become known for the doping of electron acceptor compounds, mainly for electron transport materials (electron transport materials=ETM). The donor molecules generate negative charge carriers by electron transfer processes in electron acceptor-like host materials (ETM) and the conductivity of the host material is more or less significantly changed depending on the number and mobility of the negative charge carriers. For example, the widely used fullerene-type electron transport materials (e.g. C60, C70) can be doped as e.g. described in EP2963010 or EP3667752, which makes use of compounds ABₓ, wherein A is a structural moiety that comprises a conjugated system of delocalized electrons and each B is selected from imine functional groups, wherein the nitrogen atom is bound via a double bond to a quaternary carbon atom or a cyclopropylidene moiety. Thereby significantly improve the efficiency of an organic electronic device, such as an organic solar cell or an organic photovoltaic device is in general significantly improved.

WO 2012/031735 A1 describes the use of Truxequinone derivatives of the formula (B)

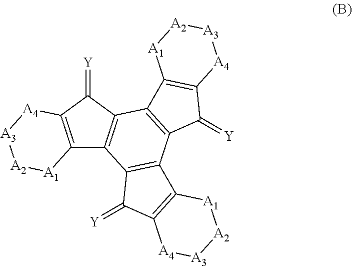

as acceptors, electron transport material and doped electron transport material in organic solar cells.

WO 2012/168358A1 describes NTCDI-derivatives (NTCDI=Naphthaline dicarboxylic acid diimides) as acceptors, electron transport material and doped electron transport material in organic solar cells.

EP 2765832 A1 describes dibenzopentalene compounds of the formula (C)

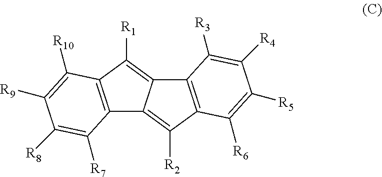

wherein
R₁ and R₂ can be selected from a plethora of different substituents and R₃ to R₁₀ are each independently selected from hydrogen or a monovalent organic substituent. Those compounds can be used as a hole injection material, a hole transfer material, a light emitting material, an electron transfer material or an electron injection material in an organic light emitting device. In particular, the compounds may be used as a light emitting material. This documents does not disclose dibenzopentalene compounds, wherein all the hydrogen atoms of the annelated benzene rings are substituted with electron acceptor groups.

Bradley et al., Chem. Phys. Letters (2014), 616, 137-141, as well as Moroni et al., J. Mol. Structure (2004), 677, 1-5, describe inter alia 1,3,5,7-tetra-tert-butyl-indacene (TTBI, see compound 4). In Bradley et al., it is described that said compounds may be useful organic electronics, in particular OPCs and OFETs.

Hafner et al., Angew. Chem. Int. Ed. 1995, 34, 330, discloses 4-aza-s-indacene an 4-phospha-s-indacene.

Makino et al., Phys. Chem, Chem, Phys, (2008), 10, 591-599, relates to a theoretical study regarding aromaticity and magnetotropicity of diclopenta-fused polyacenes.

The following indacene compounds are known

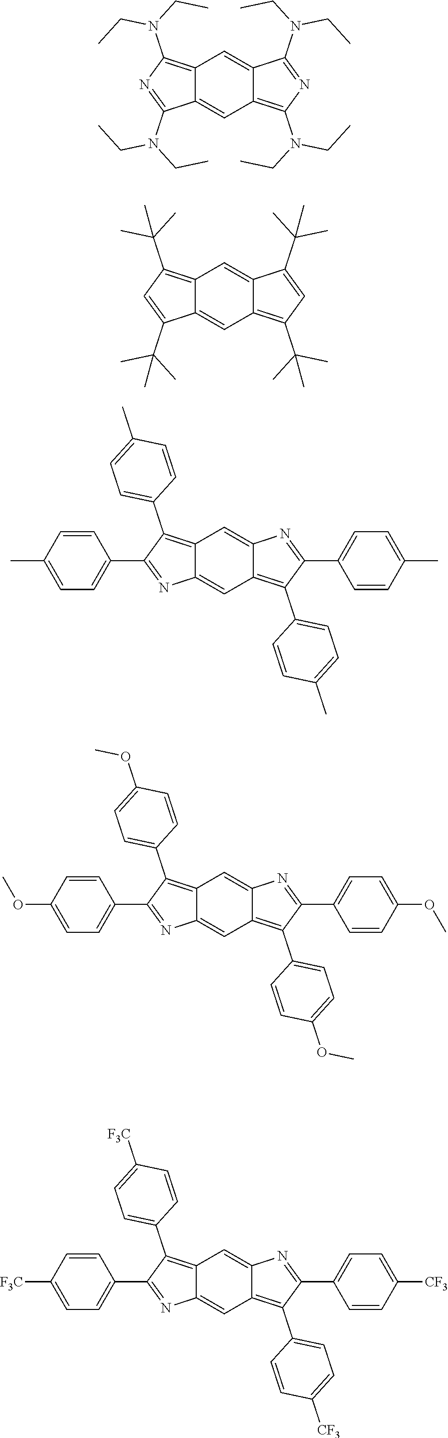

Angew. Chem. Int. Ed. 26 (1987), 10, 1037-1039. (1,3,5,7-Tetra(diethylamino)-2,6-diazaindacene)

Angew. Chem. 98 (1986), 7, 646-648. (1,3,5,7-Tetra(t-Butyl) indacene) Angew. Chem. Int. Ed. (2021), 60 (38), 20765-20770. (2,5-Diazaindacenes)

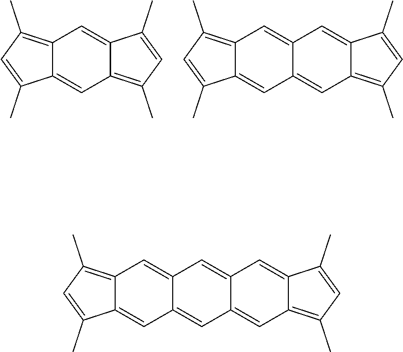

Chemical Physics Letter (2012), 545, 88-94.

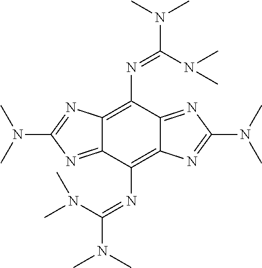

Angew. Chem. Int. Ed. 2017, 56, 3360

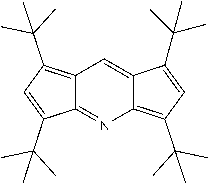 [SMILES: CC(C)(C)C1=CC(C(C)(C)C)=c2cc3c(nc21)=C(C(C)(C)C)C=C3C(C)(C)C]

Angew. Chem. Int. Ed. 1995, 34, 330.

However, the previously described compounds have disadvantages for a technical use in the production of doped semi-conductive organic layers or of corresponding electronic components with such doped layers since the manufacturing processes in large-scale production plants or those on a technical scale cannot always be sufficiently precise, which results in high control- and regulating expense within the processes for achieving a desired product quality or in undesired tolerances of the products. Furthermore, there are disadvantages in the use of previously known organic acceptors with regard to electronic components such as light-emitting diodes (OLEDs), field effect transistors (FET) or solar cells themselves since the cited production difficulties in the handling of the doping agents can lead to undesired irregularities in the electronic components or in undesired ageing effects of the electronic components. However, it should be considered at the same time that the doping agents to be used have extremely high electron affinities (reduction potentials) or electron donor 20 capabilities (oxidation potentials) and other properties suitable for the application case since, e.g., the doping agents also co-determine the conductivity or other electrical properties of the organic semi-conductive layer under given conditions. The energetic positions of the HOMO (highest occupied molecular orbital) of the matrix material and of the LUMO (lowest unoccupied molecular orbital) of the doping agent or vice versa are very decisive for the doping effect.

It is an object of the present invention to overcome the disadvantages of the state of the art, in particular to make new organic mesomeric compounds available that can be used in particular as doping agent for the doping of organic semiconductors, that can furthermore be more readily handled in the production process and that result in electronic components whose organic semi-conductive materials can be reproducibly manufactured. Furthermore, the present invention is providing a versatile structure class that allows the design of both electron acceptor compounds and electron donor compounds by tethering different types of substituents. On the one side, hole transport materials with a deep HOMO shall be dopable by the new organic mesomeric compounds. On the other side, electron transport materials, mainly used in organic photovoltaic devices (OPV) shell become better dopable.

This object is solved by the independent claims of the present application. Preferred embodiments are disclosed in the subclaims.

### SUMMARY OF THE INVENTION

A first object of the invention is an electronic component comprising at least one compound of the formula (I):

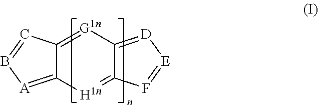

or their radical anions, radical anionic salts, radical cations, radical cationic salts, dianions, dianionic salts, dications, dicationic salts or their charge transfer complexes with donors or acceptors,
in which
n is 1, 2, 3
A is nitrogen or C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—R¹ⁿ,
each H¹ⁿ is nitrogen or C—R²ⁿ,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹, R¹², R¹³, R²¹, R²² and R²³ independently selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, Anisyl, Mesityl,
or R^{E} and R^{F} or R^{E} and R^{F} bound to the same or to different nitrogen atoms form a C₃-C₁₀ heterocycloalkyl.

In particular, an object of the invention is an electronic component comprising at least one compound of the formula (I):

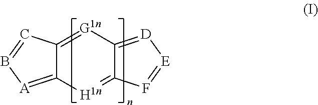

or their radical anions, radical anionic salts, radical cations, radical cationic salts, dianions, dianionic salts, dications, dicationic salts or their charge transfer complexes with donors or acceptors,
in which
n is 1, 2, 3
A is nitrogen or C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—Rin,
each H¹ⁿ is nitrogen or C—R²ⁿ,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹, R¹², R¹³, R²¹, R²² and R²³ independently selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyt, anisyl, mesityl,
wherein R^{F} is selected from C₁-C₁₀-alkyl, phenyl, tolyl, Anisyl, Mesityl,
or R^{E} and R^{F} or R^{E} and R^{F} bound to the same or to different nitrogen atoms form a C₃-C₁₀ heterocycloalkyl,
with the proviso that

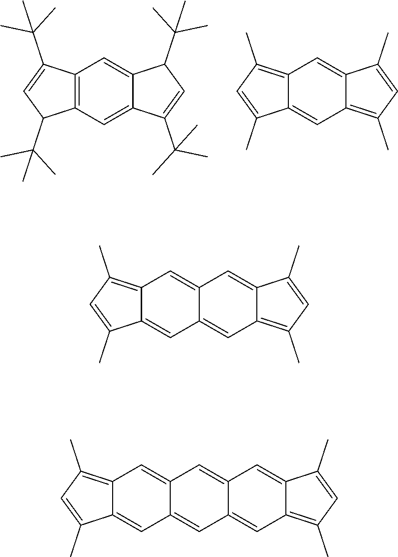

are excluded.

Further, in particular the following compounds are also excluded:

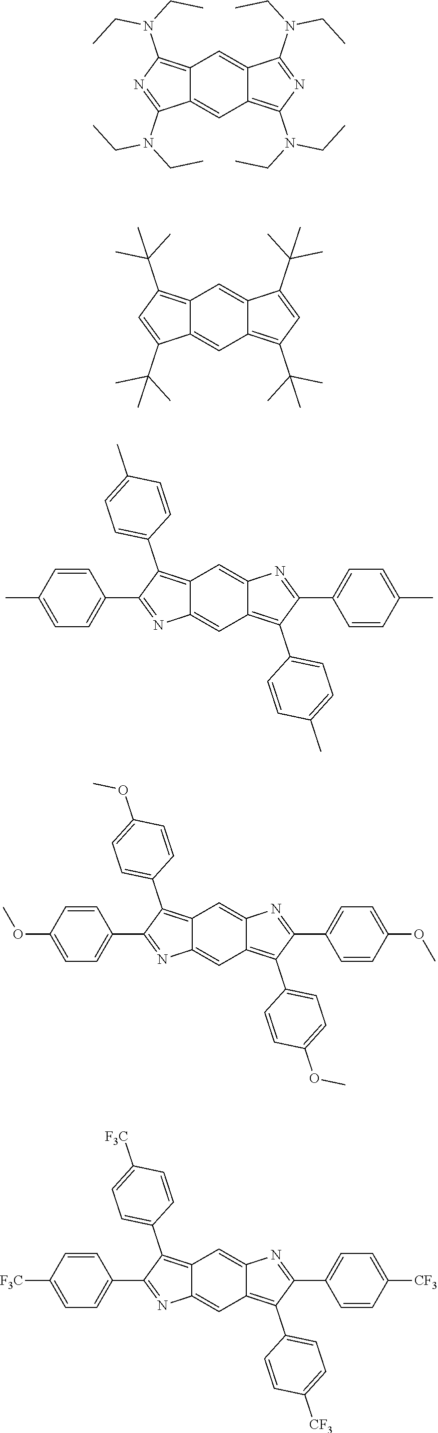

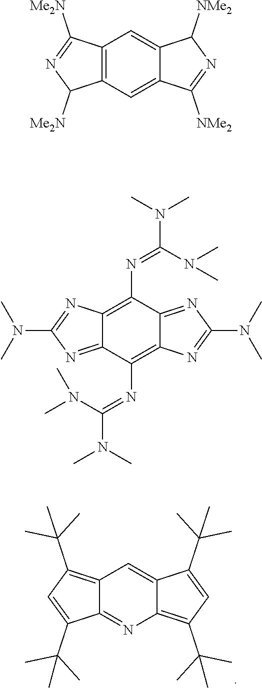

A further object of the invention is a compound of the formula (I),

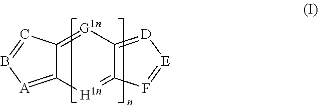

or their radical anions, radical anionic salts, radical cations, radical cationic salts, dianions, dianionic salts, dications, dicationic salts or their charge transfer complexes with donors or acceptors
in which
n is 1, 2, 3
A is nitrogen or C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—R¹ⁿ,
each H¹ⁿ is nitrogen or C—R²ⁿ,
wherein 0, 1, 2, 3 or 4 non-adjacent groups A, B, C, D, E or F are a nitrogen atom,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹, R¹², R¹³, R²¹, R²² and R²³ independently selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, anisyl, mesityl,
or R^{E} and R^{F} or R^{E} and R^{F} bound to the same or to different nitrogen atoms form a C₃-C₁₀ heterocycloalkyl,
with the proviso that

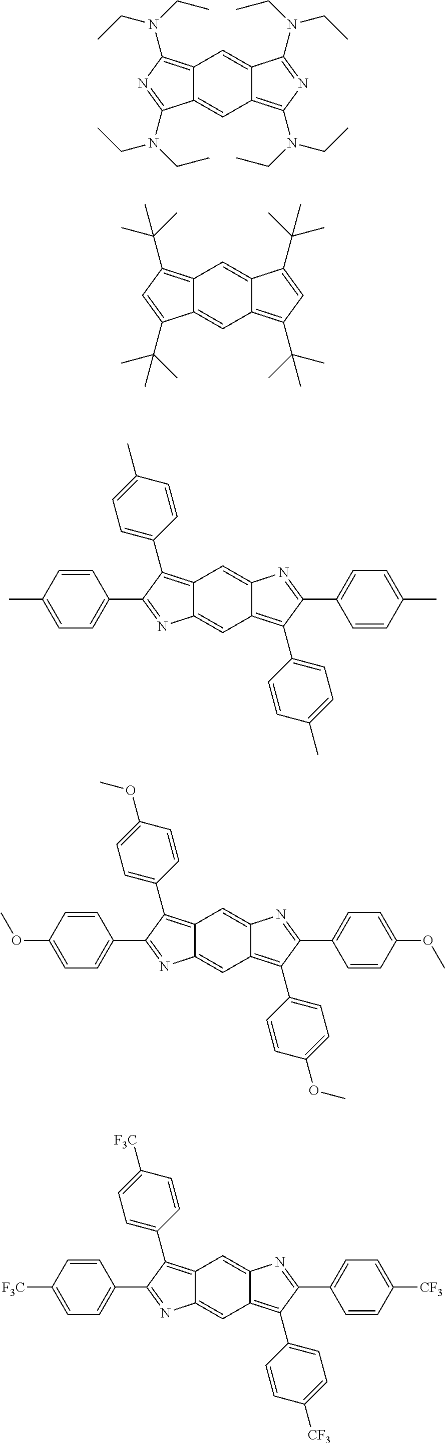

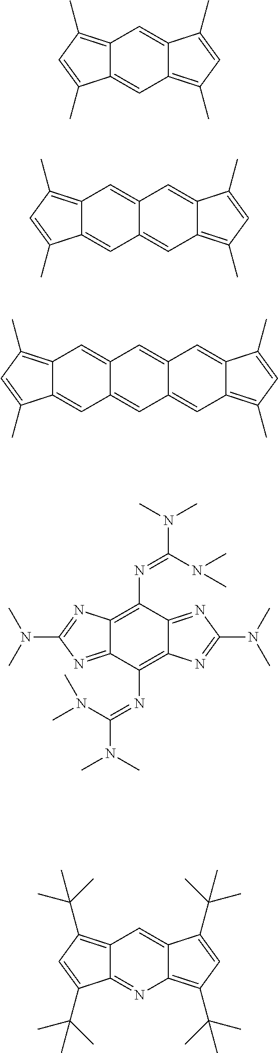

are excluded.

Further, in particular, the following compound is also excluded

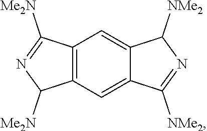 [SMILES: CN(C)C1=NC(N(C)C)c2cc3c(cc21)C(N(C)C)N=C3N(C)C]

A further object of the invention is Organic semiconductive material containing at least one organic matrix compound and at least one doping agent, characterized in that the doping agent is one or more compounds of formula (I), preferably compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37) and (I.38) and (I.39) as defined above or below.

In particular the compounds

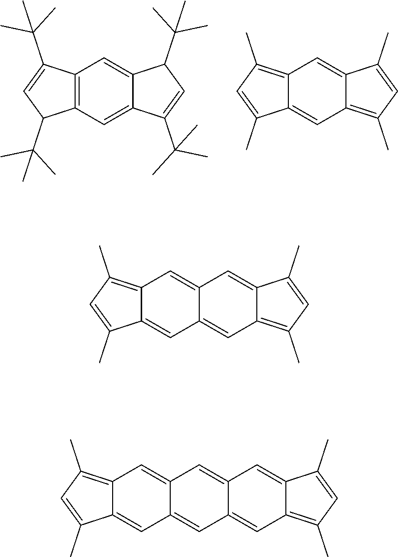

are excluded.

Further, in particular the following compounds are also excluded:

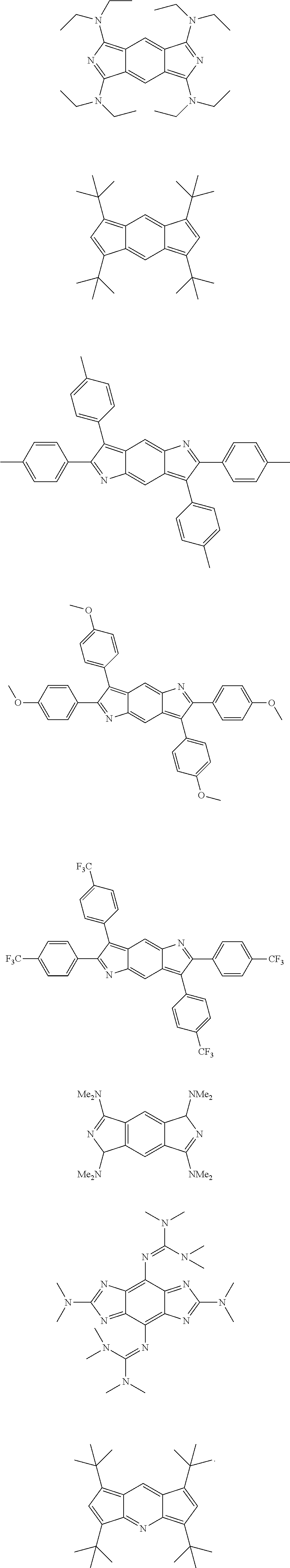

A further object of the invention is an organic semiconductive material containing at least one organic matrix compound and at least one doping agent, characterized in that the matrix compound is one or more compounds of formula (I), preferably compounds of formulae (I.1), (I.2), (I.3), (I.4), (I.5), (I.6), (I.7), (I.8), (I.9), (I.10), (I.11), (I.12), (0.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below.

In particular the compounds

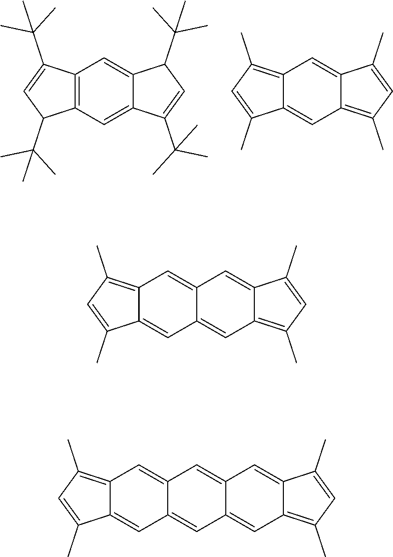

are excluded.

Further, in particular the following compounds are also excluded:

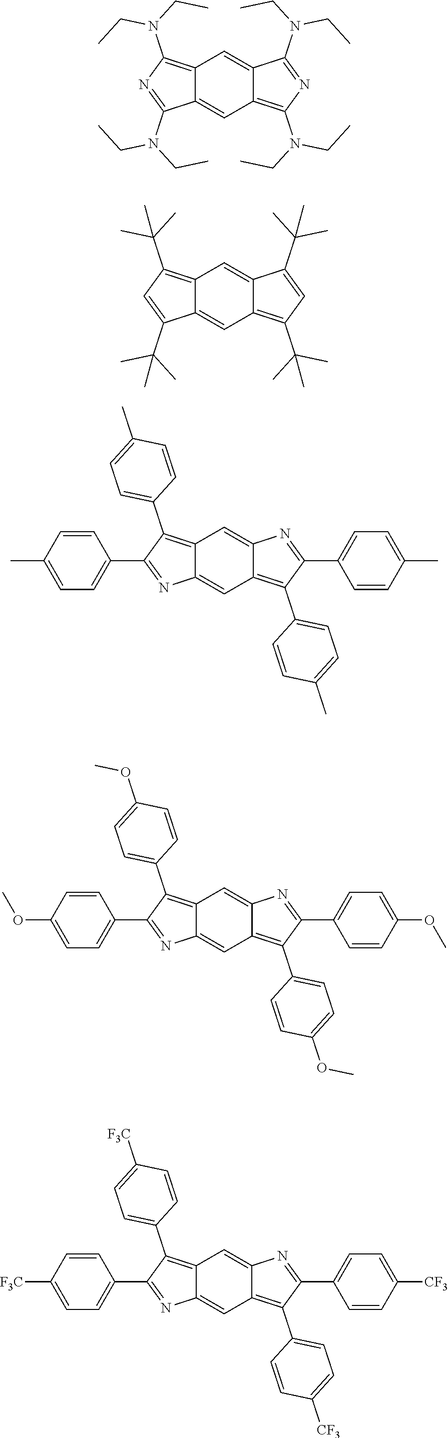

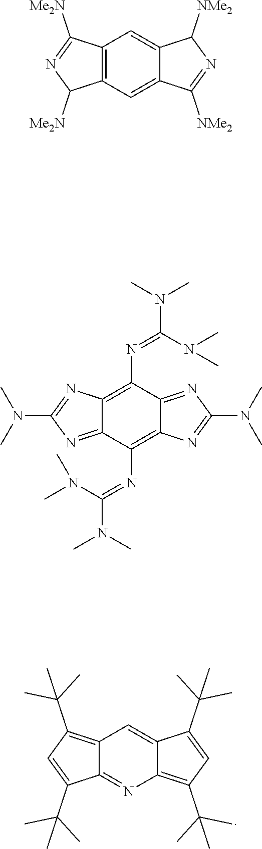

A further object of the invention is an organic semiconductive material containing at least one organic matrix compound and at least one or more light-emitting materials, characterized in that the matrix compound is one or more compounds of formula (I), preferably compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below

In particular the compounds

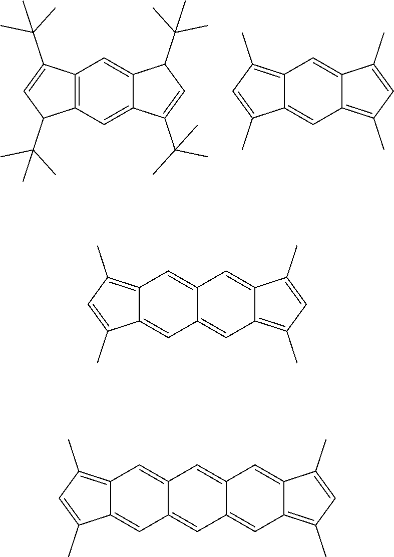

are excluded.

Further, in particular the following compounds are also excluded:

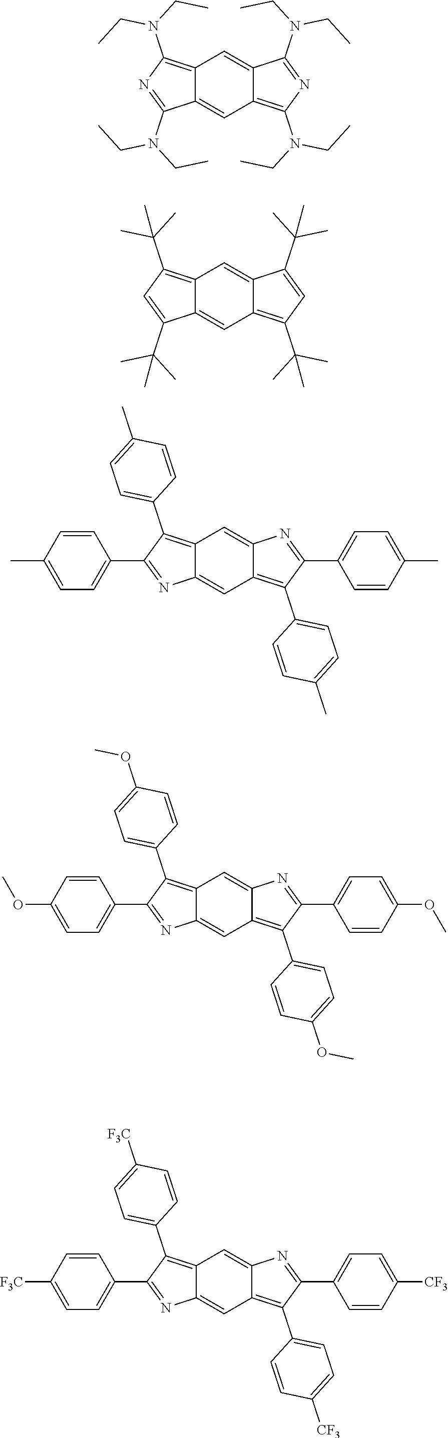

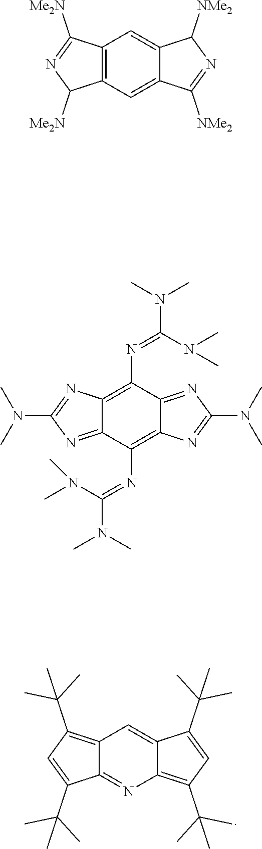

A further object of the invention is a use of at least one compound of formula (I), preferably compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below, as organic doping agent for the doping of an organic semiconductive matrix material, as matrix layers, as transport layer, as blocker layer, as absorbing layer, as charge injection layer, as organic semiconductor itself, organic semiconductive matrix material, as electron transport or as hole transport layer or as emitter matrix layer.

In particular the compounds

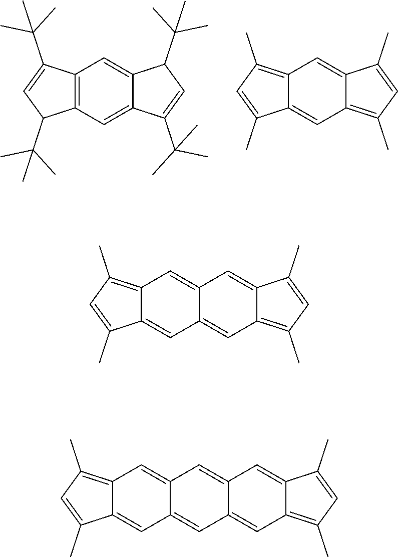

are excluded.

Further, in particular the following compounds are also excluded:

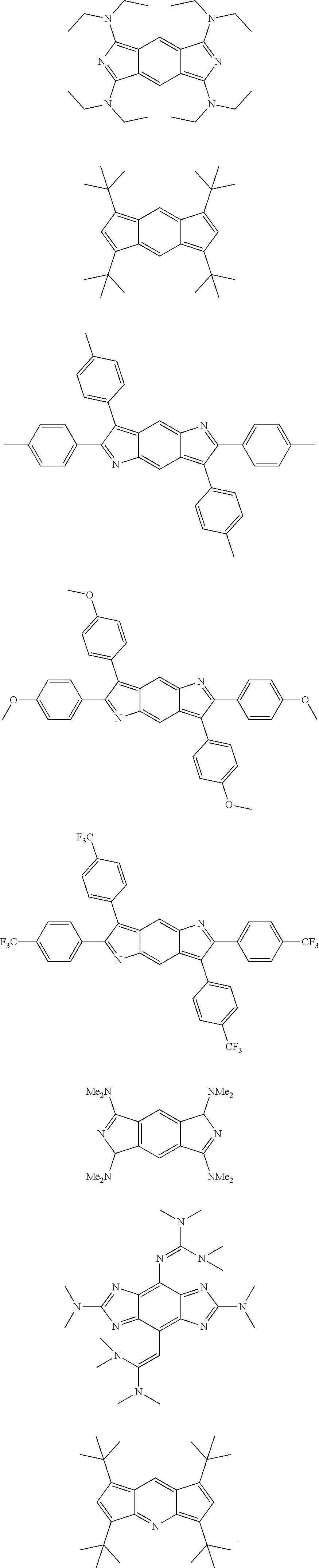

A further object of the invention is an electroluminescent arrangement comprising an upper electrode, a lower electrode, wherein at least one of said electrodes is transparent, an electroluminescent layer and optionally an auxiliary layer, wherein the electroluminescent arrangement comprises at least one compound of formula (I), preferably compounds of formulae I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below.

In particular the compounds

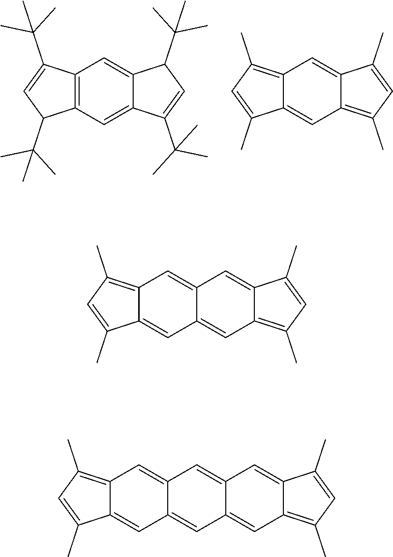

are excluded.

Further, in particular the following compounds are also excluded:

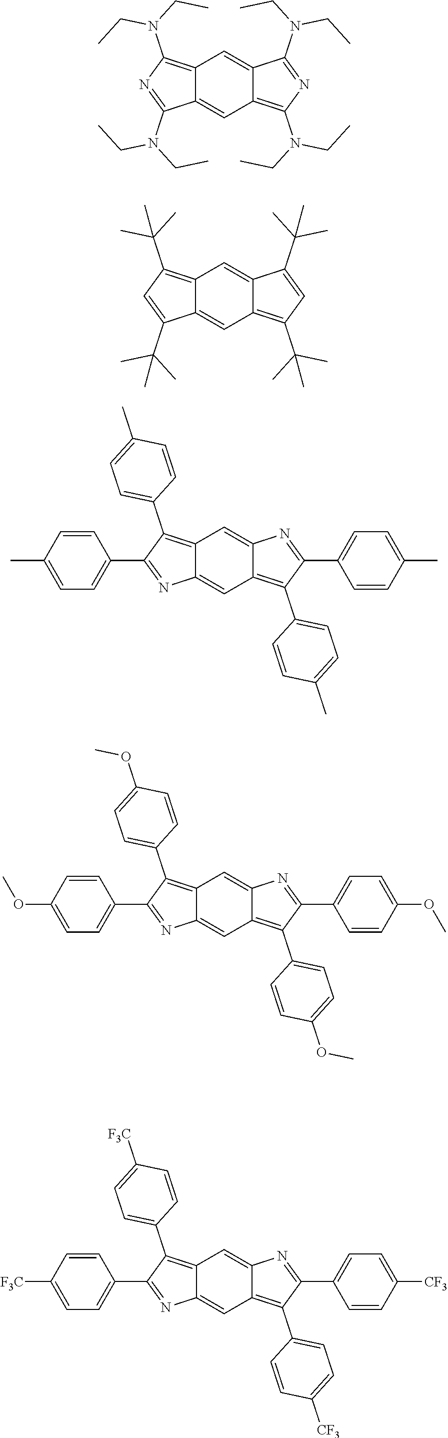

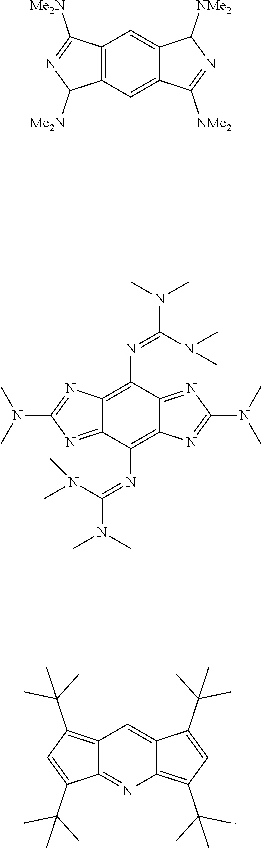

A further object of the invention is a semiconductor unit comprising at least one of formula (I), preferably compounds of formulae I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below.

In particular the compounds

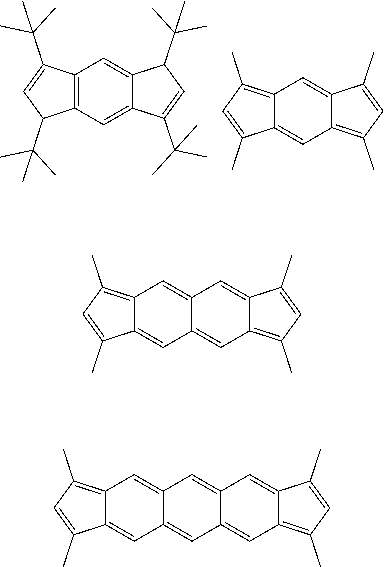

are excluded.

Further, in particular the following compounds are also excluded:

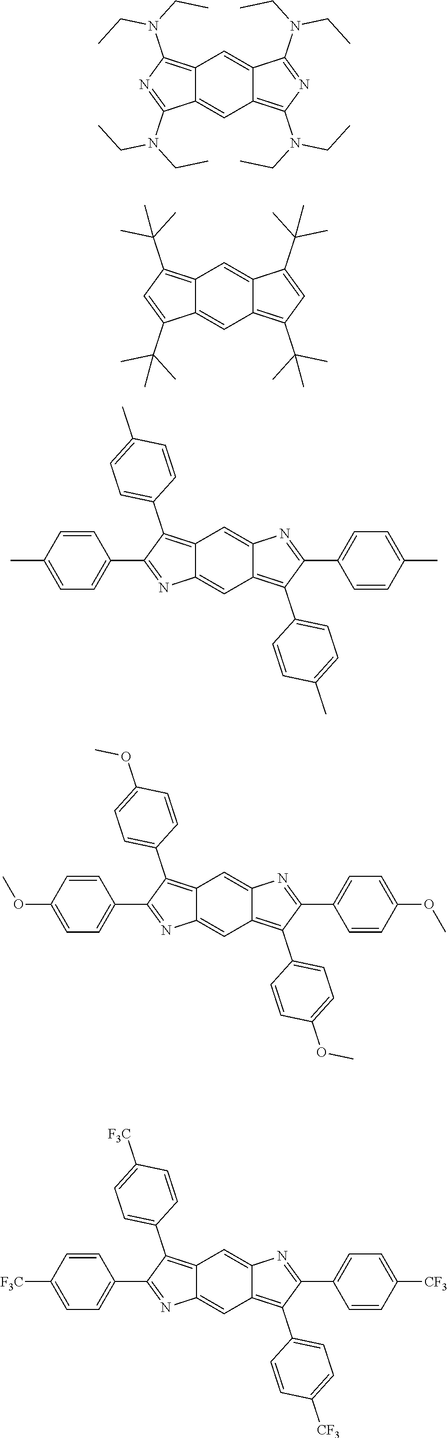

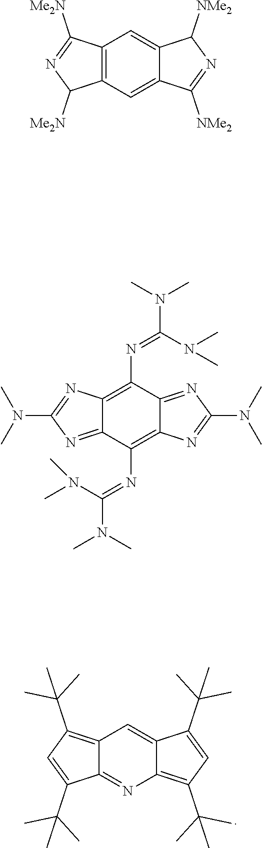

A further object of the invention is an electronic component as defined herein in the form of an organic light-emitting diode, a photovoltaic cell, an organic solar cell, an organic diode, an organic sensor, an organic field effect transistor or an organic battery.

In particular the compounds

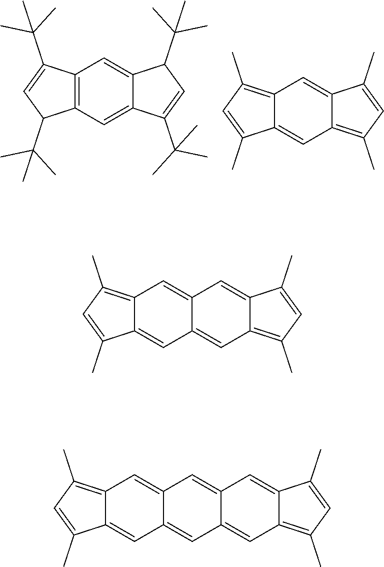

are excluded.

Further, in particular the following compounds are also excluded:

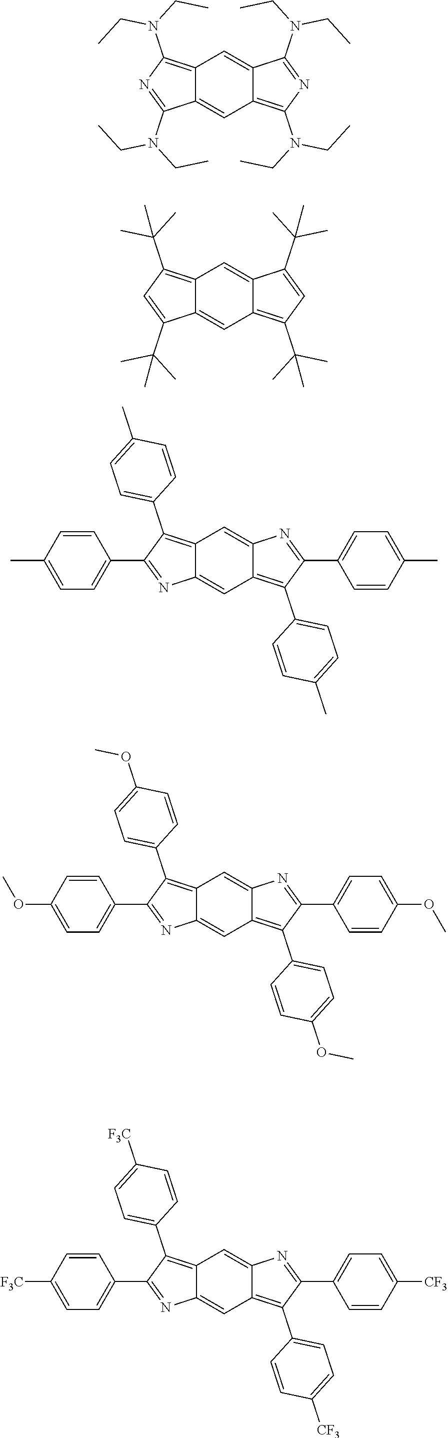

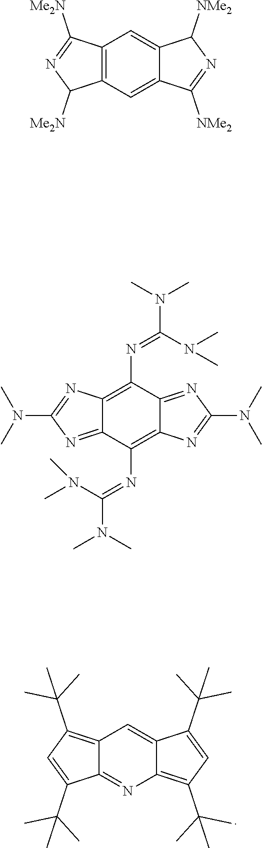

A further object of the invention is the use of at least one compound of formula (I), preferably compounds of formulae I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined above or below as an emitter material or absorber material.

In particular the compounds

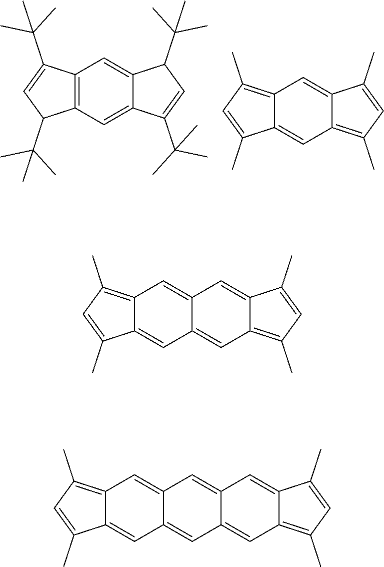

are excluded.

Further, in particular the following compounds are also excluded:

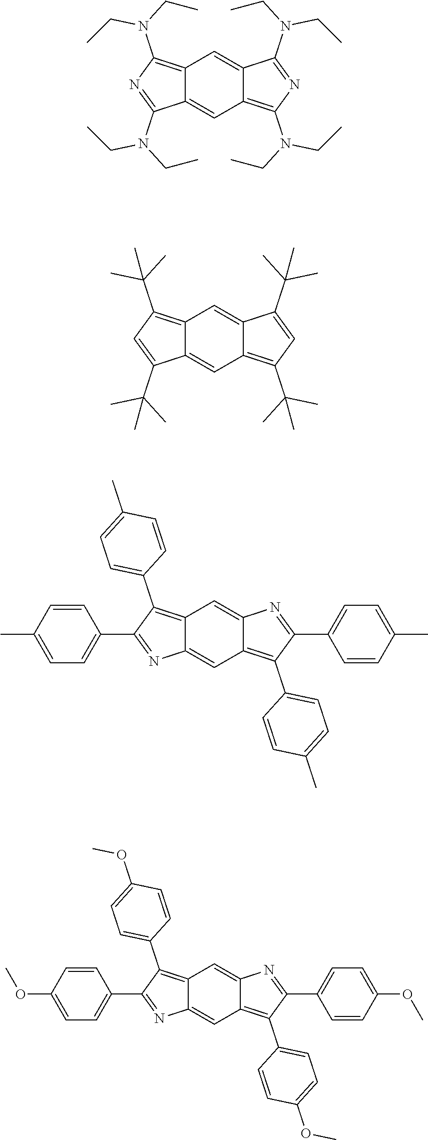

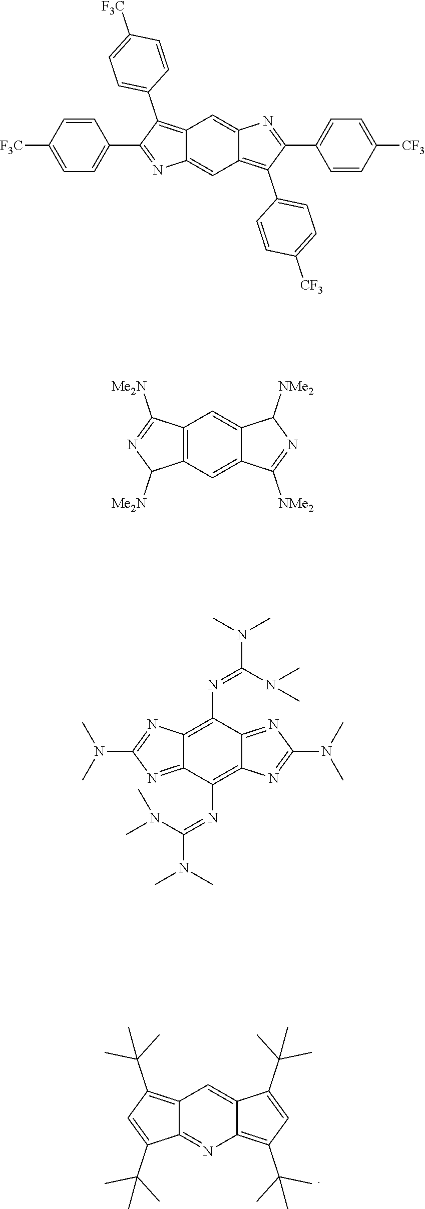

### DESCRIPTION OF THE INVENTION

The invention has the following advantages:
The compounds of formula (I) have only low production costs.
The compounds of formula (I) have a wide application range due to their antiaromatic nature. Depending on the nature of substituents (EDG vs. EWG) compounds of formula (I) can be used for n- as well as p-side application in organic electronic devices
The compounds of formula (I) are advantageously suitable as electron donors for use as n-dopants and as hole transport materials in organic-electronic components.
The compounds of formula (I) exhibit better conductivities compared to known electron donors.
The compounds of formula (I) are advantageously suitable as electron acceptors for use as p-dopants and as electron transport materials in organic-electronic components.
Furthermore, the compounds of formula (I) are characterized by a higher doping efficiency, while providing two-electron donors or two-electron acceptors respectively
The two-fold reduced (bis-anions) or two-fold oxidized derivatives (bis-cations) of the compounds of formula (I) show only a low absorption of the doped layer. Therefore, parasitic absorption and emissions can be reduced or even prevented.
The compounds of formula (I) are suitable for the production of organic and hybrid opto-electronic components, both by means of solvent processing and by vacuum reprocessing.

For clarity, the term “indacenes”, as used in the sense of the invention, comprises indazenes as well as aza indazenes wherein one, two, three or four carbon atoms are replaced by nitrogene.

The expression “halogen” denotes in each case fluorine, bromine, chlorine or iodine, particularly fluorine, chlorine and bromine.

The term “Cₙ-Cₘ-alkyl” as used herein, and also in di-Cₙ-Cₘ-alkylamino, refers to a branched or unbranched saturated hydrocarbon group having n to m carbon atoms, in particular 1 to 4 (C₁-C₄-alkyl) or 1 to 30 (C₁-C₃₀-alkyl). Examples for C₁-C₄-alkyl are methyl, ethyl, propyl, isopropyl, butyl, 1-methylpropyl(sec-butyl), 2-methylpropyl (isobutyl), 1,1-dimethylethyl(tert-butyl). Examples for C₁-C₃₀-alkyl are, in addition to those mentioned for C₁-C₄-alkyl, pentyl, 1-methylbutyl, 2-methylbutyl, 3-methylbutyl, 2,2-dimethylpropyl, 1-ethylpropyl, 1,1-dimethylpropyl, 1,2-dimethylpropyl, hexyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, n-heptyl, n-octyl, 2-ethylhexyl, n-nonyl, n-decyl, behenyl, lignocerinyl, cerotinyl, melissinyl, n-undecyl, n-dodecyl, n-tridecyl, n-tetradecyl, n-pentadecyl, n-hexadecyl, n-heptadecyl, n-octadecyl, n-nonadecyl, arachinyl, isotridecyl, isostearyl, etc.

The term C₁-C₃₀-alkoxy refers to straight-chain or branched alkyl groups having 1 to 30 carbon atoms attached via an oxygen atom at any bond in the alkyl group to the remainder of the molecule. Suitable alkyl groups are those mentioned above. Preferably C₁-C₃₀-alkoxy is C₁-C₄-alkoxy. Examples for C₁-C₄-alkoxy are methoxy, ethoxy, n-propoxy, 1-methylethoxy (isopropoxy), butoxy, 1-methylpropoxy (sec-butoxy), 2-methylpropoxy (isobutoxy) or 1,1-dimethylethoxy (tert-butoxy).

Perfluoro (C₁-C₄-alkyl) is preferably selected from trifluoromethyl, pentafluoroethyl, heptafluoro-n-propyl and nonafluoro-n-butyl. Perfluoro (C₁-C₄-alkyl) is more preferably selected from trifluoromethyl and pentafluoroethyl and in particular is trifluoromethyl.

The term C₃-C₁₄-cycloalkyl as used herein refers to a monocyclic or polycyclic, e.g. bi- or tricyclic, 3- to 14-membered saturated cycloaliphatic radical having 3 to 14 carbon atoms. C₃-C₁₄-cycloalkyl is preferably selected from cyclopropyl, cyclobutyl, cyclopentyl, cyclohexyl, cycloheptyl, cyclooctyl, perhydroanthracyl, perhydronaphthyl, perhydrofluorenyl, perhydrochrysenyl, perhydropicenyl, adamantyl, bicyclo[1.1.1]pentyl, bicyclo[2.2.1]heptyl, bicyclo[4.2.2]decyl, bicyclo[2.2.2]octyl, bicyclo[3.3.0]octyl bicyclo[3.3.2]decyl and bicyclo[4.4.0]decyl. Preferred are is monocyclic C₃-C₁₄-cycloalkyl, like cyclopropyl, cyclobutyl, cyclopentyl, cyclohexyl, cycloheptyl, cyclooctyl, more preferably cyclopentyl, cyclohexyl and cycloheptyl, in particular cyclohexyl.

C₃-C₁₄-cycloalkoxy refers to a monocyclic or polycyclic, e.g. bi- or tricyclic, 3- to 14-membered saturated cycloaliphatic radical as mentioned above bonded through O linkage to the skeleton.

The term C₆-C₁₄-aryl as used herein refers to monocyclic, bicyclic, tricyclic and tetracyclic aromatic hydrocarbon radicals with 6 to 14 ring carbon atoms, in which the rings are all condensed (fused) or two of the aromatic rings may also be joined to one another by a chemical bond and a divalent radical selected from —CH₂—, —O—, —S— or —N(H)—. Examples include phenyl, naphthyl, biphenyl, anthracenyl, phenanthrenyl, fluorenyl, indenyl, pyrenyl, dibenzofuranyl, dibenzothienyl, carbazolyl, 11H-benzo[b]fluorenyl, naphtho[2,3-b]benzofuryl, naphtho[2,3-b]benzothienyl and 5H-benzo[b]carbazolyl.

The term heteroaryl(hetaryl) includes mono- and polycyclic (e.g. bicyclic or tricyclic) heteroaromatic radicals having 4 to 13 carbon atoms, wherein hetaryl has 1, 2, 3 or 4 identical or different heteroatoms or heteroatom-containing groups as ring members, selected from N, NR⁷, O, S, SO and SO₂, preferably selected from N, O and S. The hetaryl group may be attached to the remainder of the molecule via a ring carbon or via a ring heteroatom e.g. via a nitrogen.

Preferred are 5- or 6-membered heteroaromatic rings, selected from 2-furyl, 3-furyl, 2-thienyl, 3-thienyl, 2-pyrrolyl, 3-pyrrolyl, 3-pyrazolyl, 4-pyrazolyl, 5-pyrazolyl, 2-oxazolyl, 4-oxazolyl, 5-oxazolyl, 2-thiazolyl, 4-thiazolyl, 5-thiazolyl, 2-imidazolyl, 4-imidazolyl, 1,3,4-triazol-2-yl, 2-pyridinyl, 3-pyridinyl, 4-pyridinyl, 3-pyridazinyl, 4-pyridazinyl, 2-pyrimidinyl, 4-pyrimidinyl, 5-pyrimidinyl, 2-pyrazinyl and 2-(thieno[3,2-b]thiophen-2-yl. Preferred are also 5- or 6-membered heteroaromatic rings, fused to a phenyl ring, like chinolinyl, isochinolinyl, cinnolinyl, chinazolinyl, chinoxalinyl, indolyl, isoindolyl, etc. Preferred are also 5- or 6-membered heteroaromatic rings, fused to two phenyl rings, like phenazinyl, acridinyl, etc.

In the context of the invention the expression “C₃-C₁₀ heterocyloalkyl” refers to saturated cycloaliphatic groups having 3 to 7, preferably 3 to 6 ring atoms, in which 1, 2 or 3 of the ring carbon atoms have been replaced by heteroatoms or heteroatom-containing groups, preferably selected from NR⁷, O, S, SO and SO₂ and which may be optionally substituted. In the case of a substitution, these heterocycloaliphatic groups preferably have 1, 2 or 3, particularly preferably 1 or 2, particularly 1 substituent(s). The heterocyloalkyl refers to monocyclic radicals that are attached to the remainder of the molecule via a heteroatom ring member. By way of example of such heterocycloaliphatic residues, mention may be made of aziridinyl, azetidinyl, pyrrolidinyl, pyrazolidinyl, imidazolidinyl, oxazolidinyl, isoxazolidinyl, thiazolidinyl, isothiazolidinyl, 1,2,4-oxadiazolidinyl, 1,2,4-thiadiazolidinyl, 1,2,4 triazolidinyl, 1,3,4-oxadiazolidinyl, 1,3,4 thiadiazolidinyl, 1,3,4 triazolidinyl, piperidinyl, hexahydropyridazinyl, hexahydropyrimidinyl, hexahydropyrimidinyl, piperazinyl, 1,3,5-hexahydrotriazinyl, 1,2,4 hexahydrotriazinyl, morpholinyl, 2-thiomorpholinyl, 3-thiomorpholinyl, 1-oxothiomorpholinyl, 1-oxothiomorpholinyl, 1,1-dioxothiomorpholinyl, 1,1-dioxothiomorpholinyl, hexahydroazepinyl, hexahydrooxepinyl, hexahydrodiazepinyl, hexahydrooxazepinyl and the like.

The electron acceptor groups are groups that accepts electrons transferred to it from another group or compound. Electron acceptor groups are preferably selected from cyano, nitro, fluoro, perfluoro (C₁-C₄-alkyl), chloro and bromo. More preferably, the electron acceptor groups are selected from cyano, nitro, fluoro, trifluoromethyl and pentafluoroethyl.

The electron donor groups are groups that donates electrons to another group or compound. Electron donor groups are preferably selected from C₁-C₃₀-alkyl, C₃-C₁₄-cycloalkyl, C₁-C₃₀-alkoxy, C₆-C₁₄-aryloxy, di(C₆-C₁₄-aryl)amino, di(C₁-C₃₀-alkyl)amino and di(C₃-C₁₄-cycloalkyl)amino.

### Compounds of Formula (I)

The invention relates to compounds of formula (I), wherein the radicals A, B, C, D, E, F, G and H as one of the meanings as defined above. Further the invention relates to the use of at least one compound of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined below, or their radical anions, radical anionic salts, radical cations, radical cationic salts, dianions, dianionic salts, dications, dicationic salts or their charge transfer complexes with donors or acceptors, in organic devices.

Preferred are compounds of formula (I), wherein of R¹ is selected from trifluoromethyl, pentafluoroethyl, NR^{X}R^{Y},

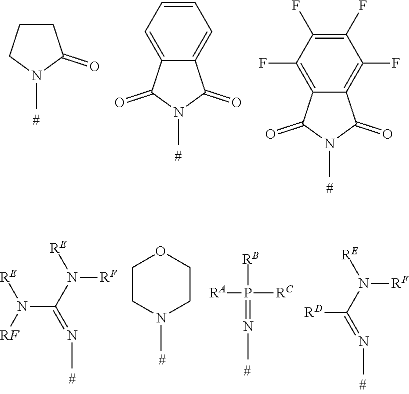

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein of R² is selected from trifluoromethyl, pentafluoroethyl, NR^{X}R^{Y},

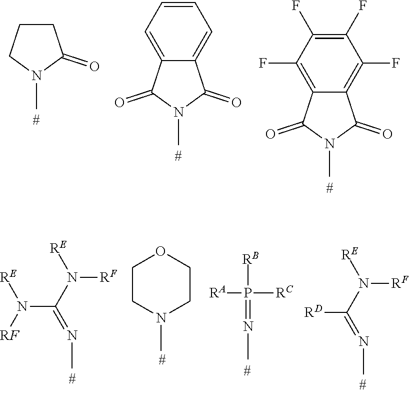

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein of R³ is selected from hydrogen, trifluoromethyl, pentafluoroethyl, NR^{X}R^{Y},

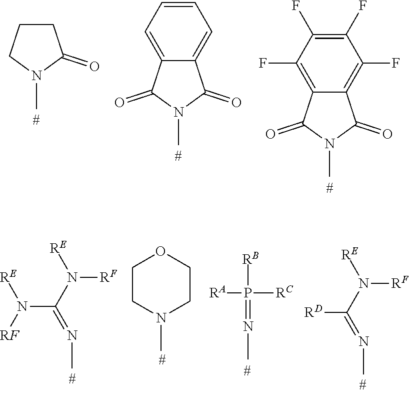

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein of R⁴ is selected from trifluoromethyl, pentafluoroethyl, NR^{X}R^{Y},

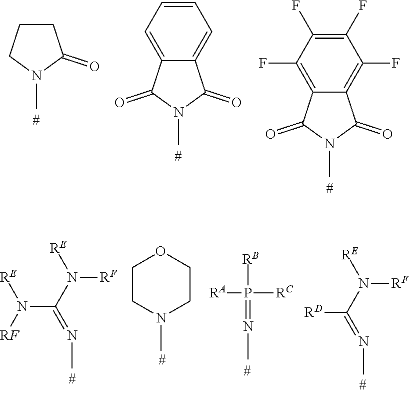

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein of R⁵ is selected from hydrogen, trifluoromethyl, pentafluoroethyl, NR^{X}R^{Y},

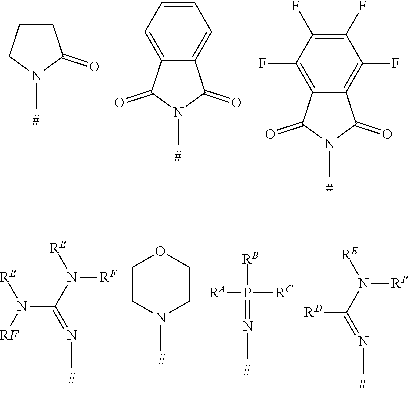

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein of R⁶ is selected from trifluoromethyl, pentafluoroethyl, NR^{X}R^{Y},

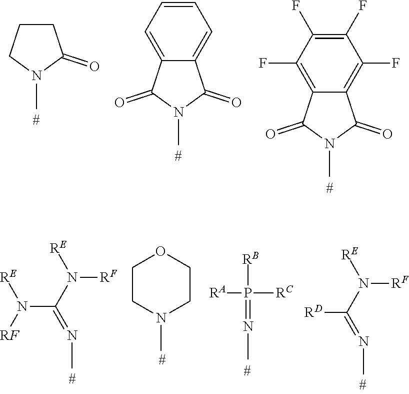

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein R¹¹ is selected from from hydrogen, trifluoromethyl, pentafluoroethyl, NR^{X}R^{Y},

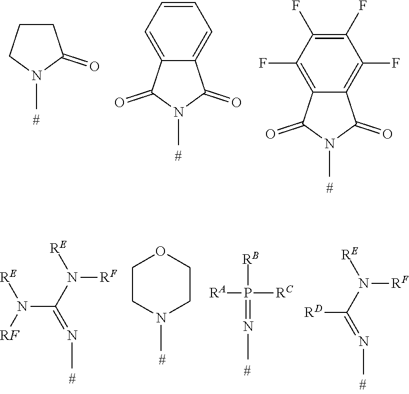

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein R¹² is selected from from hydrogen, trifluoromethyl, pentafluoroethyl, NR^{X}R^{Y},

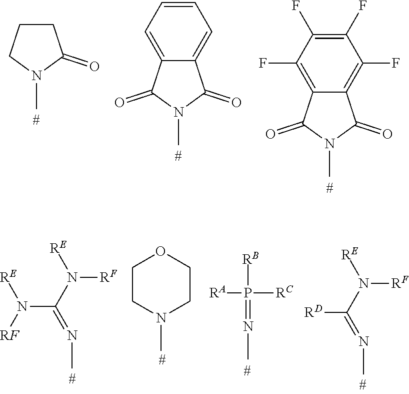

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} together with the nitrogen to which they bond form C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein R¹³ is selected from from hydrogen, trifluoromethyl, pentafluoroethyl, NR^{X}R^{Y},

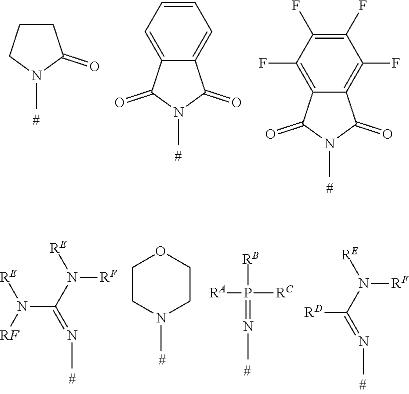

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I) wherein R²¹ is selected from from hydrogen, trifluoromethyl, pentafluoroethyl, NR^{X}R^{Y},

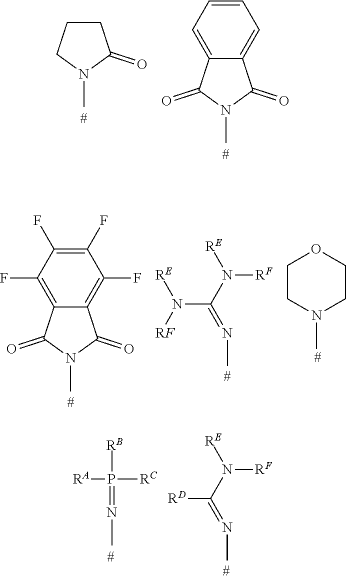

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₆-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein R²² is selected from from hydrogen, trifluoromethyl, pentafluoroethyl, NR^{X}R^{Y},

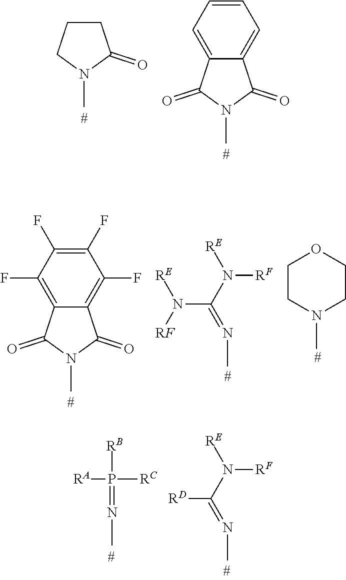

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Preferred are compounds of formula (I), wherein R²³ is selected from from hydrogen, trifluoromethyl, pentafluoroethyl, NR^{X}R^{Y},

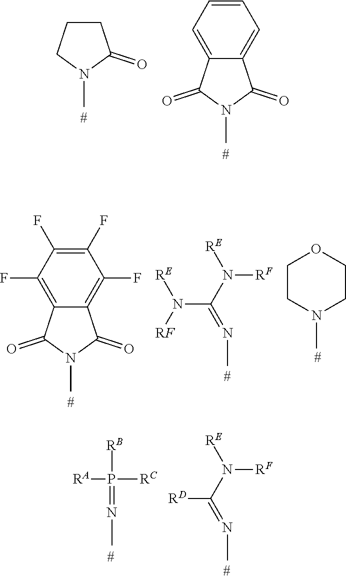

where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

Particular preferred compounds of the formula (I), wherein R¹¹, R¹², R¹³, R²¹, R²² and R²³ are hydrogen.

Irrespective of its occurrence the radical R⁷ is preferably selected from hydrogen, C₁-C₄-alkyl, C₁-C₄-haloalkyl or C₆-C₁₄-aryl, wherein aryl is unsubstituted or substituted by 1, 2, 3, 4 or 5 identical or different radicals selected from CN, halogen, C₁-C₄-alkyl or C₁-C₄-haloalkyl.

Irrespective of its occurrence the radical R^{X} and R^{Y} are preferably selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl.

A preferred embodiment are compounds of formula (I), in particular compounds which are selected from compounds of the following formulae (I.1)-(I.39):

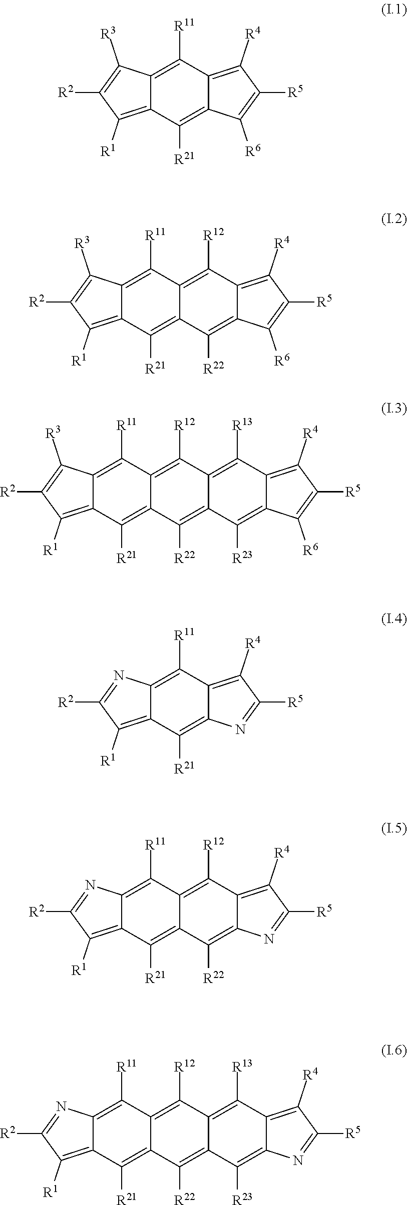

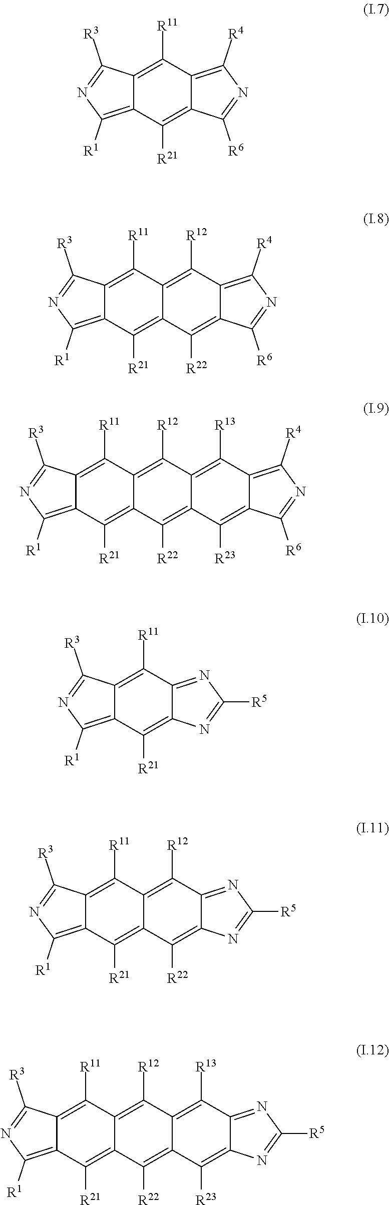

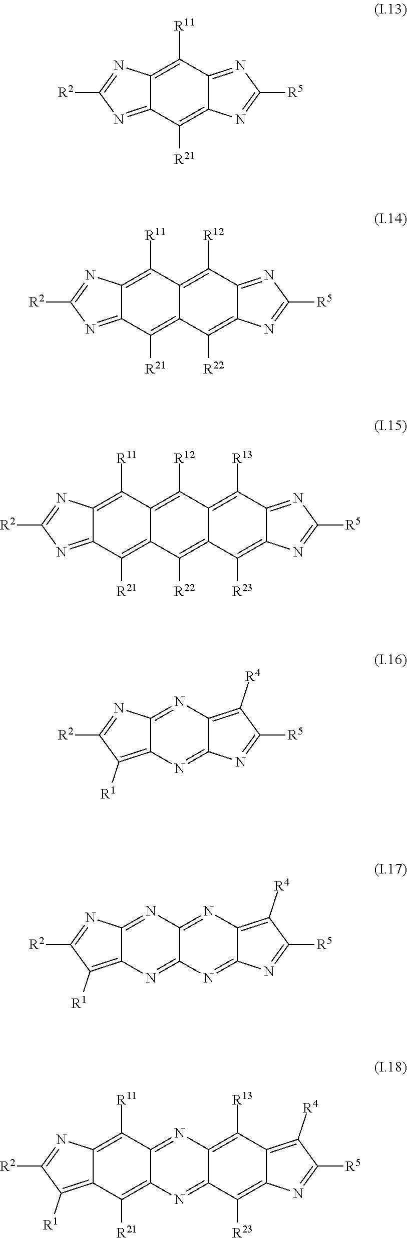

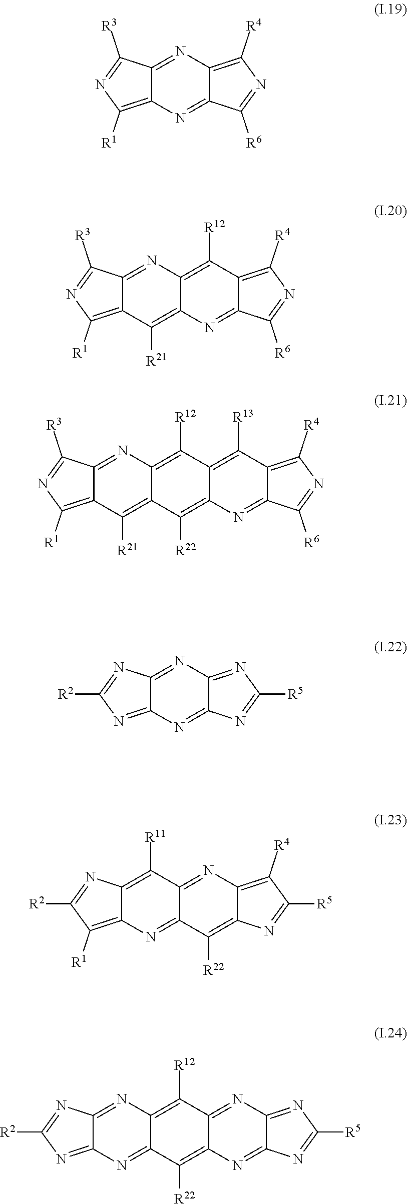

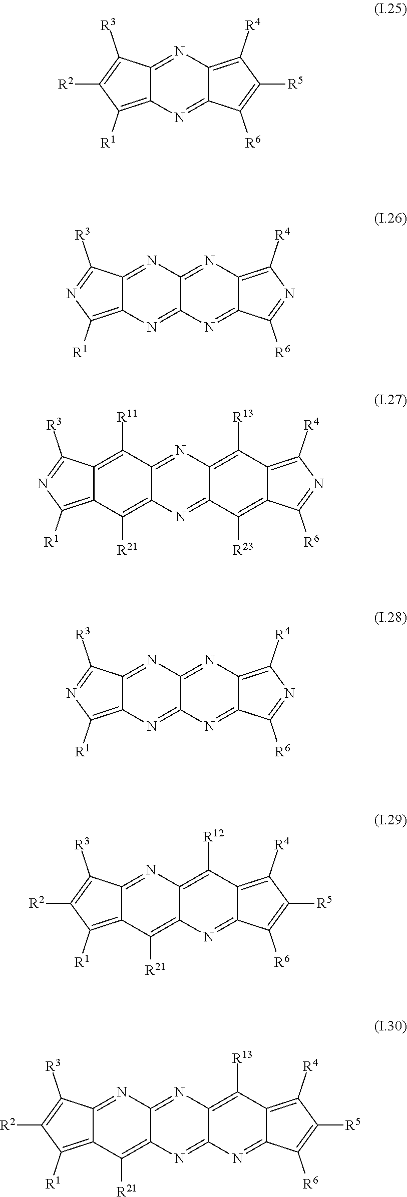

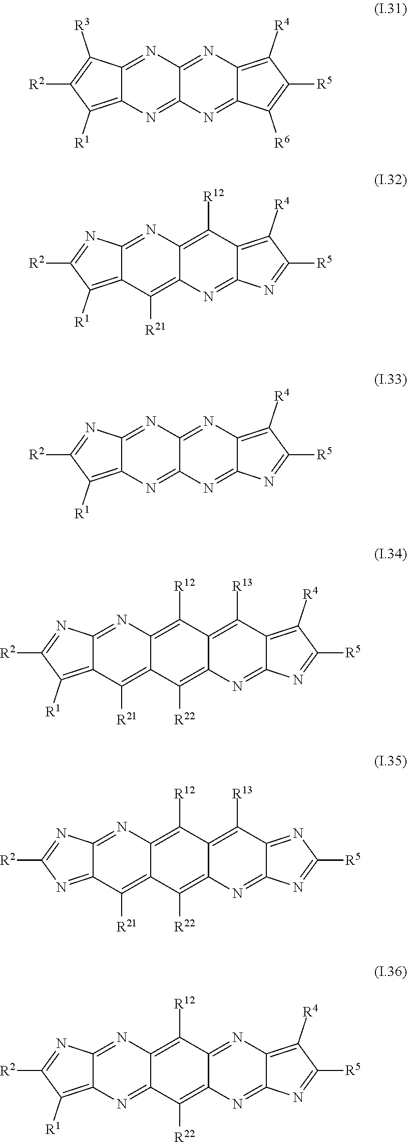

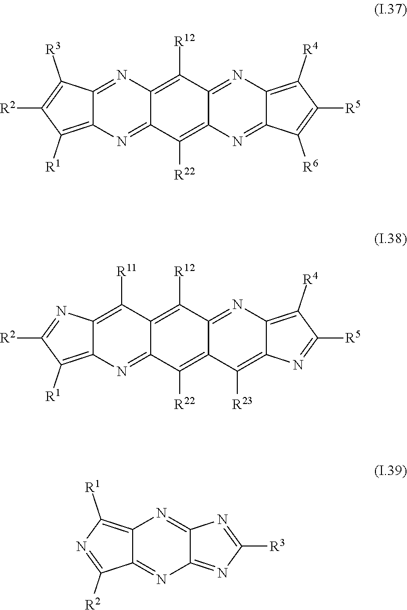

wherein
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₆-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹, R¹², R¹³, R²¹, R²² and R²³ independently selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, anisyl, mesityl,
or R^{E} and R^{F} bound to the same or to different nitrogen atoms form a C₃-C₁₀ heterocycloalkyl.

Another embodiment of the invention is the electronic component according to the invention in the form of an organic light-emitting diode, a photovoltaic cell, an organic solar cell, an organic diode, an organic sensor, an organic field effect transistor or an organic battery.

Another embodiment of the invention is the use of compounds of formula (I), preferably compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, or their radical anions, radical anionic salts, radical cations, radical cationic salts, dianions, dianionic salts, dications, dicationic salts or their charge transfer complexes with donors or acceptors as organic doping agent for the doping of an organic semiconductive matrix material, as matrix layers, as transport layer, as blocker layer, as absorbing layer, as charge injection layer, as organic semiconductor itself, organic semiconductive matrix material, as electron transport or as hole transport layer or as emitter matrix layer.

Preferrably, the compounds of the formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, their radical anions, radical anionic salts, radical cations, radical cationic salts, dianions, dianionic salts, dications, dicationic salts or their charge transfer complexes with donors or acceptors are used as as organic conductors, ferromagnets, or electro- or photochromic material.

In the compounds in accordance with the invention the position of the LUMO is so low that further technically interesting hole transport materials can now be efficiently doped. Due to the extremely low position of the LUMO and to the associated high reduction potential of the compounds even performance efficiencies of solar cells can be significantly improved. The doping effect of a certain magnitude (e.g. a doped layer of a certain conductivity) can be achieved with a substantially lower amount of dopant material to be used compared to conventional dopants under otherwise unchanged conditions. In addition, these compounds are extremely diffusion-stable in organic layers accounting on their high polarity. By making available pentalenes as p-doping agents or n-doping agents, these make possible a sufficient electrical conductivity of the organic semi-conductive matrix given advantageous electron affinity or electron donating ability of the doping agents in the particular components at low diffusion coefficients that ensure a component structure that is stable in time. Furthermore, the charge carrier injection of contacts into the doped layer can be improved by the doping agents. Furthermore, the doped organic semi-conductive material and the resulting electronic component can have an improved long-time stability on account of the compounds used in accordance with the invention. This concerns, e.g., a reduction or loss of the conductivity over time. This furthermore concerns the stability of the doped layer that is arranged adjacent to non-doped layers of an electro-optical component so that electro-optical components with increased long-time stability of the electro optical properties such as light emission quantum yield or, effectiveness of a solar cell or the like result.

Compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, have been found to be specifically useful to perform the invention. When tethered by electron withdrawing groups, those compounds are able to dope all common OLED hole transport materials. Especially, hole transport materials with a deep HOMO can be doped. In the opposite, when compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, are tethered by electron donating groups, those compounds are able to dope all common OPV electron transport materials, e.g. C60 and C70, or compounds like truxene derivatives reported in WO 2012031735 or even NTCDI derivatives as reported in WO 201216838.

Either, compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, can be strong electron acceptors and form easily radical anion salts (where the pentalene compound can carry for instance one or two negative charges) or charge-transfer complexes with electron donor compounds. Or, compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, can be strong electron donors and form easily radical cation salts (where the compound according to the invention can carry for instance one or two positive charges) or charge-transfer complexes with electron acceptor compounds. Such radical ion salts (radical anions or radical cations) or charge-transfer complexes have a variety of different useful applications such as to for charge injection layers, charge transport layers, organic conductor bodies, ferromagnetic bodies, or electrochromic or photochromic bodies.

By carrying out p-doping experiments, it was found that the compounds according to the invention gave very good doping properties. It is especially important to note that the substitution pattern defined by those compounds give strongly accepting compounds with a reduction potential in the range of 0V vs. Fc/Fc+ to 0.4V vs. Fc/Fc+ when the compounds according to the invention were tethered by related electron withdrawing groups. Fc/Fc+ denoted as usual the Ferrocene/Ferrocenium redox couple. Reduction potentials can be considered as measures for the LUMO of a molecule. Favorable substitution patterns involve six-membered (hetero-) cycles fully substituted with acceptor units such as cyano, fluoro, chloro, bromo, and the like, as functional unit in the pentalene compound. The six-membered (hetero-) cycles can be for instance perfluoropyridin-4-yl, tetrafluoro-4-(trifluoromethyl)phenyl), 4-cyanoperfluorophenyl, 4-nitroperfluorophenyl, dichloro-3,5-difluoro-4-(trifluoromethyl)phenyl, perfluorophenyl, trifluoro-3-(trifluoromethyl)pyridin-4-yl, difluoro-3,5-bis(trifluoromethyl)pyridin-4-yl or 3,5-bis(trifluoromethyl)triazin-2,4,6-yl.

By carrying out n-doping experiments, it was found that the compounds according to the invention gave very good doping properties. It is especially important to note that the substitution pattern defined by those compounds give donor compounds with an oxidation potential in the range of 0V vs. Fc/Fc+ to −1.0V vs. Fc/Fc+, preferably-0.4 vs. Fc/Fc+ to −0.8V vs. Fc/Fc+ when the compounds according to the invention were tethered by related electron donating groups. Oxidation potentials can be considered as measures for the HOMO of a molecule. Favorable substitution patterns involve six-membered (hetero-) cycles substituted with donor units such as dialkylamino, alkoxy, alkyl and the like, as functional unit in the pentalene compound. The six-membered (hetero-) cycles can be for instance phenyl or pyridyl.

For p-doped OLED or organic solar cell, often hole-injecting materials such as phthalocyanine copper complex (CuPc), 4,4′,4″-tris(N-3-methylphenyl-N-phenyl-amino)triphenylamine (m-MTDATA), 4,4′,4″-tris(N-(2-naphthyl)-N-phenyl-amino)triphenylamine (2-TNATA) or MeO-TPD (N,N,N′,N′-tetrakis(4-methoxy-phenyl)benzidine), or Spiro-TTB (2,2′,7,7′-Tetrakis-(N,N-diphenylamino)-9,9′-spirobifluoren, also called Spiro-TTP) are doped by electron acceptor compounds. The layer sequence is then for instance: Anode/p-doped HIL/(p-doped) HTL/EBL/EML/ETL/EIL/Cathode. Herein, HIL denotes a hole injection layer, HTL denotes an hole transport layer, EBL denotes an electron blocking layer, EML denotes a (light) emitting layer, ETL denoted an electron transport layer, EIL denotes electron injection layer. Such HIL materials have typically a relatively low oxidation potential in the range of 0V to 0.1V vs. Fc/Fc+. Oxidation potential can be considered as a measure for the HOMO of a molecule. There is a need, however, to achieve good doping results also in host materials which are conventionally used as HTL or EBL materials. They often have a higher oxidation potential in the range of 0.1 to 0.4 V vs. Fc/Fc+. It is remarkable, that the selected dopants provide the same high conductivities in a HIL type host and a HTL type host. HTL type materials are for instance: N,N′-Bis(naphthalen-1-yl)-N,N′-bis(phenyl)-benzidine, N,N′-Bis(naphthalen-1-yl)-N,N′-bis(phenyl)-9,9spiro-bifluorene, 9,9-Bis[4-(N,N-bis-biphenyl-4-yl-amino)phenyl]-9H-fluorene, N,N′-bis(phenanthren-9-yl)-N,N′-bis(phenyl)-benzidine, 2,2′-Bis[N,N-bis(biphenyl-4-yl)amino]9,9-spiro-bifluorene, 1,3,5-tris{4-[bis(9,9-dimethyl-fluoren-2-yl)amino]phenyl}benzene, tri (terphenyl-4-yl)amine.

For electron acceptor compounds used in OSCs that provide a low LUMO-level, such as fullerenes (C60, C70) or their derivatives (e.g. PCBM), phosphine imines were described and demonstrated in WO2012/175219 as sufficiently working and despite air-stable n-dopants. Later then, guanidine derivatives have been described as comparable air-stable n-dopants for doping C60 and other materials having an acceptor level in the range of −1.0 V vs. Fc/Fc+ (EP2963010B1). However, a broader variety of suitable and air-stable n-dopants for organic electronic devices particularly for OPV, providing better device performance as well as cost-effective manufacturing processes, does still represent an unmet need.

The deposition rate on a substrate with the compound used in accordance with the invention can be determined, e.g., using a quartz thickness monitor, as is customarily used, e.g., in the production of OLEDs. In particular, the ratio of the deposition rates of matrix materials and doping agent can be measured by independent measurements of them using two separate quartz thickness monitors in order to adjust the doping ratio.

It is understood that the compounds used in accordance with the invention are preferably such that they evaporate more or less or practically non-decomposed. However, if necessary, even purposeful precursors can be used as doping source that release the compounds used in accordance with the invention, e.g., acid addition salts, e.g., of a volatile or non-volatile inorganic or organic acid, or their charge transfer complexes, which acids and/or electron donors are preferably not volatile or only slightly volatile or the charge transfer complex itself acts as doping agent.

The p-doping agent is preferably selected in such a manner that it generates a conductivity just as high as or preferably higher than F4TCNQ under conditions that are otherwise the same such as, in particular, doping concentration (molar ratio, doping agent: matrix, layer thickness, current strength) at a given matrix material (e.g., zinc phthalocyanine or another matrix material cited further below), e.g., a conductivity (s/cm) greater than/equal to 1.1 times, 1.2 times or greater than/equal to 1.5 times or twice that of F4TCNQ as doping agent.

The n-doping agent is preferably selected in such a manner that it generates a conductivity just as high as or preferably higher than compounds described in EP2963010B1 or in WO2012/175219 under conditions that are otherwise the same such as, in particular, doping concentration (molar ratio, doping agent: matrix, layer thickness, current strength) at a given matrix material (e.g., C60 or another carbon allotrope).

The doping agent used according to the invention is preferably selected in such a manner that the semiconductive organic material doped with it still has ≥20%, preferably ≥30%, especially preferably >50% or 60% of the conductivity (s/cm) of the value at 100° C. after a temperature change of 100° C. to RT (20° C.).

### Electron Donating Matrix Materials

The present invention describes suitable doping agents for organic semiconductive materials such as hole transport materials HTM that are customarily used in OLEDs or organic solar cells. The semiconductive materials are preferably intrinsically hole-conducting. The following gives an exemplary description of materials that can be applied in conjunction with doping agents of the compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

Another aspect of the invention is an organic semiconductive material containing at least one organic matrix compound and at least one doping agent, wherein the doping agent is one or more compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

The matrix material comprises at least one matrix compound and at least one compound of formula (I).

The matrix material can consist partially (>10 or >25% by weight) or substantially (>50% by weight or >75% by weight) or totally of a metal phthalocyanine complex, a porphyrine complex, especially metal porphyrine complex, oligothiophene-, oligophenyl-, oligophenylene vinylene- or oligofluorene compound, in which the oligomer preferably comprises 2-500 or more, preferably 2-100 or 2-50 or 2-10 or more monomeric units. The oligomer can also comprise >4, >6 or >10 or more monomeric units, in particular also for the above-indicated ranges, thus, e.g., 4 or 6-10 monomeric units, 6 or 10-100 monomeric units or 10-500 monomeric units. Polymeric matrix materials can also be used. The monomers and oligomers can be substituted or unsubstituted and even block- or mixed polymerizates of the cited oligomers can be present as well as a compound with a triarylamine unit or a spiro-bifluorene compound. The cited matrix materials can also be present in combination with each other, optionally also in combination with other matrix materials. The matrix materials can have electron-donating substitutents such as alkyl- or alkoxy groups that have a reduced ionizing energy or reduce the ionizing energy of the matrix material.

The metal phthalocyanine complexes or porphyrine complexes used as matrix material can have a main group metal atom or subgroup metal atom. The metal atom Me can be coordinated 4-, 5- or 6-fold, e.g., in the form of oxo(Me═O), dioxo- (O=Me=O) imine-, diimine-, hydroxo-, dihydroxo-, amino- or diamino complexes, without being limited to them. The phthalocyanine complex or porphyrine complex can each be partially hydrogenated, however, the mesomeric ring system is preferably not disturbed. The phthalocyanine can contain, e.g., magnesium, zinc, iron, nickel, cobalt, magnesium, copper or vanadyl (═VO) as central atom. The same or other metal atoms or oxometal atoms can be present in the case of porphyrine complexes.

In one preferred embodiment the matrix compound is either selected from phthalocyanine metal (Me) complexes (MePc) or triarylamino based or thiopheno based hole transport materials (HTM).

In particular, such dopable hole transport materials HTM can be arylated benzidines, e.g., N,N′-perarylated benzidines or other diamines such as of the type TPD (in which one, several or all of the aryl groups can have aromatic heteroatoms), suitable arylated starburst compounds such as N,N′,N″-perarylated starburst compounds such as the compound TDATA (in which one, several or all of the aryl groups can have aromatic heteroatoms). The aryl groups can comprise phenyl, naphthyl, pyridine, quinoline, isoquinoline, peridazine, pyrimidine, pyrazine, pyrazole, imidazole, oxazole, furan, pyrrole, indole or the like, especially for each of the above-cited compounds. The phenyl groups of the particular compounds can be partially or completely replaced by thiophene groups.

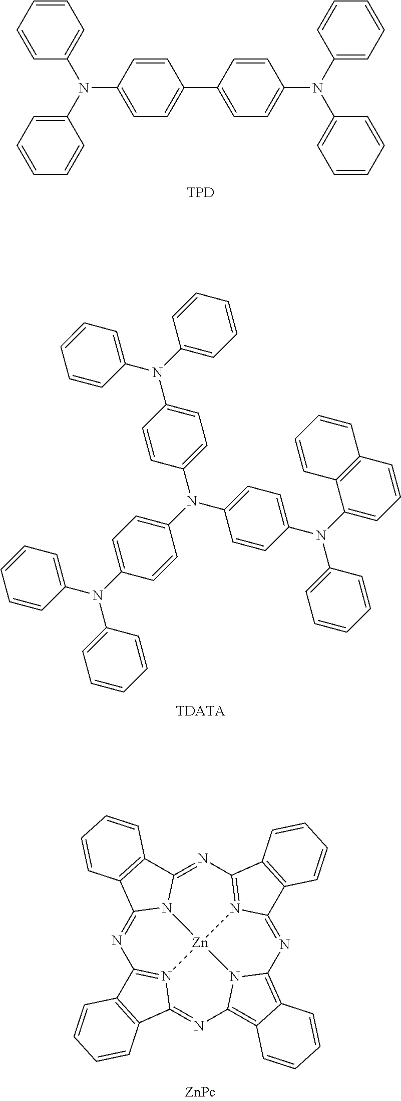

It is understood that even other suitable organic matrix materials/matrix compounds, in particular hole-conducting materials can be used that have semi-conductive properties.

In particular matrix/matrix comprises at least one matrix compound and at least one compound of the formula (I), wherein the matrix compound is selected from 4,4′,4″-tris(N-(2-naphthyl)-N-phenyl-amino)triphenylamine (2-TNATA), 4,4′,4″-tris(N-3-methylphenyl-N-phenyl-amino)triphenylamine (m-MTDATA), N,N,N′,N′-tetrakis(4-methoxy-phenyl)benzidine (MeO-TPD), (2,2′,7,7′-tetrakis-(N,N-diphenylamino)-9,9′-spirobifluorene (spiro-TTB), N,N′-bis(naphthalen-1-yl)-N,N′-bis(phenyl)-benzidine, N,N′-bis(naphthalen-1-yl)-N,N′-bis(phenyl)-9,9-spiro-bifluorene, 9,9-bis[4-(N,N-bis-biphenyl-4-yl-amino)phenyl]-9H-fluorene, 2,2′-bis[N,N-bis(biphenyl-4-yl)amino]-9,9-spiro-bifluorene, N,N′-((9H-fluoren-9,9-diyl)bis(4,1-phenylen))bis(N-([1,1′-biphenyl]-4-yl)-[1,1′-biphenyl]-4-amine) (BPAPF), N,N′-bis(phenanthren-9-yl)-N,N′-bis(phenyl)-benzidine, 1,3,5-tris{4-[bis(9,9-dimethyl-fluoren-2-yl)amino]phenyl}benzene, tri (terphenyl-4-yl)amine, N-(4-(6-((9,9-dimethyl-9H-fluoren-2-yl) (6-methoxy-[1,1′-biphenyl]-3-yl)amino)-1,3,3-trimethyl-2,3-dihydro-1H-inden-1-yl)phenyl)-N-(6-methoxy-[1,1′-biphenyl]-3-yl)-9,9-dimethyl-9H-fluoren-2-amine, N-([1,1′-biphenyl]-4-yl)-N-(4-(6-([1,1′-biphenyl]-4-yl(9,9-dimethyl-9H-fluoren-2-yl)amino)-1,3,3-trimethyl-2,3-dihydro-1H-inden-1-yl)phenyl)-9,9-dimethyl-9H-fluoren-2-amine, N,N-di([1,1′-biphenyl]-4-yl)-3-(4-(di([1,1′-biphenyl]-4-yl)amino)phenyl)-1,1,3-trimethyl-2,3-dihydro-1H-inden-5-amine, N-(4-(6-(bis(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9-dimethyl-9H-fluoren-2-amine, N-(4-(6-(9,9′-spirobi[fluoren]-2-yl(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9′-spirobi[fluoren]-2-amine, N-(4-(6-(dibenzo[b,d]furan-2-yl(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)dibenzo[b,d]furan-2-amine, 9-(4-(6-(9H-carbazol-9-yl)-1,3,3-trimethyl-2,3-dihydro-1H-inden-1-yl)phenyl)-9H-carbazole, N-([1,1′-biphenyl]-4-yl)-3-(4-([1,1′-biphenyl]-4-yl(4-methoxyphenyl)amino)phenyl)-N-(4-methoxyphenyl)-1,1,3-trimethyl-2,3-dihydro-1H-inden-5-amine, 3-(4-(bis(6-methoxy-[1,1′-biphenyl]-3-yl)amino)phenyl)-N,N-bis(6-methoxy-[1,1′-biphenyl]-3-yl)-1,1,3-trimethyl-2,3-dihydro-1H-inden-5-amine, N1-([1,1′-biphenyl]-4-yl)-N1-(4-(6-([1,1′-biphenyl]-4-yl(4-(diphenylamino)phenyl)amino)-1,3,3-trimethyl-2,3-dihydro-1H-inden-1-yl)phenyl)-N4,N4-diphenylbenzene-1,4-diamine, N,N-di([1,1′-biphenyl]-4-yl)-4′-(6-(4-(di([1,1′-biphenyl]-4-yl)amino)phenyl)-1,3,3-trimethyl-2,3-dihydro-1H-inden-1-yl)-[1,1′-biphenyl]-4-amine, N-(4-(5-(bis(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9-dimethyl-9H-fluoren-2-amine, N-(4-(6-(bis(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9-dimethyl-9H-fluoren-2-amine, N,N′-bis(9,9-dimethyl-fluoren-2-yl)-N,N′-diphenyl-benzidine (BF-DPB), N,N′-((9H-fluorene-9,9-diyl)bis(4,1-phenylene))bis(N-([1,1′-biphenyl]-4-yl)-[1,1′-biphenyl]-4-amine) (BPAPF), N4,N4,N4′, N4′-tetrakis(9,9-dimethyl-9H-fluoren-2-yl)-[1,1′-biphenyl]-4,4′-diamine (TDMFB), N-([1,1′-biphenyl]-2-yl)-N-(9,9-dimethyl-9H-fluoren-2-yl)-9,9′-spirobi[fluoren]-2-amine, (2,7-bis[N,N-bis(4-methoxyphenyl)amino]-9,9-spirobi[9H-fluorene] (spiro-MeO-TPD), a mixture of N-(4-(5-(bis(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9-dimethyl-9H-fluoren-2-amine and N-(4-(6-(bis(9,9-dimethyl-9H-fluoren-2-yl)amino)-1,3,3-trimethyl-2,3-dihydro-1H-inden-1-yl)phenyl)-N-(9,9-dimethyl-9H-fluoren-2-yl)-9,9-dimethyl-9H-fluoren-2-amine, N-([1,1′-biphenyl]-4-yl)-9,9-dimethyl-N-(4-(9-phenyl-9H-carbazol-3-yl)phenyl)-9H-fluoren-2-amine and mixtures thereof.

### Electron Accepting Matrix Materials

The present invention also describes suitable doping agents for organic semi-conductive materials such as electron transport materials ETM that are customarily used in organic solar cells. The semi-conductive materials are preferably intrinsically hole-conducting. The most common and industrialized ETM in organic solar cells are fullerenes like C60 or C70 as well as their derivatives. Those materials can be also applied in conjunction with doping agents of the compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (0.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

Preferred is the matrix compound/matrix compound which is either selected from C60, C70 or another carbon allotrope.

### Doping

The doping can take place in particular in such a manner that the molar ratio of matrix molecule to doping agent, or in the case of oligomeric matrix materials the ratio of matrix monomer number to doping agent is 1:100000, preferably 1:10000, especially preferably 1:5 to 1:1000, e.g., 1:10 to 1:100, e.g., ca. 1:50 to 1:100 or also 1:25 to 1:50.

### Evaporation of the Doping Agents

The doping of the particular matrix material (either indicated here as hole-conducting matrix material HTM or as electron-conducting material ETM) with the doping agents to be used in accordance with the invention can be produced by one or a combination of the following processes:
a) Mixed evaporation in the vacuum with a source for HTM or ETM and one for the doping agent.
b) Sequential deposition of HTM or ETM and doping agent with subsequent inward diffusion of the doping agent by thermal treatment
c) Doping of an HTM layer or ETM layer by a solution of doping agent with subsequent evaporation of the solvent by thermal treatment
d) Surface doping of an HTM layer or an ETM layer by a layer of doping agent applied on either or both surfaces of the HT layer.
e) Making a solution of host and dopant and form a film from the solution for instance by coating, casting or printing techniques or other film making techniques known to a person skilled in the art.

The doping can take place in such a manner that the doping agent is evaporated out of a precursor compound that releases the doping agent under heating and/or irradiation. The irradiation can take place by electromagnetic radiation, especially visible light, UV light or IR light, e.g., by laser light or also by other radiation types. The heat necessary for evaporation can substantially be made available by the irradiation and can also be radiated in a purposeful manner into certain bands of the compounds or precursors or compound complexes such as charge transfer complexes to be evaporated in order to facilitate the evaporation of the compounds by dissociation of the complexes by conversion into excited states. It is understood that the evaporation conditions described in the following are directed to those without irradiation and that uniform evaporation conditions are to be used for purposes of comparison.

For example, the following can be used as precursor compounds:
a) Mixtures or stoichiometric or mixed crystalline compounds of the doping agent and an inert, non-volatile substance, e.g., a polymer, molecular sieve, aluminum oxide, silica gel, and oligomers or another organic or inorganic substance with high evaporation temperature, in which the doping agent is bound primarily by van der Waals forces and/or hydrogen bridge bonding to this substance.
b) Mixture or stoichiometric or mixed crystalline compound of the doping agent and one non-volatile compound V more or less of the electron donor type, in which a more or less complete charge transfer occurs between the doping agent and the compound V as in charge transfer complexes with more or less electron-rich polyaromatics or heteroaromatics or another organic or inorganic substance with high evaporation temperature.
c) Mixture or stoichiometric or mixed crystalline compound of the doping agent and a substance that evaporates together with the doping agent and has the same or higher ionizing energy as the substance HT to be doped, so that the substance does not form a trap for holes in the organic matrix material. According to the invention the substance can also be identical to the matrix material here, e.g., be a metal phthalocyanine or benzidine derivative. Further suitable volatile co-substances such as hydroquinones, 1,4-phenylene diamines or 1-amino-4-hydroxybenzene or other compounds form quinhydrones or other charge transfer complexes.

### Electronic Component

A plurality of electronic components or equipment containing them can be produced using the organic compounds in accordance with the invention for producing doped organic semiconductive materials that can be arranged in particular in the form of layers or electrical line paths. In particular, the doping agents in accordance with the invention can be used to produce organic, light-emitting diodes (OLED), organic solar cells, organic diodes, especially those with a high rectification ratio such as 10³-10⁷, preferably 10⁴-10⁷ or 10⁵-10⁷ or organic field effect transistors. The conductivity of the doped layers and/or the improvement of the charge carrier injection of contacts into the doped layer can be improved by the doping agents in accordance with the invention. In particular in the case of OLEDs or organic solar cells the component can have a pin structure (the device has a one or more p-doped hole transport layers and/or one or more n-doped electron transport layers) or an inverted structure (the top-electrode and hole transport layer are located on the same side from the light emitting or light harvesting layer while the substrate is on the opposite side) or possible variations of them without being limited to them. An injection layer can be made, for instance, by forming a layer containing or consisting of the organic compounds in accordance with the invention between an electrode and a charge transporting layer. However, the use of the doping agents in accordance with the invention is not limited to the advantageous exemplary embodiments cited above.

A further object of the invention is an electronic component with an electronically functionally active area that comprises or consists of at least one compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

Preferred is an electronic component, wherein the electronically functionally active area comprises an organic semi-conductive matrix material that is doped with at least one doping agent for changing the electronic properties of the semi-conductive matrix material using at least one at least one compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

Further preferred is an electronic component in the form of an organic light-emitting diode, a photovoltaic cell, an organic solar cell, an organic diode, an organic field effect transistor or an organic battery.

A further object of the invention is an organic field-effect transistor comprising a substrate having at least one gate structure, a source electrode and a drain electrode and at least one compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

A further object of the invention is a substrate comprising a plurality of organic field-effect transistors, at least some of the field-effect transistors comprising at least one compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

An object of the invention is also a semiconductor unit comprising said substrate.

A further object of the invention is an electroluminescent arrangement comprising an upper electrode, a lower electrode, wherein at least one of said electrodes is transparent, an electroluminescent layer and optionally an auxiliary layer, wherein the electroluminescent arrangement comprises at least one compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein.

Preferred is an electroluminescent arrangement in form of an organic light-emitting diode (OLED).

In a further embodiment of the invention, the compound of the formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, are employed as matrix material for a fluorescent or phosphorescent compound, in an emitting layer. The organic electroluminescent (electronic component) device here may comprise one emitting layer or a plurality of emitting layers, where at least one emitting layer comprises at least one compound according to the invention as matrix material.

A further object of the invention is the use of compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as an emitter material.

In a further embodiment of the invention, the compound of the formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as defined herein, are employed as matrix material in an absorbing layer. The organic electronic device here may comprise one absorbing layer or a plurality of absorbing layers, where at least one absorbing layer comprises at least one compound according to the invention as matrix material.

A further object of the invention is the use of compounds of formula (I), in particular compounds of formulae (I.1), (I.2), (I.3), (I.4), (I.5), (I.6), (I.7), (I.8), (I.9), (I.10), (I.11), (I.12), (I.13), (I.14), (I.15), (I.16), (I.17), (I.18), (I.19), (I.20), (I.21), (I.22), (I.23), (I.24), (I.25), (I.26), (I.27), (I.28), (I.29), (I.30), (I.31), (I.32), (I.33), (I.34), (I.35), (I.36), (I.37), (I.38) and (I.39) as an absorber material.

A further object of the invention are compounds of formula (I):

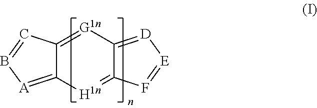

or their radical anions, radical anionic salts, radical cations, radical cationic salts, dianions, dianionic salts, dications, dicationic salts or their charge transfer complexes with donors or acceptors,
in which
n is 1, 2, 3
A is nitrogen or C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—R¹ⁿ
each H¹ⁿ is nitrogen or C—R²ⁿ,
wherein 0, 1, 2, 3 or 4 non-adjacent groups A, B, C, D, E or F are a nitrogen atom,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₆-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₆-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹, R¹², R¹³, R²¹, R²² and R²³ independently selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, anisyl, mesityl,
or R^{E} and R^{F} bound to the same or to different nitrogen atoms form a C₃-C₁₀ heterocycloalkyl,
with the proviso that

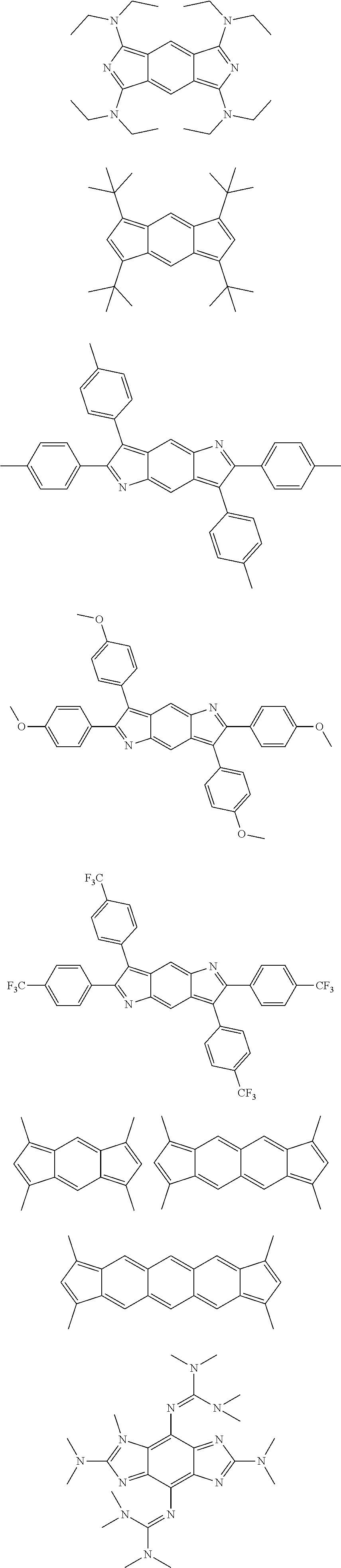

are excluded.

Further, in particular, the following compounds are also excluded

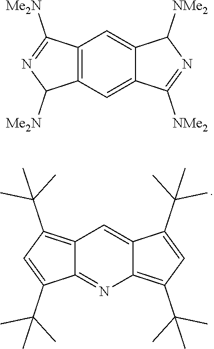

### EXAMPLES

The invention will be explained in detail with a few exemplary embodiments.

### Preparation of Donor Substituted 2,6-Diazaindacenes

1,1,3,5,5,7-Hexachloro-2,6-diaza-1,5-dihydroindacene has been synthesized according to a procedure by R. Gompper et. al, Angew. Chem. Int. Ed. Engl., 26, 1037-1039.

### Synthesis of Example DAI-1

### N,N′-((1Z,5Z)-3,7-bis(methyl(phenyl)amino) pyrrolo[3,4-f]isoindole-1,5-diylidene)bis(N-methylbenzenaminium)tetrafluoroborate

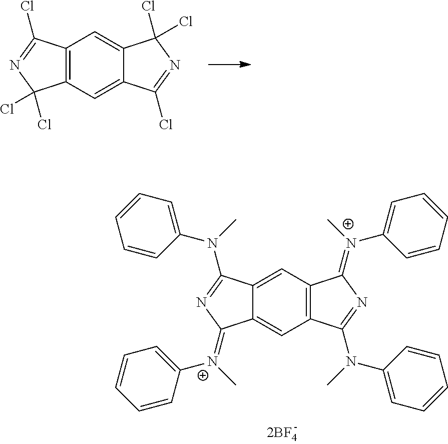 [SMILES: ClC1=NC(Cl)(Cl)c2cc3c(cc21)C(Cl)(Cl)N=C3Cl ; CN(c1ccccc1)c1n/c(=[N+](/C)c2ccccc2)c2cc3c(N(C)c4ccccc4)n/c(=[N+](/C)c4ccccc4)c3cc12]

1,1,3,5,5,7-Hexachloro-2,6-diaza-1,5-dihydroindacene (0.72 g, 2 mmol) and 20 ml dry THF were placed in a Schlenk vessel. After cooling to −70° C., N,1,1,1-tetramethyl-N-phenylsilanamine (1.8 g, 10 mmol) was added. The reaction mixture was slowly warmed to room temperature. The orange precipitate was filtered and then dissolved in acetonitrile. Sodium tetrafluoroborate (1.1 g, 10 mmol) was added. The suspension was stirred at room temperature for 1 day. After the solvent was removed under reduced pressure, the orange residue was triturated with dichloromethane and water. The organic suspension was filtered and the obtained orange solid was washed with dichloromethane (1.1 g, 1.47 mmol, 73%).

MS (APCI) (m/z): 544.66 ([C₃₈H₃₄N₆—(CH₃)₂+H]⁺).

### 1,3,5,7-Tetra(methyl(phenyl)amino)-2,6-diaza-s-indacene

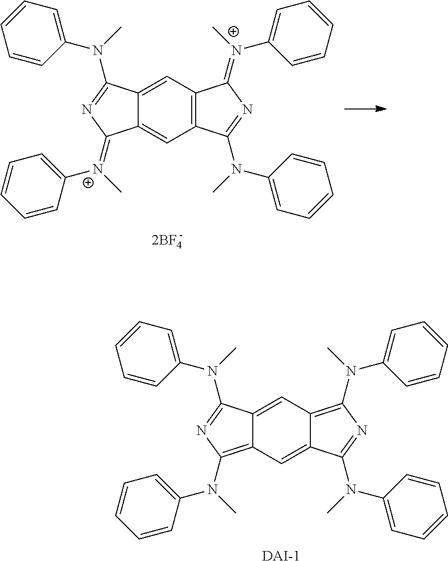

N,N-((1Z,5Z)-3,7-bis(methyl(phenyl)amino) pyrrolo[3,4-f]isoindole-1,5-diylidene)bis(N-methylbenzenaminium)tetrafluoroborate (0.62 g, 0.83 mmol) was suspended in 40 ml dry THF and potassium (0.065 g, 1.66 mmol) was added. The mixture was refluxed under nitrogen for 18 h. The volatiles were removed under vacuum and the solid residue was extracted several times with benzene. After removal of the benzene under vacuum, the pure product was obtained as a purple-green solid (0.287 g, 0.50 mmol, 60%).

¹H NMR (80 MHz, C₆D₆) δ 7.12-6.67 (m, 20H), 6.39 (s, 2H), 3.41 (s, 12H).

MS (APCI) (m/z): 575.1 ([C₃₈H₃₄N₆+H]⁺).

Melting point (DSC): 202° C.

CV (ACN, E₀ vs. Fc/Fc⁺) E₀^{0/+1}=−0.85 V; E₀^{+1/+2}=−0.52 V.

### Synthesis of Example DAI-2

### [3,7-Bis(diethylamino)-5-(diethylazaniumylidene)-1,5-dihydro-2,6-diaza-s-indacen-1-ylidene]bis(ethyl)azanium tetrafluoroborate

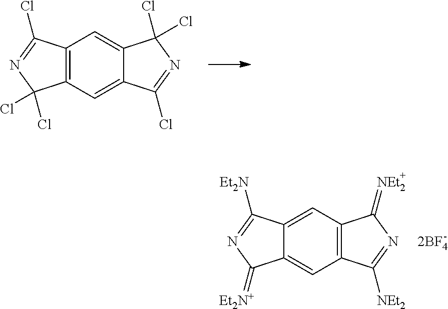

According to the procedure described in example DAI-1, using diethyltrimethylsilyla-mine instead of N,1,1,1-tetramethyl-N-phenylsilanamine, [3,7-Bis(diethylamino)-5-(diethylazaniumylidene)-1,5-dihydro-2,6-diaza-s-indacen-1-ylidene]bis(ethyl)azanium tetrafluoroborate was synthesized (35% yield).

¹H NMR (80 MHz, CD₃CN) δ 8.11 (s, 2H), 4.59-3.60 (m, 16H), 1.70-1.22 (m, 24H).

MS (APCI) (m/z): 439.4 ([C₂₆H₄₂N₆+H]⁺).

CV (ACN, E₀ vs. Fc/Fc⁺) E₀^{+2/+1}=−0.69 V; E₀^{+1/0}=−1.17 V.

### 1,3,5,7-Tetra(diethylamino)-2,6-diaza-s-indacene

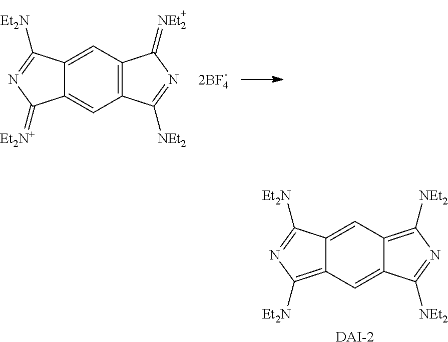

According to the procedure described in example DAI-1, using [3,7-Bis(diethylamino)-5-(diethylazaniumylidene)-1,5-dihydro-2,6-diaza-s-indacen-1-ylidene]bis(ethyl)azanium tetrafluoroborate instead of N,N′-((1Z,5Z)-3,7-bis(methyl(phenyl)amino) pyrrolo[3,4-f]isoindole-1,5-diylidene)bis(N-methylbenzenaminium)tetrafluoroborate, 1,3,5,7-Tetra(diethylamino)-2,6-diaza-s-indacene was synthesized (76% yield).

MS (APCI) (m/z): 439.0 ([C₂₆H₄₂N₆+H]⁺).

CV (ACN, E₀ vs. Fc/Fc⁺) E₀^{0/+1}=−1.25 V; E₀^{+1/+2}=−0.45 V.

Melting point (DSC): 247° C.

### Synthesis of Example DAI-3

### N-Ethyl-1,1,1-trimethyl-N-phenylsilanamine

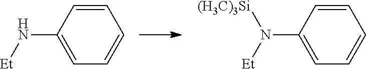

N-Ethyl aniline (19 ml, 150 mmol) was dissolved in 50 ml dry THF. After cooling down to 0° C., 2.5 M n-BuLi-solution in n-hexane (66 ml, 165 mmol) was added and the solution was stirred for 15 min. Then chlorotrimethylsilane (29.3 ml, 230 mmol) in 100 ml THF was slowly added. The resulting suspension was stirred at room temperature for 1 day. The solid was filtered off and the solvent was removed under reduced pressure. N-pentane was added and the solution was decanted. This process was repeated three times. The solutions were combined and then the n-pentane was removed under reduced pressure. The remaining liquid was distillated under vacuum to give a colorless liquid (24 g, 124 mmol, 83%).

Boling point: 78° C. (8 mbar).

¹H NMR (80 MHz, neat) δ 10.59-9.83 (m, 5H), 6.54 (q, J=7.0 Hz, 2H), 4.27 (t, J=7.0 Hz, 3H), 3.46 (s, 9H).

### N,N′-((1Z,5Z)-3,7-bis(ethyl(phenyl)amino) pyrrolo[3,4-f]isoindole-1,5-diylidene)bis(N-ethylbenzenaminium)tetrafluoroborate

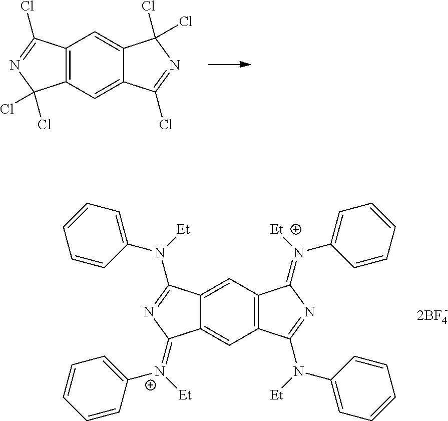

According to the procedure described in example DAI-1, using, N-Ethyl-1,1,1-trimethyl-N-phenylsilanamine instead of N,1,1,1-tetramethyl-N-phenylsilanamine, N,N′-((1Z,5Z)-3,7-bis(ethyl(phenyl)amino) pyrrolo[3,4-f]isoindole-1,5-diylidene)bis(N-ethyl-benzenaminium)tetrafluoroborate was synthesized (58% yield).

MS (APCI) (m/z): 631.5 ([C₄₂H₄₂N₆+H]⁺).

CV (ACN, E₀ vs. Fc/Fc⁺) E₀^{+2/+1}=−0.52 V; E₀^{+1/0}=−0.88 V.

### 1,3,5,7-Tetra(ethyl(phenyl)amino)-2,6-diaza-s-indacene

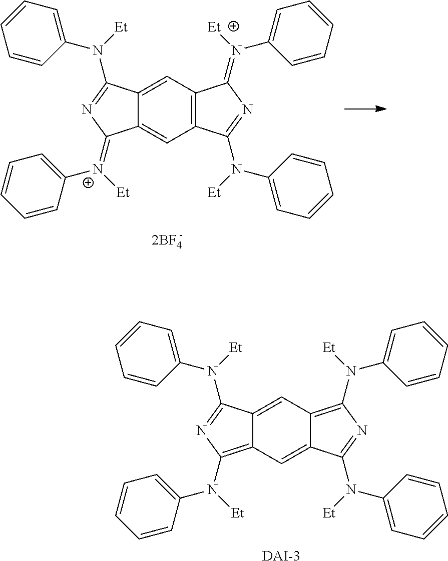

According to the procedure described in example DAI-1, using N,N-((1Z,5Z)-3,7-bis(ethyl(phenyl)amino) pyrrolo[3,4-f]isoindole-1,5-diylidene)bis(N-ethylbenzenaminium) tetrafluoroborate instead of N,N′-((1Z,5Z)-3,7-bis(methyl(phenyl)amino) pyrrolo[3,4-f]isoindole-1,5-diylidene)bis(N-methylbenzenaminium)tetrafluoroborate, 1,3,5,7-Tetra(ethyl(phenyl)amino)-2,6-diaza-s-indacene was synthesized (22% yield).

¹H NMR (80 MHz, C₆D₆) δ 7.15-6.63 (m, 20H), 6.19 (s, 2H), 3.96 (q, J=7.0 Hz, 8H), 1.18 (t, J=7.0 Hz, 12H).

MS (APCI) (m/z): 631.4 ([C₄₂H₄₂N₆+H]⁺).

CV (ACN, E₀ vs. Fc/Fc⁺) E₀^{0/+1}=−0.88 V; E₀^{+1/+2}=−0.52 V.

### Synthesis of Example DAI-4

### 3,7-Bis(dimethylamino)-5-(dimethylazaniumylidene)-1,5-dihydro-2,6-diaza-s-indacen-1-ylidene]bis(methyl)azanium tetrafluroborate

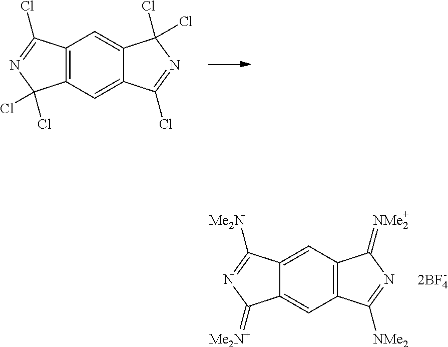

According to the procedure described in example DAI-1, using, dimethyltrimethylsilylamine instead of N,1,1,1-tetramethyl-N-phenylsilanamine, 3,7-Bis(dimethylamino)-5-(dimethylazaniumylidene)-1,5-dihydro-2,6-diaza-s-indacen-1-ylidene]bis(methyl)azanium tetrafluroborate was synthesized (64% yield).

¹H NMR (80 MHz, CD₃CN) δ 8.41 (s, 2H), 3.83 (s, 12H), 3.67 (s, 12H).

MS (APCI) (m/z): 327.1 ([C₁₈H₂₆N₆+H]⁺).

CV (ACN, E₀ vs. Fc/Fc⁺) E₀^{+2/+1}=−0.69 V; E₀^{+1/0}=−1.12 V.

### 1,3,5,7-Tetra(dimethylamino)-2,6-diaza-s-indacene

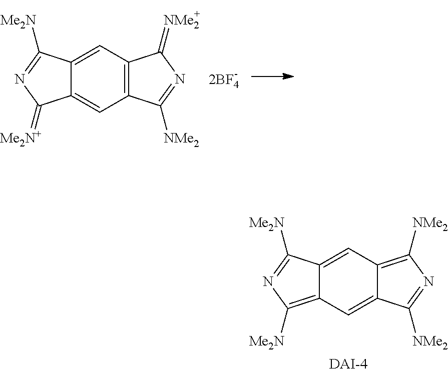

3,7-Bis(dimethylamino)-5-(dimethylazaniumylidene)-1,5-dihydro-2,6-diaza-s-indacen-1-ylidene]bis(methyl)azanium tetrafluroborate (3.22 g, 6.44 mmol), 125 ml dry THF and potassium (0.55 g, 14.1 mmol) were mixed. The reaction mixture was refluxed under nitrogen for 4 days. Then the THF was removed under vacuum and the solid residue was extracted with hot toluene using a Soxhlet extractor. After cooling down, the crystallized product was isolated by filtration (1.4 g, 4.29 mmol, 67%).

MS (APCI) (m/z): 327.5 ([C₁₈H₂₆N₆+H]⁺).

CV (ACN, E₀ vs. Fc/Fc⁺) E₀^{0/+1}=−1.13 V; E₀^{+1/+2}=−0.70 V.

### Synthesis of Example DAI-5

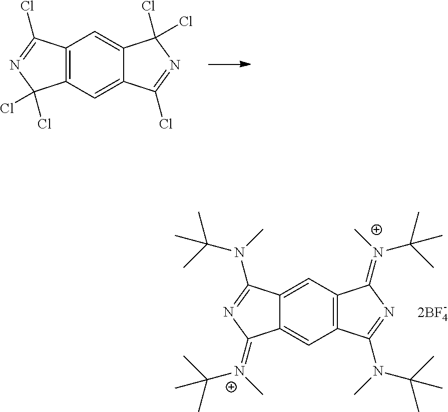

According to the procedure described in example DAI-1, using N-tert-butyl-N-methylaminotrimethylsilane instead of N,1,1,1-tetramethyl-N-phenylsilanamine, (Z)—{(Z)-5-[(tert-Butyl)(methyl)azaniumylidene]-3,7-bis[(tert-butyl)-N-methylamino]-1,5-dihydro-2,6-diaza-s-indacen-1-ylidene}(tert-butyl)(methyl)azanium tetrafluoroborate was synthesized (76% yield).

¹H NMR (80 MHz, DMSO-d₆) δ 8.43 (s, 2H), 3.84 (s, 12H), 1.68 (s, 36H).

MS (APCI) (m/z): 423.5 ([C₃₀H₅₀N₆—(CH₃)—(C(CH₃)₃)+H]⁺).

### 1,3,5,7-Tetra(methyl(tert-butyl)amino)-2,6-diaza-s-indacene

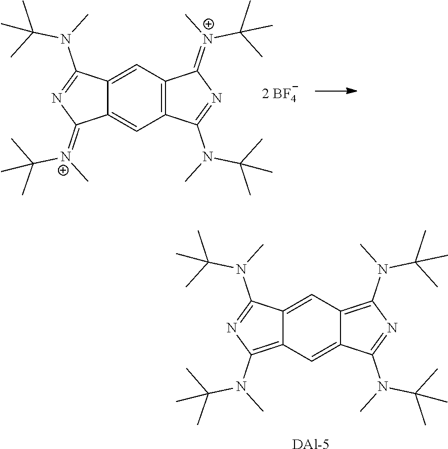

According to the procedure described in example DAI-1, using (Z)—{(Z)-5-[(tert-Butyl)(methyl)azaniumylidene]-3,7-bis[(tert-butyl)-N-methylamino]-1,5-dihydro-2,6-di-aza-s-indacen-1-ylidene}(tert-butyl)(methyl)azanium tetrafluoroborate instead of N,N′-((1Z,5Z)-3,7-bis(methyl(phenyl)amino) pyrrolo[3,4-f]isoindole-1,5-diylidene)bis(N-methylbenzenaminium)tetrafluoroborate, 1,3,5,7-Tetra(methyl(tert-butyl)amino)-2,6-di-aza-s-indacene was synthesized (54% yield).

¹H NMR (80 MHz, C₆D₆) δ 7.98 (s, 2H), 3.06 (s, 12H), 1.53 (s, 36H).

MS (APCI) (m/z): 495.5 ([C₃₀H₅₀N₆+H]⁺).

CV (ACN, E₀ VS. Fc/Fc⁺) E₀^{0/+1}=−1.04 V; E₀^{+1/+2}=−0.69 V.

### Synthesis of Example DAI-6

### (Z)-(3,7-Bis {N-methyl[p-(trifluoromethyl)phenyl]amino}(Z)—-5-{methyl[p-(trifluoromethyl)phenyl]azaniumylidene}-1,5-dihydro-2,6-diaza-s-indacen-1-ylidene)(methyl)[p-(tri-fluoromethyl)phenyl]azanium tetrafluoroborate

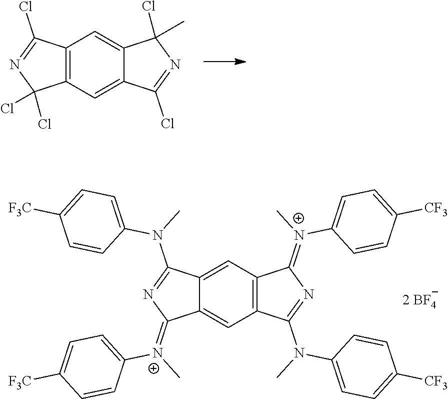 [SMILES: CC1(Cl)N=C(Cl)c2cc3c(cc21)C(Cl)=NC3(Cl)Cl ; CN(c1ccc(C(F)(F)F)cc1)c1n/c(=[N+](/C)c2ccc(C(F)(F)F)cc2)c2cc3c(N(C)c4ccc(C(F)(F)F)cc4)n/c(=[N+](/C)c4ccc(C(F)(F)F)cc4)c3cc12]

According to the procedure described in example DAI-1, using N,1,1,1-tetramethyl-N-(4-(trifluoromethyl)phenyl) silanamine instead of N,1,1,1-tetramethyl-N-phenylsilanamine, (Z)-(3,7-Bis {N-methyl[p-(trifluoromethyl)phenyl]amino}(Z)-5-{methyl[p-(trifluoro-methyl)phenyl]azaniumylidene}-1,5-dihydro-2,6-diaza-s-indacen-1-ylidene)(methyl)[p-(trifluoromethyl)phenyl]azanium tetrafluoroborate was synthesized (14% yield).

MS (APCI) (m/z): 846.4 ([C₄₂H₃₀F₁₂N₆]⁺).

CV (ACN, E₀ vs. Fc/Fc⁺) E₀^{+2/+1}=−0.33 V; E₀^{+1/0}=−0.61 V.

### 1,3,5,7-Tetrakis {N-methyl[p-(trifluoromethyl)phenyl]amino}-2,6-diaza-s-indacene

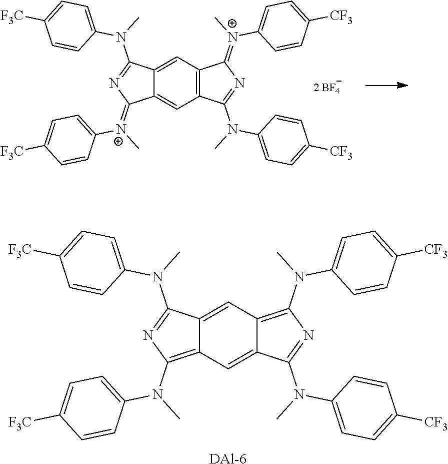 [SMILES: CN(c1ccc(C(F)(F)F)cc1)c1n/c(=[N+](/C)c2ccc(C(F)(F)F)cc2)c2cc3c(N(C)c4ccc(C(F)(F)F)cc4)n/c(=[N+](/C)c4ccc(C(F)(F)F)cc4)c3cc12 ; CN(C1=NC(N(C)c2ccc(C(F)(F)F)cc2)=c2cc3c(cc21)=C(N(C)c1ccc(C(F)(F)F)cc1)N=C3N(C)c1ccc(C(F)(F)F)cc1)c1ccc(C(F)(F)F)cc1 ; "DAl-6"]

According to the procedure described in example DAI-1, using (Z)-(3,7-Bis {N-methyl[p-(trifluoromethyl)phenyl]amino}(Z)-5-{methyl[p-(trifluoromethyl)phenyl]azaniumylidene}-1,5-dihydro-2,6-diaza-s-indacen-1-ylidene)(methyl)[p-(trifluoromethyl)phenyl]azanium tetrafluoroborate instead of N,N′-((1Z,5Z)-3,7-bis(methyl(phenyl)amino) pyrrolo[3,4-f]isoindole-1,5-diylidene)bis(N-methylbenzenaminium)tetrafluoroborate, 1,3,5,7-Tetrakis{N-methyl[p-(trifluoromethyl)phenyl]amino}-2,6-diaza-s-indacene was synthesized (30% yield).

MS (APCI) (m/z): 847.0 ([C₄₂H₃₀F₁₂N₆+H]⁺).

CV (ACN, E₀ vs. Fc/Fc⁺) E₀^{0/+1}=−0.64 V; E₀^{+1/+2}=−0.36 V.

### Preparation of Aryl and Acceptor substituted 2,6-Diazaindacenes

### Synthesis of Example DAI-7

### 2,5-Diphenyl-1H-pyrrole-3,4-dicarbaldehyde

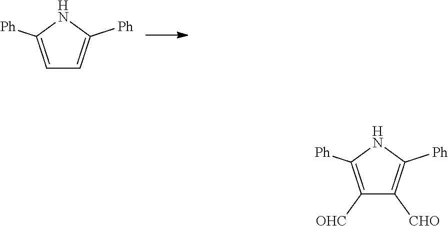 [SMILES: c1ccc(-c2ccc(-c3ccccc3)[nH]2)cc1 ; O=Cc1c(-c2ccccc2)[nH]c(-c2ccccc2)c1C=O]

2,5-Diphenyl-1H-pyrrole (1.0 g, 4.6 mmol), 5 ml dry toluene, DMF (2.2 ml, 29 mmol) and phosphoryl chloride (2.1 ml, 23 mmol) were mixed. The reaction mixture was heated to 100° C. for 16 h. The reaction mixture was cooled down and subsequently saturated sodium acetate solution was added. After stirring for 30 min at 90° C. a light brown solid precipitated. Then the solid was filtered and washed several times with water. After drying in vacuum, the title product was obtained as light brown solid (1.1 g, 4.0 mmol, 88%).

¹H NMR (300 MHz, acetone-d₆) δ 11.68 (br. s, 1H), 10.31 (s, 2H), 7.85-7.76 (m, 4H), 7.56-7.46 (m, 6H).

MS (APCI) (m/z): 276.0 ([C₁₈H₁₃NO₂+H]⁺).

### 1,3,5,7-Tetrakis(phenyl)-2,6-diaza-s-indacene

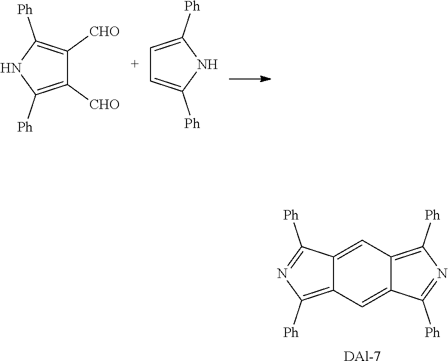 [SMILES: O=Cc1c(-c2ccccc2)[nH]c(-c2ccccc2)c1C=O ; c1ccc(-c2ccc(-c3ccccc3)[nH]2)cc1 ; c1ccc(C2=NC(c3ccccc3)=c3cc4c(cc32)=C(c2ccccc2)N=C4c2ccccc2)cc1 ; "DAl-7"]

2,5-diphenyl-1H-pyrrole (0.11 g, 0.50 mmol), 2,5-diphenyl-1H-pyrrole-3,4-dicarbaldehyde (0.14 g, 0.50 mmol), 5 ml dry dichloromethane and phosphoryl chloride (0.11 ml, 1.25 mmol) were mixed. The reaction mixture was stirred at room temperature for 5 days. Then the reaction mixture was diluted with dichloromethane and subsequently diisopropylethylamine (0.42 ml, 2.5 mmol) was added. After filtration through silica gel the solvent was removed under reduced pressure. The residue was washed with a mixture of n-hexane and ethyl acetate. After filtration, the pure product was isolated in form of green/brown crystals (0.033 g, 0.072 mmol, 14%).

¹H NMR (300 MHz, CD₂Cl₂) δ 8.29-6.68 (m, 22H).

MS (APCI) (m/z): 459.0 ([C₃₄H₂₂N₂+H]⁺).

CV (CH₂Cl₂, E₀ vs. Fc/Fc⁺) E₀^{0/-1}=−0.90 V; E₀^{0/+1}=0.67 V; E₀^{+1/+2}=1.01 V.

### Synthesis of Example DAI-8

1,4-Bis[4-biphenyl]-1,4-butandione was prepared according to a literature procedure from Xu, W.-L. et. al. Organic Letters 2020 22 (18), 7169-7174.

### 2,5-Di([1,1′-biphenyl]-4-yl)-1H-pyrrole

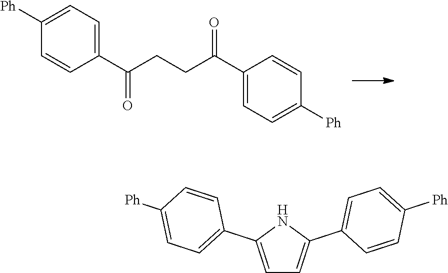 [SMILES: O=C(CCC(=O)c1ccc(-c2ccccc2)cc1)c1ccc(-c2ccccc2)cc1 ; c1ccc(-c2ccc(-c3ccc(-c4ccc(-c5ccccc5)cc4)[nH]3)cc2)cc1]

1,4-bis[4-biphenyl]-1,4-butandione (3.9 g, 10 mmol), ammonium acetate (6.9 g, 90 mmol) and 12 mL acetic acid were mixed. The reaction mixture was heated to 160° C. for 16 h and allowed to cool to room temperature. The crystals were filtered and washed several times with water and ethanol. After recrystallization from 1,2-dichlorobenzene the pure product was obtained as green crystals (3.5 g, 9.5 mmol, 95%).

¹H NMR (80 MHz, DMSO-d₆) δ 11.37 (s, 1H), 8.23-7.16 (m, 18H), 6.70 (s, 2H).

MS (APCI) (m/z): 372.0 ([C₂₈H₂₁N+H]⁺).

Melting point (DSC): 327° C.

### 2,5-Di([1,1′-biphenyl]-4-yl)-1H-pyrrole-3,4-dicarbaldehyde

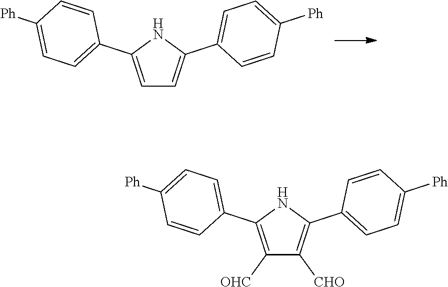 [SMILES: c1ccc(-c2ccc(-c3ccc(-c4ccc(-c5ccccc5)cc4)[nH]3)cc2)cc1 ; O=Cc1c(-c2ccc(-c3ccccc3)cc2)[nH]c(-c2ccc(-c3ccccc3)cc2)c1C=O]

According to the procedure described in example DAI-7, using 2,5-di([1,1′-biphenyl]-4-yl)-1H-pyrrole instead of 2,5-Diphenyl-1H-pyrrole, 2,5-Di([1,1′-biphenyl]-4-yl)-1H-pyrrole-3,4-dicarbaldehyde (88% yield).

¹H NMR (80 MHz, DMSO-d₆) δ 12.80 (s, 1H), 10.25 (s, 2H), 8.12-7.11 (m, 18H).

MS (APCI) (m/z): 428.3 ([C₃₀H₂₁NO₂+H]⁺).

### 1,3,5,7-Tetrakis(1,1′-biphenyl)-2,6-diaza-s-indacene

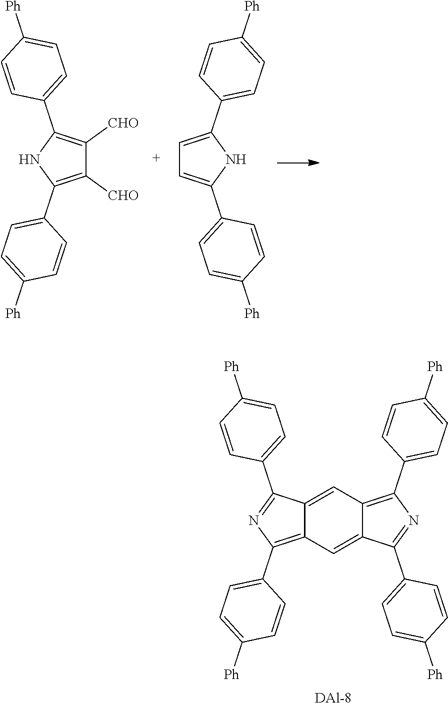 [SMILES: O=Cc1c(-c2ccc(-c3ccccc3)cc2)[nH]c(-c2ccc(-c3ccccc3)cc2)c1C=O ; c1ccc(-c2ccc(-c3ccc(-c4ccc(-c5ccccc5)cc4)[nH]3)cc2)cc1 ; c1ccc(-c2ccc(C3=NC(c4ccc(-c5ccccc5)cc4)=c4cc5c(cc43)=C(c3ccc(-c4ccccc4)cc3)N=C5c3ccc(-c4ccccc4)cc3)cc2)cc1 ; "DAl-8"]

2,5-di([1,1′-biphenyl]-4-yl)-1H-pyrrole (2.6 g, 7 mmol), 2,5-di([1,1′-biphenyl]-4-yl)-1H-pyrrole-3,4-dicarbaldehyde (3.0 g, 7 mmol), 70 ml 1,2-dichlorobenzene and phosphoryl chloride (1.6 ml, 17.5 mmol) were mixed. The reaction mixture was stirred at 180° C. for 4 days. Then the reaction mixture was cooled down and subsequently diisopropylethylamine (6.1 ml, 35 mmol) was added. The precipitate was filtered and recrystallized from 1,2-dichlorobenzene (0.66 g, 0.86 mmol, 12%)

MS (APCI) (m/z): 763.5 ([C₅₈H₃₈N₂+H]⁺).

Melting point (DSC): 362° C.

### Synthesis of Example DAI-9

### 1,4-Bis(3,5-bis(trifluoromethyl)phenyl) butane-1,4-dione

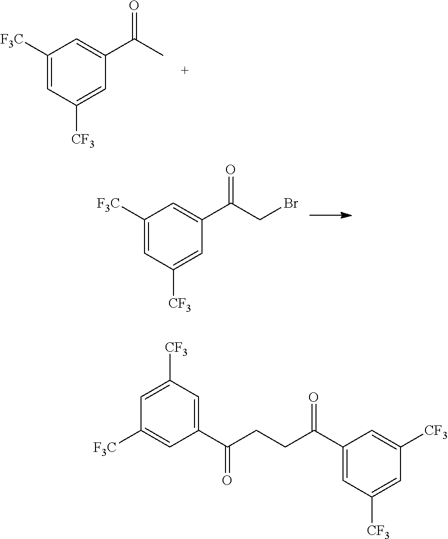

1,4-Bis(3,5-bis(trifluoromethyl)phenyl) butane-1,4-dione was prepared according to a literature procedure from A. P. Brucks et. al. Synthesis 2013, 45, 1886-1898

### 2,5-Bis(3,5-bis(trifluoromethyl)phenyl)-1H-pyrrole

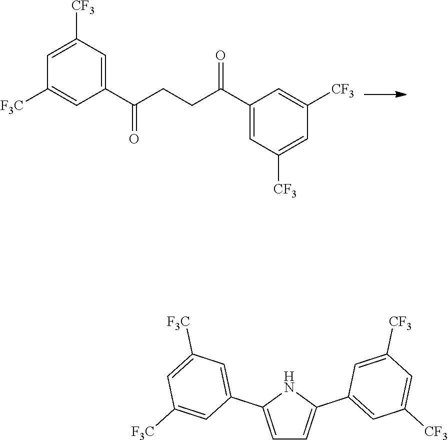 [SMILES: O=C(CCC(=O)c1cc(C(F)(F)F)cc(C(F)(F)F)c1)c1cc(C(F)(F)F)cc(C(F)(F)F)c1 ; FC(F)(F)c1cc(-c2ccc(-c3cc(C(F)(F)F)cc(C(F)(F)F)c3)[nH]2)cc(C(F)(F)F)c1]

According to the procedure described in example DAI-7, using 1,4-bis(3,5-bis(trifluoro-methyl)phenyl) butane-1,4-dione instead of 1,4-bis[4-biphenyl]-1,4-butandione, 2,5-Bis(3,5-bis(trifluoromethyl)phenyl)-1H-pyrrole was obtained (82% yield).

¹H NMR (80 MHz, CDCl₃) δ 10.12 (s, 1H), 8.06 (s, 4H), 7.71 (s, 2H), 6.77 (d, J=2.6 Hz, 2H).

MS (APCI) (m/z): 491.3 ([C₂₀H₉F₁₂N+H]⁺).

### 2,5-Bis(3,5-bis(trifluoromethyl)phenyl)-1H-pyrrole-3-carbaldehyde

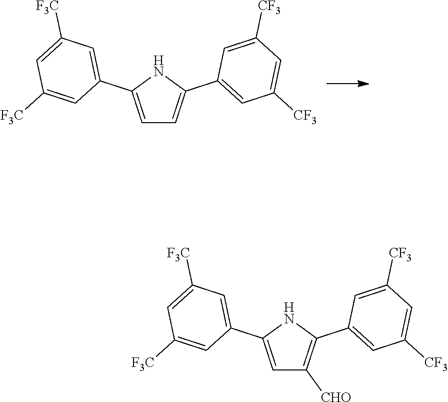 [SMILES: FC(F)(F)c1cc(-c2ccc(-c3cc(C(F)(F)F)cc(C(F)(F)F)c3)[nH]2)cc(C(F)(F)F)c1 ; O=Cc1cc(-c2cc(C(F)(F)F)cc(C(F)(F)F)c2)[nH]c1-c1cc(C(F)(F)F)cc(C(F)(F)F)c1]

2,5-bis(3,5-bis(trifluoromethyl)phenyl)-1H-pyrrole (2 g, 4 mmol), 4 ml dry toluene, DMF (1.9 ml, 25 mmol) and phosphoryl chloride (1.8 ml, 20 mmol) were mixed. The reaction mixture was heated to 100° C. for 1 day and then was cooled down to room temperature and filtered. The solid was dissolved in DMSO and a 1 M sodium hydroxide solution was added. The solution was stirred for 3 weeks at room temperature. After that the solution was transferred into a separation funnel and diethyl ether and water was added. The organic phase was separated, washed several times with water and then dried with anhydrous sodium sulfate. After filtration of the salt and evaporation of the solvent the crude product was recrystallized from toluene (1.5 g, 2.9 mmol, 72%).

¹H NMR (80 MHz, DMSO-d₆) δ 12.63 (s, 1H), 9.77 (s, 1H), 8.50 (s, 4H), 8.19 (s, 1H), 7.94 (s, 1H), 7.57 (s, 1H).

MS (APCI) (m/z): 520.3 ([C₂₁H₉F₁₂NO+H]⁺).

### 1,3,5,7-Tetrakis(3,5-bis(trifluoromethyl)phenyl)-2,6-diaza-s-indacene

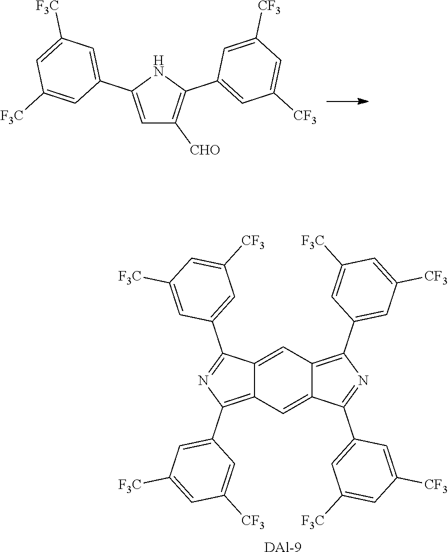

2,5-bis(3,5-bis(trifluoromethyl)phenyl)-1H-pyrrole-3-carbaldehyde (65 mg, 0.125 mmol), 0.5 ml dry 1,2-dichloroethane and phosphoryl chloride (0.01 ml, 0.125 mmol) were mixed. The reaction mixture was stirred at 84° C. for 1 day. Then the reaction mixture was cooled down, diluted with dichloromethane and subsequently triethylamine (0.1 ml) was added. The precipitate was filtered and dried to give a dark purple solid (55 mg, 55 μmol, 88%).

MS (APCI) (m/z): 1003.4 ([C₄₂H₁₄F₂₄N₂+H]⁺).

CV (CH₂Cl₂, E₀ vs. Fc/Fc⁺) E₀^{0/-1}=−0.49 V

### Synthesis of Example DAI-10

1-(3′,5′-Bis(trifluoromethyl)-[1,1′-biphenyl]-4-yl) ethan-1-one was prepared according to a literature procedure from Feuerstein, M. et. al. Synlett 2002, 11, 1807-1810.

### 1-(3′,5′-Bis(trifluoromethyl)-[1,1′-biphenyl]-4-yl)-2-bromoethan-1-one

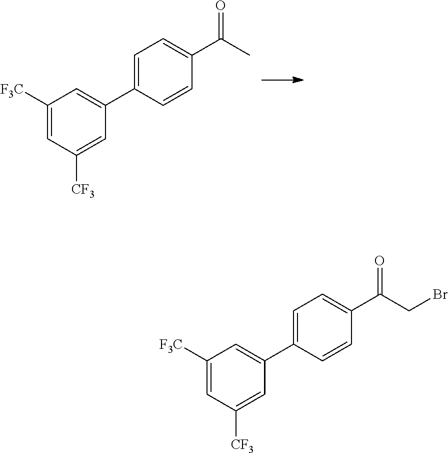 [SMILES: CC(=O)c1ccc(-c2cc(C(F)(F)F)cc(C(F)(F)F)c2)cc1 ; O=C(CBr)c1ccc(-c2cc(C(F)(F)F)cc(C(F)(F)F)c2)cc1]

1-(3′,5′-bis(trifluoromethyl)-[1,1′-biphenyl]-4-yl) ethan-1-one (12.5 g, 38 mmol), 40 ml diethyl ether and 20 ml 1,4-dioxane were mixed. Bromine (2 ml, 39 mmol) was added dropwise to this suspension. The reaction mixture was stirred over night at room temperature. A solution of sodium sulfite and then diethyl ether was added. The organic phase was separated, and then dried with anhydrous sodium sulfate. After filtration of the salt and evaporation of the solvent the product was isolated as colorless crystals (15.6 g, 38 mmol, 100%).

¹H NMR (80 MHz, acetone-d₆) δ 8.32-7.94 (m, 7H), 4.82 (s, 2H).

MS (APCI) (m/z): 410.9 ([C₁₆H₉⁷⁹BrF₆O+H]⁺).

### 1,4-Bis(3′,5′-bis(trifluoromethyl)-[1,1′-biphenyl]-4-yl) butane-1,4-dione

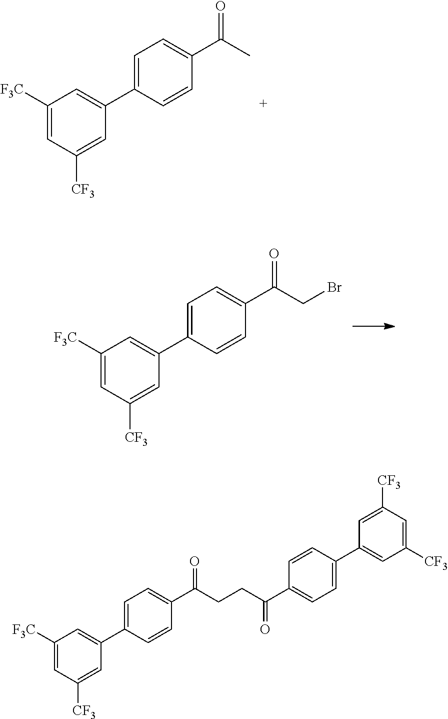 [SMILES: CC(=O)c1ccc(-c2cc(C(F)(F)F)cc(C(F)(F)F)c2)cc1 ; O=C(CBr)c1ccc(-c2cc(C(F)(F)F)cc(C(F)(F)F)c2)cc1 ; O=C(CCC(=O)c1ccc(-c2cc(C(F)(F)F)cc(C(F)(F)F)c2)cc1)c1ccc(-c2cc(C(F)(F)F)cc(C(F)(F)F)c2)cc1]

Anhydrous zinc chloride (12.5 g, 91.25 mmol) was melted under vacuum. After cooling down to room temperature, 30 ml toluene, diethylamine (7.5 ml, 73 mmol) and tert-Butyl alcohol (5 ml, 78 mmol) were added. The reaction mixture was stirred at room temperature for 2 h. Then 1-(3′,5′-bis(trifluoromethyl)-[1,1′-biphenyl]-4-yl)-2-bromoethan-1-one (15 g, 36.5 mmol) and 1-(3′,5′-bis(trifluoromethyl)-[1,1′-biphenyl]-4-yl) ethan-1-one (12 g, 36 mmol) were added. The reaction mixture was stirred over night at room temperature. The precipitated colorless solid was filtered and washed with 5% H₂SO₄-solution, water and ethanol. Recrystallization from acetic acid led to the isolation of the pure product (14.3 g, 21.6 mmol, 60%).

MS (APCI) (m/z): 663.1 ([C₃₂H₁₈F₁₂O₂+H]⁺).

### 2,5-bis(3′,5′-bis(trifluoromethyl)-[1,1′-biphenyl]-4-yl)-1H-pyrrole

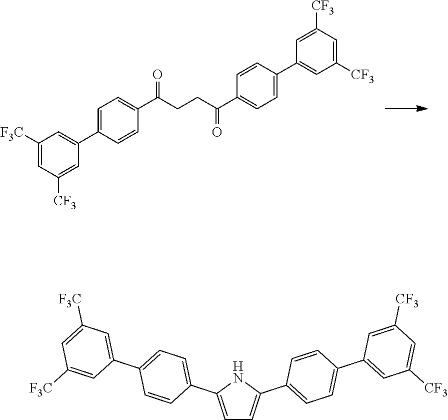 [SMILES: O=C(CCC(=O)c1ccc(-c2cc(C(F)(F)F)cc(C(F)(F)F)c2)cc1)c1ccc(-c2cc(C(F)(F)F)cc(C(F)(F)F)c2)cc1 ; FC(F)(F)c1cc(-c2ccc(-c3ccc(-c4ccc(-c5cc(C(F)(F)F)cc(C(F)(F)F)c5)cc4)[nH]3)cc2)cc(C(F)(F)F)c1]

1,4-bis(3′,5′-bis(trifluoromethyl)-[1,1′-biphenyl]-4-yl) butane-1,4-dione (14.8 g, 22 mmol), ammonium acetate (22.6 g, 293 mmol) and 50 ml acetic acid were mixed. The reaction mixture was heated to 150° C. for 16 h. During cooling to room temperature the crude product was crystallizing. The crystals were filtered and washed several times with water. After crystallization with ethanol the pure product was obtained as yellow-green crystals (12.2 g, 19 mmol, 86%).

¹H NMR (80 MHz, CD₂Cl₂) δ 8.85 (s, 1H), 8.11 (s, 4H), 7.89 (s, 2H), 7.73 (s, 8H), 6.75 (d, J=2.5 Hz, 2H).

MS (APCI) (m/z): 644.2 ([C₃₂H₁₇F₁₂N+H]⁺).

### 2,5-bis(3′,5′-bis(trifluoromethyl)-[1,1′-biphenyl]-4-yl)-1H-pyrrole-3-carbaldehyde

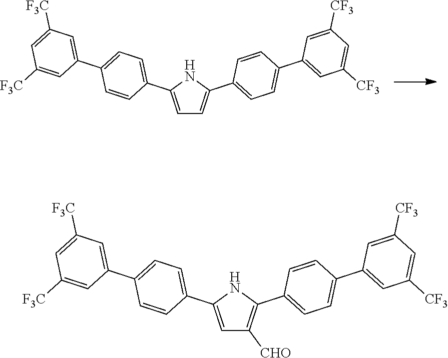 [SMILES: FC(F)(F)c1cc(-c2ccc(-c3ccc(-c4ccc(-c5cc(C(F)(F)F)cc(C(F)(F)F)c5)cc4)[nH]3)cc2)cc(C(F)(F)F)c1 ; O=Cc1cc(-c2ccc(-c3cc(C(F)(F)F)cc(C(F)(F)F)c3)cc2)[nH]c1-c1ccc(-c2cc(C(F)(F)F)cc(C(F)(F)F)c2)cc1]

2,5-bis(3′,5′-bis(trifluoromethyl)-[1,1′-biphenyl]-4-yl)-1H-pyrrole (12 g, 18.65 mmol), 75 ml dry toluene, DMF (2.15 ml, 17.45 mmol) and phosphoryl chloride (2.0 ml, 28 mmol) were mixed. The reaction mixture was heated to 100° C. for 3 h. The reaction mixture was cooled down and the yellow-green precipitate was filtered. The solid was dissolved in DMSO and a 1 M sodium hydroxide solution was added. The solution was stirred for 3 days at 60° C. After that the solution was transferred into a separation funnel, ethyl acetate and water were added. The organic phase was separated, washed several times with water and then dried with anhydrous sodium sulfate. After filtration of the salt and evaporation of the solvent the product was isolated in form of yellow-green solid (9.7 g, 14.4 mmol, 77%).

¹H NMR (80 MHz, acetone-d₆) δ 11.60 (s, 1H), 9.98 (s, 1H), 8.37 (s, 4H), 8.20-7.80 (m, 10H), 7.18 (s, 1H).

MS (APCI) (m/z): 671.8 ([C₃₃H₁₇F₁₂NO+H]⁺).

### 1,3,5,7-Tetrakis(3′,5′-bis(trifluoromethyl)-[1,1′-biphenyl]-4-yl)-2,6-diaza-s-indacene

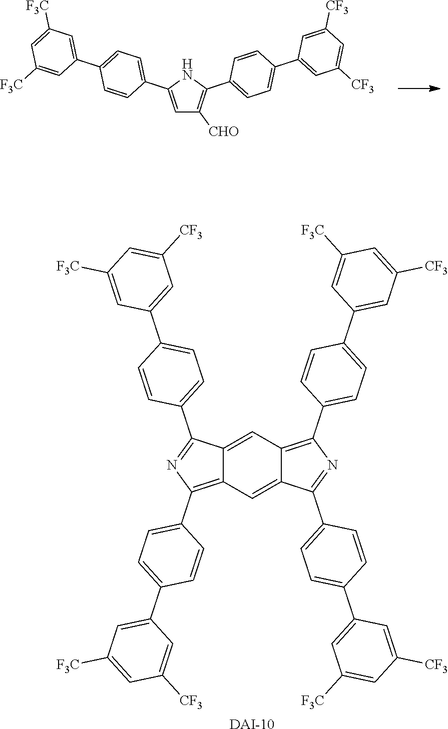

2,5-bis(3′,5′-bis(trifluoromethyl)-[1,1′-biphenyl]-4-yl)-1H-pyrrole-3-carbaldehyde (2.52 mg, 3.75 mmol), 19 ml dry toluene and phosphoryl chloride (0.34 ml, 3.75 mmol) were mixed. The reaction mixture was stirred at 100° C. for 1 day. Then the reaction mixture was cooled down, diluted with dichloromethane and subsequently triethylamine (3 ml) was added. The precipitate was filtered, dried and was recrystallized from 1,2-dichlorobenzene (1.94 g, 1.48 mmol, 79%).

MS (APCI) (m/z): 1306.7 ([C₆H₃₀F₂₄N₂+H]⁺).

CV (THF, E₀ vs. Fc/Fc⁺) E₀^{0/-1}=−0.83 V.

DSC: decomposition >400° C.

### Synthesis of Example DAI-11

### 1,4-Bis(2,6-bis(trifluoromethyl)pyridin-4-yl) butane-1,4-dione

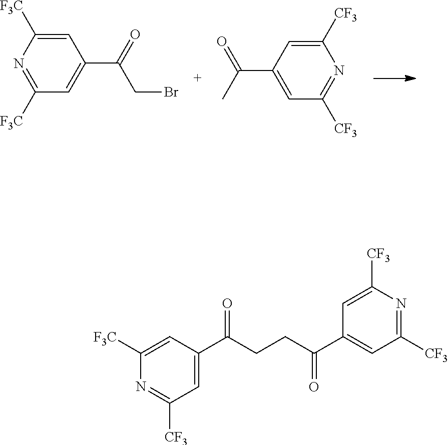 [SMILES: O=C(CBr)c1cc(C(F)(F)F)nc(C(F)(F)F)c1 ; CC(=O)c1cc(C(F)(F)F)nc(C(F)(F)F)c1 ; O=C(CCC(=O)c1cc(C(F)(F)F)nc(C(F)(F)F)c1)c1cc(C(F)(F)F)nc(C(F)(F)F)c1]

According to the procedure described in example DAI-7, using 1-(2,6-bis(trifluoromethyl)pyridin-4-yl)-2-bromoethan-1-one and 1-(2,6-bis(trifluoromethyl)pyridin-4-yl) ethan-1-one instead of 1-(3′,5′-bis(trifluoromethyl)-[1,1′-biphenyl]-4-yl)-2-bromoethan-1-one and and 1-(3′,5′-bis(trifluoromethyl)-[1,1′-biphenyl]-4-yl) ethan-1-one, 1,4-Bis(2,6-bis(trifluoromethyl)pyridin-4-yl) butane-1,4-dione was obtained (39% yield).

¹H NMR (80 MHz, CDCl₃) δ 8.36 (s, 4H), 3.58 (s, 4H).

MS (APCI) (m/z): 513.0 ([C₁₈H₈F₁₂N₂O₂+H]⁺).

### 2,5-Bis(2,6-bis(trifluoromethyl)pyridin-4-yl)-1H-pyrrole

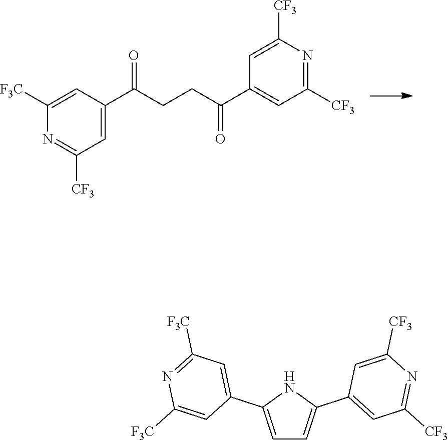 [SMILES: O=C(CCC(=O)c1cc(C(F)(F)F)nc(C(F)(F)F)c1)c1cc(C(F)(F)F)nc(C(F)(F)F)c1 ; FC(F)(F)c1cc(-c2ccc(-c3cc(C(F)(F)F)nc(C(F)(F)F)c3)[nH]2)cc(C(F)(F)F)n1]

According to the procedure described in example DAI-7, using 1,4-bis(2,6-bis(trifluoro-methyl)pyridin-4-yl) butane-1,4-dione instead of 1,4-bis(3′,5′-bis(trifluoromethyl)-[1,1′-biphenyl]-4-yl) butane-1,4-dione, 2,5-Bis(2,6-bis(trifluoromethyl)pyridin-4-yl)-1H-pyrrole was obtained (55% yield).

¹H NMR (80 MHz, DMSO-d₆) δ 12.33 (s, 1H), 8.55 (s, 4H), 7.47 (d, J=2.3 Hz, 2H).

MS (APCI) (m/z): 493.9 ([C₁₈H₇F₁₂N₃+H]⁺).

### 2,5-Bis(2,6-bis(trifluoromethyl)pyridin-4-yl)-1H-pyrrole-3-carbaldehyde

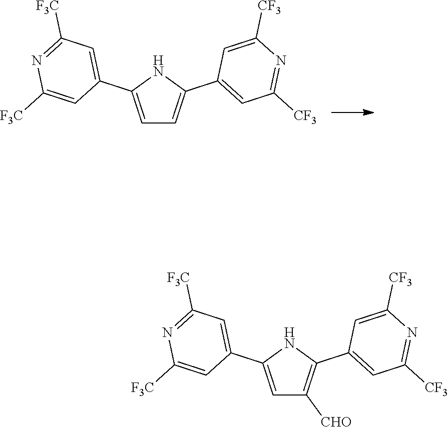 [SMILES: FC(F)(F)c1cc(-c2ccc(-c3cc(C(F)(F)F)nc(C(F)(F)F)c3)[nH]2)cc(C(F)(F)F)n1 ; O=Cc1cc(-c2cc(C(F)(F)F)nc(C(F)(F)F)c2)[nH]c1-c1cc(C(F)(F)F)nc(C(F)(F)F)c1]

According to the procedure described in example DAI-7, using 2,5-bis(2,6-bis(trifluoro-methyl)pyridin-4-yl)-1H-pyrrole instead of 2,5-bis(3′,5′-bis(trifluoromethyl)-[1,1′-biphenyl]-4-yl)-1H-pyrrole, 2,5-Bis(2,6-bis(trifluoromethyl)pyridin-4-yl)-1H-pyrrole-3-carbaldehyde was obtained (64% yield).

¹H NMR (80 MHz, DMSO-d₆) δ 13.06 (s, 1H), 9.93 (s, 1H), 8.72 (d, J=2.6 Hz, 4H), 8.03 (s, 1H).

MS (APCI) (m/z): 522.2 ([C₁₉H₇F₁₂N₃O+H]⁺).

### 1,3,5,7-Tetrakis(2,6-bis(trifluoromethyl)pyridin-4-yl)-2,6-diaza-s-indacene

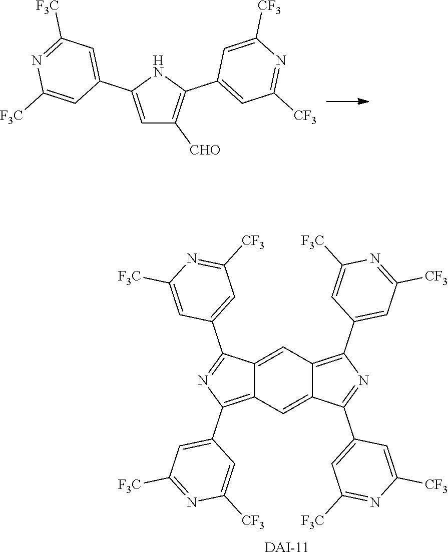

2,5-Bis(2,6-bis(trifluoromethyl)pyridin-4-yl)-1H-pyrrole-3-carbaldehyde (65 mg, 0.125 mmol), 0.5 ml dry tetrachloroethene and phosphoryl chloride (0.011 ml, 0.125 mmol) were mixed. The reaction mixture was stirred at 125° C. for 6 days. Then the reaction mixture was cooled down, diluted with dichloromethane and subsequently triethylamine (0.1 ml) was added. The precipitate was filtered and dried. The dark purple crude product was characterized by mass spectrometry (1 mg, 1 μmol, 1%).

MS (APCI) (m/z): 1008.7 ([C₃₈H₁₀F₂₄N₆+H]⁺).

### Synthesis of Example DAI-12

### 1,1′-(3,7-di(pyrrolidin-1-yl) pyrrolo[3,4-f]isoindole-1,5-diylidene)bis(pyrrolidin-1-ium)tetrafluroborate

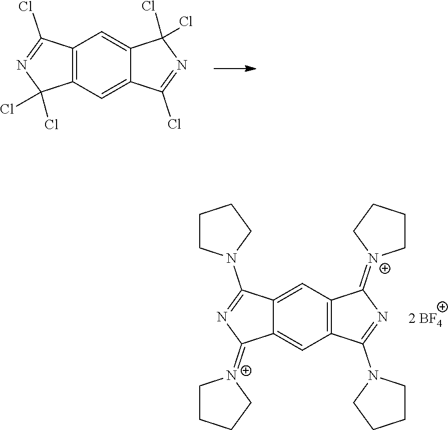 [SMILES: ClC1=NC(Cl)(Cl)c2cc3c(cc21)C(Cl)(Cl)N=C3Cl ; c1c2c(N3CCCC3)nc(=[N+]3CCCC3)c2cc2c(N3CCCC3)nc(=[N+]3CCCC3)c12]

1,1,3,5,5,7-Hexachloro-2,6-diaza-1,5-dihydroindacene (3.0 g, 8.2 mmol) and 82 ml dry THF were mixed. After cooling down to −78° C., 1-(trimethylsilyl) pyrrolidine (5.9 g, 41 mmol) was added. The reaction mixture was slowly warmed up to room temperature overnight. The green precipitate was filtered and then dissolved in acetonitrile. Then sodium tetrafluoroborate (5.5 g, 50 mmol) was added. The suspension was stirred at room temperature for 1 day. After that, the solvent was removed under reduced pressure to give a dark green solid (1.66 g, 2.75 mmol, 33%).

¹H NMR (80 MHz, ACN-d₃) δ 8.25 (s, 2H), 4.54-3.72 (m, 16H), 2.53-2.02 (m, 16H).

### 1,3,5,7-tetra(pyrrolidin-1-yl) pyrrolo[3,4-f]isoindole

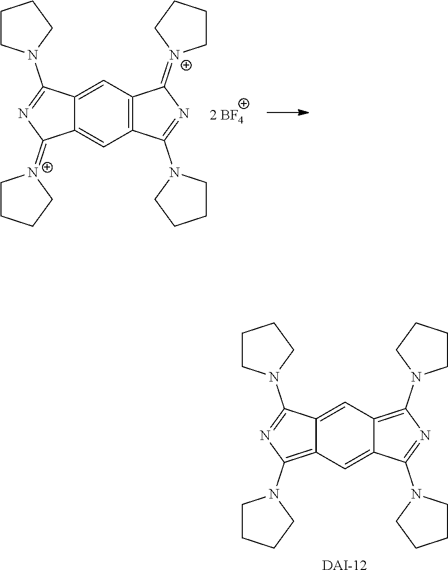

1,1′-(3,7-di(pyrrolidin-1-yl) pyrrolo[3,4-f]isoindole-1,5-diylidene)bis(pyrrolidin-1-ium)tetrafluroborate (1.2 g, 2 mmol), 75 ml dry THF and potassium (0.19 g, 4.9 mmol) were mixed. The reaction mixture was refluxed under nitrogen for 1 day, after which the potassium was consumed and the reaction solution turned dark blue. Then THF was removed under vacuum and the solid residue was extracted with hot toluene. After cooling down und removal of the solvent, the crystalline product could be isolated (0.05 g, 0.11 mmol, 6%).

CV (ACN, E₀ vs. Fc/Fc⁺) E₀^{0/+1}=−1.2 V; E₀^{+1/+2}=−0.75 V.

### Synthesis of Example DAI-13

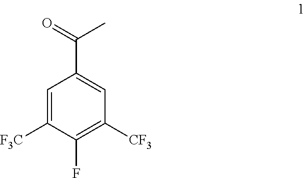 [SMILES: CC(=O)c1cc(C(F)(F)F)c(F)c(C(F)(F)F)c1]

Acetophenone 1 is commercially available (HE Chemical, CAS 1807120-08-6).

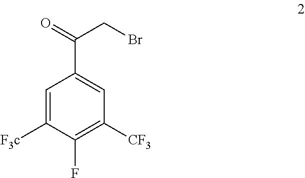

α-Bromoketone 2 is commercially available (HE Chemical, CAS 1805215-76-2).

### 1,4-bis[4-fluoro-3,5-bis(trifluoromethyl)phenyl]butane-1,4-dione

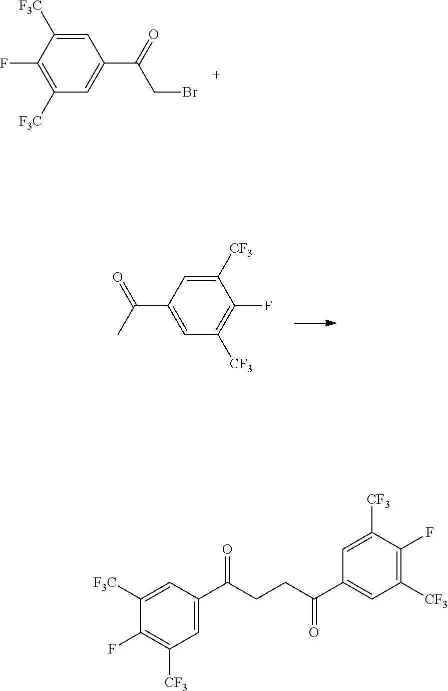 [SMILES: O=C(CBr)c1cc(C(F)(F)F)c(F)c(C(F)(F)F)c1 ; CC(=O)c1cc(C(F)(F)F)c(F)c(C(F)(F)F)c1 ; O=C(CCC(=O)c1cc(C(F)(F)F)c(F)c(C(F)(F)F)c1)c1cc(C(F)(F)F)c(F)c(C(F)(F)F)c1]

According to the procedure described in example DAI-7, using 2-bromo-1-[4-fluoro-3,5-bis(trifluoromethyl)phenyl]ethan-1-one and 1-[4-fluoro-3,5-bis(trifluoromethyl)phenyl]ethan-1-one instead of 1-(3′,5′-bis(trifluoromethyl)-[1,1′-biphenyl]-4-yl)-2-bromo-ethan-1-one and 1-(3′,5′-bis(trifluoromethyl)-[1,1′-biphenyl]-4-yl) ethan-1-one, 1,4-bis[4-fluoro-3,5-bis(trifluoromethyl)phenyl]butane-1,4-dione was obtained (81% yield).

MS (APCI) (m/z): 547.7 ([C₂₀H₈F₁₄O₂+H]⁺).

### 2,5-bis[4-fluoro-3,5-bis(trifluoromethyl)phenyl]pyrrole

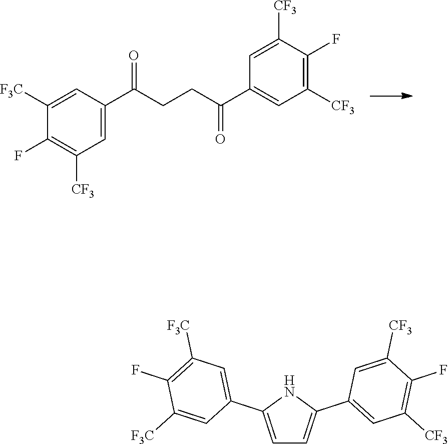 [SMILES: O=C(CCC(=O)c1cc(C(F)(F)F)c(F)c(C(F)(F)F)c1)c1cc(C(F)(F)F)c(F)c(C(F)(F)F)c1 ; Fc1c(C(F)(F)F)cc(-c2ccc(-c3cc(C(F)(F)F)c(F)c(C(F)(F)F)c3)[nH]2)cc1C(F)(F)F]

A mixture of 1,4-bis[4-fluoro-3,5-bis(trifluoromethyl)phenyl]butane-1,4-dione (5.87 g, 10.75 mmol) and ammonium acetate (1.66 g, 21.54 mmol) in ethanol (18 mL) was heated to reflux in a nitrogen atmosphere for 2 h. The resulting brown solution was transferred to a separatory funnel (Et₂O). Water (80 mL) was added and the aqueous layer was washed with Et₂O (3×50 mL). The combined organic layers were washed with saturated aqueous NaCl solution (50 mL), dried over MgSO₄ and the solvent was removed. The crude product was purified by column chromatography (silica gel; petroleum ether/diethyl ether, 100:1 to 100:9) to obtain 2,5-bis[4-fluoro-3,5-bis(trifluoromethyl)phenyl]pyrrole (4.63 g, 8.78 mmol, 82%) as a white solid.

MS (APCI) (m/z): 527.1 ([C₂₀H₇F₁₄N]⁺).

### 2,5-bis[4-fluoro-3,5-bis(trifluoromethyl)phenyl]pyrrole-3-carbaldehyde

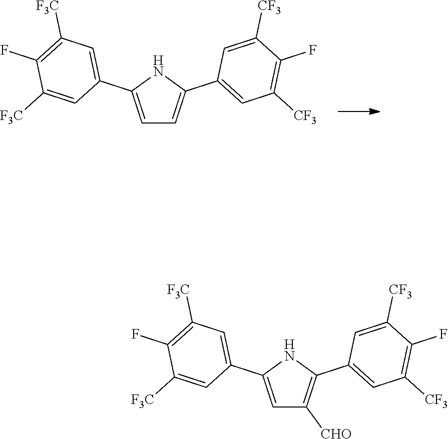 [SMILES: Fc1c(C(F)(F)F)cc(-c2ccc(-c3cc(C(F)(F)F)c(F)c(C(F)(F)F)c3)[nH]2)cc1C(F)(F)F ; O=Cc1cc(-c2cc(C(F)(F)F)c(F)c(C(F)(F)F)c2)[nH]c1-c1cc(C(F)(F)F)c(F)c(C(F)(F)F)c1]

2,5-bis[4-fluoro-3,5-bis(trifluoromethyl)phenyl]pyrrole (2.90 g, 5.5 mmol) was suspended in DMF (15 mL) under nitrogen atmosphere and POCl₃ (0.62 mL) was added dropwise. The resulting mixture was heated to 100° C. for 3 h. Water (7 mL) was added and the mixture stirred at 40° C. overnight. More water (100 mL) was added and the mixture washed with diethyl ether (3×50 mL). The combined organic phases were washed with sat. aq. NaCl solution (50 mL), dried with MgSO₄ and the solvents removed under reduced pressure. The crude product was washed with PE/Et₂O (5:1, 2×60 mL) and with PE (3×50 mL) to yield 2.68 g (4.8 mmol, 87%) of 2,5-bis[4-fluoro-3,5-bis(trifluoromethyl)phenyl]pyrrole-3-carbaldehyde.

MS (APCI) (m/z): 556.0 ([C₂₁H₇F₁₄NO+H]⁺).

### 1,3,5,7-tetrakis[4-fluoro-3,5-bis(trifluoromethyl)phenyl]-2,6-diaza-s-indacene

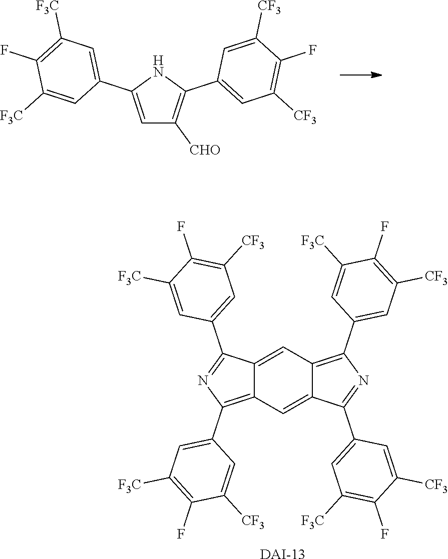

2,5-bis[4-fluoro-3,5-bis(trifluoromethyl)phenyl]pyrrole-3-carbaldehyde (1.32 g, 2.38 mmol) and potassium carbonate (3.35 g, 24.24 mmol) were placed in a Schlenk flask and phosphoryl chloride (20 mL) was added slowly. The mixture was heated to 100° C. for 3.5 h. The phosphoryl chloride was distilled off and the residue was treated with THF (40 mL). The solid was filtered off and the solvent was removed. The resulting residue was treated with Et₂O (50 mL) and the undissolved solids were filtered off. The solvent was removed and the crude product was purified by sublimation (10E-6 mbar, 250° C.) to obtain 1,3,5,7-tetrakis[4-fluoro-3,5-bis(trifluoromethyl)phenyl]-2,6-diaza-s-indacene (24 mg, 22 μmol, 1%) as a dark solid.

MS (APCI) (m/z): 1075.0 ([C₄₂H₁₀F₂₈N₂+H]⁺).

CV (ACN, E₀ vs. Fc/Fc⁺) E₀^{0/-1}=+0.50 V, E₀^{-1/-2}=+0.26 V.

### Synthesis of Example DAI-14

### 1,3,5,7-tetrakis[3,5-bis(trifluoromethyl)phenyl]-4,8-bis(trifluoromethyl)-2,4,6,8-tetrahydro-2,6-diaza-s-indacene

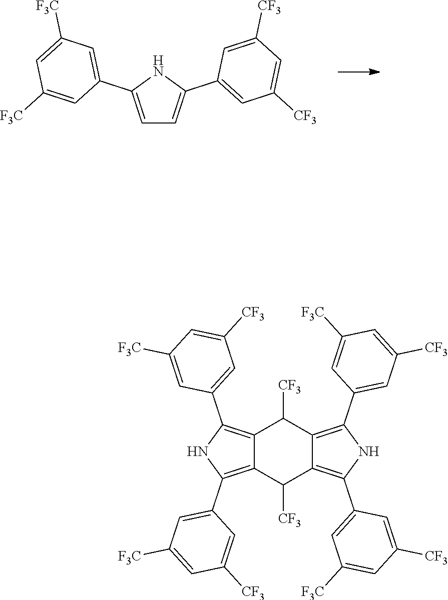 [SMILES: FC(F)(F)c1cc(-c2ccc(-c3cc(C(F)(F)F)cc(C(F)(F)F)c3)[nH]2)cc(C(F)(F)F)c1 ; FC(F)(F)c1cc(-c2[nH]c(-c3cc(C(F)(F)F)cc(C(F)(F)F)c3)c3c2C(C(F)(F)F)c2c(-c4cc(C(F)(F)F)cc(C(F)(F)F)c4)[nH]c(-c4cc(C(F)(F)F)cc(C(F)(F)F)c4)c2C3C(F)(F)F)cc(C(F)(F)F)c1]

2,5-bis[3,5-bis(trifluoromethyl)phenyl]pyrrole (1.5 g, 3 mmol) was placed in a micro-wave vial, CH₂Cl₂ (5 mL) was added followed BF₃·Et₂O (0.4 mL) and trifluoroacetaldehyde ethyl hemiacetale (0.4 mL) and the resulting mixture was stirred overnight at ambient temperature. The next morning BF₃·Et₂O (0.4 mL) and trifluoroacetaldehyde ethyl hemiacetale (0.4 mL) were added and stirring continued for nine days. The solvents were removed under reduced pressure and the crude product recrystallized from ethanol and water to yield 420 mg (0.37 mmol, 25%) of 1,3,5,7-tetrakis[3,5-bis(trifluoromethyl)phenyl]-4,8-bis(trifluoromethyl)-2,4,6,8-tetrahydro-2,6-diaza-s-indacene as a white solid.

MS (APCI) (m/z): 1143.2 ([C₄₄H₁₆F₃₀N₂+H]⁺).

### 1,3,5,7-tetrakis[3,5-bis(trifluoromethyl)phenyl]-4,8-bis(trifluoromethyl)-2,6-diaza-s-indacene

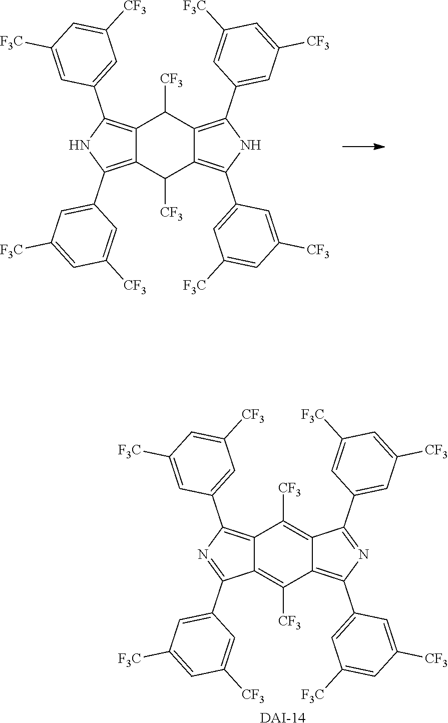

A mixture of 1,3,5,7-tetrakis[3,5-bis(trifluoromethyl)phenyl]-4,8-bis(trifluoromethyl)-2,4,6,8-tetrahydro-2,6-diaza-s-indacene (893 mg, 782 μmol), N-bromosuccinimide (556 mg, 3.12 mmol), potassium carbonate (864 mg, 6.25 mmol) and AlBN (6.4 mg, 39 μmol) in CCl₄ (10 mL) was heated under an argon atmosphere to reflux for 24 h. The solids were filtered off and the solvent evaporated to yield 450 mg (390 μmol, 50%) of 1,3,5,7-tetrakis[3,5-bis(trifluoromethyl)phenyl]-4,8-bis(trifluoromethyl)-2,6-diaza-s-indacene as a green solid.

MS (APCI) (m/z): 1139.2 ([C₄₄H₁₂F₃₀N₂+H]⁺).

CV (ACN, E₀ vs. Fc/Fc⁺) E₀^{0/-1}=+0.11 V, E₀^{-1/-2}=−0.31 V.

### Sample Preparation and Conductivity Measurement:

All layer were fabricated by thermal evaporation at room temperature under ultrahigh vacuum conditions (base pressure <5×10-7 mbar) by controlling the evaporation rates with quartz crystal microbalances (QCMs). 1 nm Cr and 50 nm Au were deposited through a shadow mask on a glass substrate to form interdigitated electrode patterns with 200-500 μm channel length. To prepare 30 nm thick doped layers with a specific doping ratio, a n-dopant was co-evaporated with an electron transport material (ETM), while the individual deposition rates were controlled with independent QCMs. These films were covered with 50 nm of intrinsic host material in order to provide a quick encapsulation from residual gases in the nitrogen glovebox used for characterization and encapsulation. This cover layer was found to increase the total lateral current between electrodes by less than 10%. Lateral conductivity was determined from cur-rent-voltage characteristics (−10 V to 10 V) using a source-measure unit, either directly in the glovebox or in air after encapsulation of the samples with cavity glasses and get-ter.

### Thermal Properties:

| | DAI-10 | | DAI-2 | DAI-4 |
|---|---|---|---|---|
| T_subl | 300° | C. | 140° C. | 180° C. |
| T_evap | 315° | C. | 135° C. | 170° C. |
| (0.3 Å/s, | | | | |
| <5E−7 mbar, | | | | |
| MTC) | | | | |
| T_decomp | >400° | C. | 230° C. | 240° C. |
| (DSC) | | | | |

### Conductivities:

| | | Dopant | Conductivity |
|---|---|---|---|
| | | concentration | doped film |
| ETM | n-Dopant | (wt %) | (S/cm) |
| C60 | None | — | 6E−5 |
| | W₂(hpp)₄ | 10 | 2 |
| | DAI-2 | 10 | 20 |
| | DAI-4 | 10 | 30 |
| Bis-HFl-NTCDI | None | — | 4E−7 |
| | W₂(hpp)₄ | 5 | 4E−5 |
| | DAI-2 | 5 | 4E−4 |
| | DAI-2 | 10 | 7E−4 |
| | DAI-4 | 10 | 2E−3 |
| DAI-10 | None | — | 1E−7 |
| | W₂(hpp)₄ | 2 | 3E−5 |
| | W₂(hpp)₄ | 10 | 3E−4 |
| | DAI-4 | 2 | 7E−5 |
| | DAI-4 | 10 | 3E−4 |

C60 [CAS 99685-96-8] is a fullerene compound and widely used as electron transport material in organic solar cell application. It was purchased from LUMTEC Corp. Taiwan.

Bis-HFI-NTCDI [CAS 1397188-84-9] means 2,7-Di(9H-fluoren-2-yl)benzo[lmn][3,8]-phenanthroline-1,3,6,8(2H,7H)-tetraone and is commercially available at LUMTEC Corp. Taiwan.

W₂(hpp)₄ is a strong electron donor compound and was synthesizes according to Cot-ton, F. Albert; Donahue, James P.; Lichtenberger, Dennis L.; Murillo, Carlos A.; Villagrán, Dino (2005). “Expeditious Access to the Most Easily Ionized Closed-Shell Molecule, W₂(hpp)₄”. J. Am. Chem. Soc. 127 (31), 10808-10809.

### Sample Preparation and Conductivity Measurement DAI-13:

A glass substrate with photolithographically patterned ITO electrodes (channel length 40-160 μm) was provided. Organic layers were produced by thermal evaporation at room temperature under ultrahigh vacuum conditions (base pressure <5×10⁻⁷ mbar) by controlling the evaporation rates with quartz crystal microbalances (QCMs). 30 nm thick doped layers were processed by co-evaporation of dopant and a hole-transport material (HTM). To obtain a specific doping ratio, the individual deposition rates were controlled with independent QCMs. Lateral conductivity was determined in-situ from current-voltage characteristics (−10 V to 10 V) using a source-measure unit. A film of Spiro-TTB doped with 10 wt % of DAI-13 was found to have a conductivity of 2E-6 S/cm, far above the conductivity of undoped Spiro-TTB of 1E-8 S/cm.

In Table 1 are shown the HOMO and LUMO levels for inventive compounds Q1 to Q28 both calculated and determined by cyclic voltammetry measurements. LUMO levels were calculated with the program package GAUSSIAN 16 (340 Quinnipiac St Bldg 40. Wallingford, CT 06492 USA) by applying the hybrid functional B3LYP with a 6-311G** basis set in solution (solvent ACN or if applicable identical to CV solvent). CV values were measured with 0.1M NBu4PF6 as electrolyte and 0.2 Vs−1 scan rate.

TABLE 1
Calculated and measured HOMO and LUMO levels of compounds Q1 to Q35.

| | | | HOMO, |
|---|---|---|---|
| | | | LUMO |
| | | HOMO, | [eV] |
| | | LUMO | measured, |
| | | [eV] | solvent |
| Com- | | calculated, | n.d = not |
| pound | Structure | solvent | determined |
| Q1 | 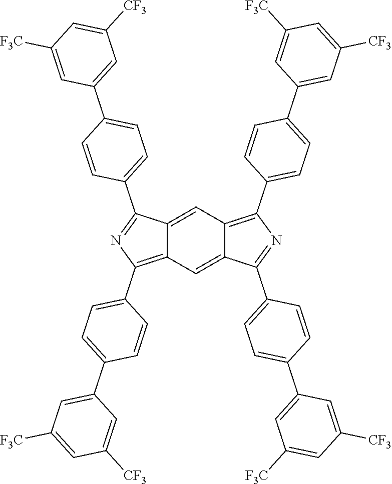 [SMILES: FC(F)(F)c1cc(-c2ccc(C3=NC(c4ccc(-c5cc(C(F)(F)F)cc(C(F)(F)F)c5)cc4)=c4cc5c(cc43)=C(c3ccc(-c4cc(C(F)(F)F)cc(C(F)(F)F)c4)cc3)N=C5c3ccc(-c4cc(C(F)(F)F)cc(C(F)(F)F)c4)cc3)cc2)cc(C(F)(F)F)c1] | −5.51, −3.90, THF | n.d., −3.97, THF |
| Q2 | 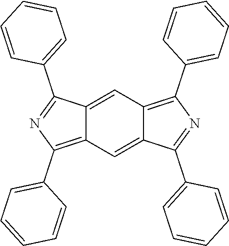 [SMILES: c1ccc(C2=NC(c3ccccc3)=c3cc4c(cc32)=C(c2ccccc2)N=C4c2ccccc2)cc1] | −5.40, −3.69, DCM | −5.50, −3.92, DCM |
| Q3 | 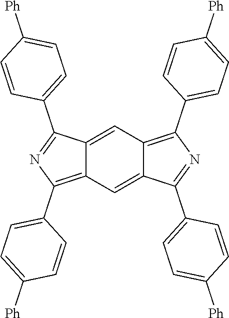 [SMILES: c1ccc(-c2ccc(C3=NC(c4ccc(-c5ccccc5)cc4)=c4cc5c(cc43)=C(c3ccc(-c4ccccc4)cc3)N=C5c3ccc(-c4ccccc4)cc3)cc2)cc1] | −5.27, −3.68, ACN | n.d., n.d. |
| Q4 | 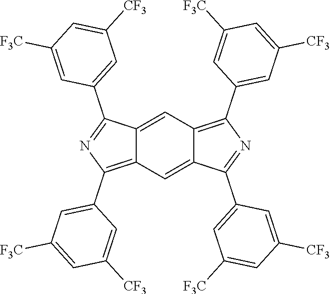 [SMILES: FC(F)(F)c1cc(C2=NC(c3cc(C(F)(F)F)cc(C(F)(F)F)c3)=c3cc4c(cc32)=C(c2cc(C(F)(F)F)cc(C(F)(F)F)c2)N=C4c2cc(C(F)(F)F)cc(C(F)(F)F)c2)cc(C(F)(F)F)c1] | −6.03, −4.31, DCM | n.d., −4.31, DCM |
| Q5 | 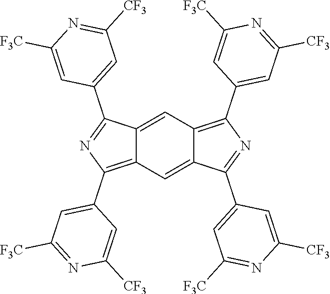 [SMILES: FC(F)(F)c1cc(C2=NC(c3cc(C(F)(F)F)nc(C(F)(F)F)c3)=c3cc4c(cc32)=C(c2cc(C(F)(F)F)nc(C(F)(F)F)c2)N=C4c2cc(C(F)(F)F)nc(C(F)(F)F)c2)cc(C(F)(F)F)n1] | −6.61, −4.84, ACN | n.d., n.d. |
| Q6 | 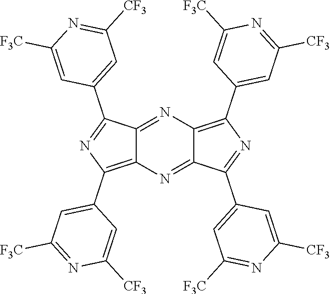 [SMILES: FC(F)(F)c1cc(C2=NC(c3cc(C(F)(F)F)nc(C(F)(F)F)c3)=c3nc4c(nc32)=C(c2cc(C(F)(F)F)nc(C(F)(F)F)c2)N=C4c2cc(C(F)(F)F)nc(C(F)(F)F)c2)cc(C(F)(F)F)n1] | −6.75, −5.38, ACN | n.d., n.d. |
| Q7 | 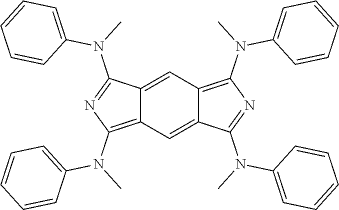 [SMILES: CN(C1=NC(N(C)c2ccccc2)=c2cc3c(cc21)=C(N(C)c1ccccc1)N=C3N(C)c1ccccc1)c1ccccc1] | −4.05, −2.00, ACN | −3.95, n.d., ACN |
| Q8 | 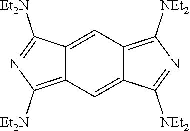 | −3.67, −1.51, ACN | −3.63, n.d., ACN |
| Q9 | 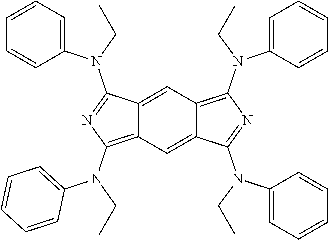 [SMILES: CCN(C1=NC(N(CC)c2ccccc2)=c2cc3c(cc21)=C(N(CC)c1ccccc1)N=C3N(CC)c1ccccc1)c1ccccc1] | −4.00, −1.82, ACN | −3.92, n.d., ACN |
| Q10 | 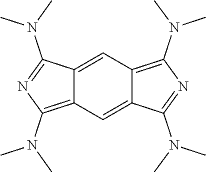 | −3.76, −1.57, ACN | −3.67, n.d., ACN |
| Q11 | 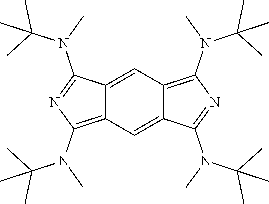 [SMILES: CN(C1=NC(N(C)C(C)(C)C)=c2cc3c(cc21)=C(N(C)C(C)(C)C)N=C3N(C)C(C)(C)C)C(C)(C)C] | −3.82, −1.89, ACN | −3.76, n.d., ACN |
| Q12 | 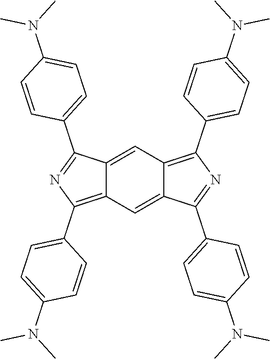 | −4.42 −3.00, ACN | n.d., n.d. |
| Q13 | 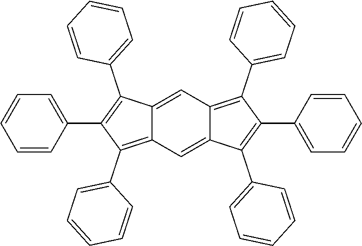 [SMILES: c1ccc(C2=C(c3ccccc3)c3cc4c(cc3=C2c2ccccc2)C(c2ccccc2)=C(c2ccccc2)C=4c2ccccc2)cc1] | −5.33, −3.42, ACN | n.d., n.d. |
| Q14 | 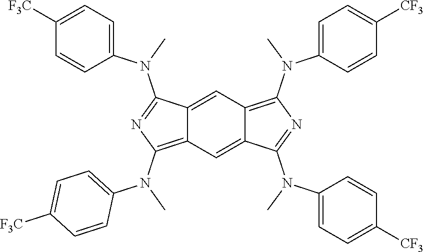 [SMILES: CN(C1=NC(N(C)c2ccc(C(F)(F)F)cc2)=c2cc3c(cc21)=C(N(C)c1ccc(C(F)(F)F)cc1)N=C3N(C)c1ccc(C(F)(F)F)cc1)c1ccc(C(F)(F)F)cc1] | −4.23, −2.32, ACN | n.d., n.d. |
| Q15 | 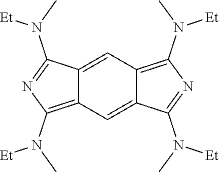 [SMILES: CCN(C)C1=NC(N(C)CC)=c2cc3c(cc21)=C(N(C)CC)N=C3N(C)CC] | −3.69, −1.48, ACN | n.d., n.d. |
| Q16 | 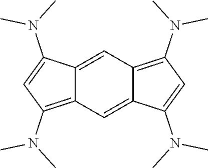 | −3.54, −1.39, ACN | n.d., n.d. |
| Q17 | 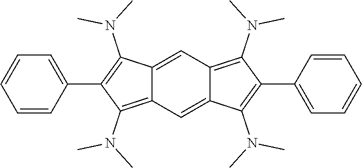 [SMILES: CN(C)C1=C(c2ccccc2)C(N(C)C)=c2cc3c(cc21)=C(N(C)C)C(c1ccccc1)=C3N(C)C] | −4.25, −2.14, ACN | n.d., n.d. |
| Q18 | 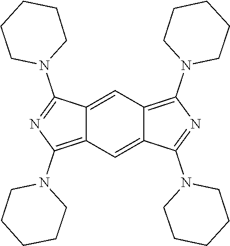 [SMILES: c1c2c(cc3c1=C(N1CCCCC1)N=C3N1CCCCC1)=C(N1CCCCC1)N=C2N1CCCCC1] | −3.88, −1.89, ACN | n.d., n.d. |
| Q20 | 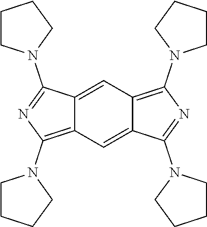 [SMILES: c1c2c(cc3c1=C(N1CCCC1)N=C3N1CCCC1)=C(N1CCCC1)N=C2N1CCCC1] | −3.62, −1.46, ACN | −3.60, n.d., ACN |
| Q21 | 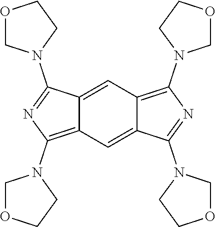 [SMILES: c1c2c(cc3c1=C(N1CCOC1)N=C3N1CCOC1)=C(N1CCOC1)N=C2N1CCOC1] | −3.89, −1.72, ACN | n.d., n.d. |
| Q22 | 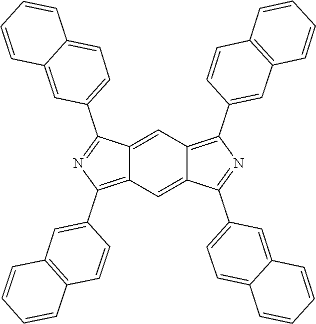 [SMILES: c1ccc2cc(C3=NC(c4ccc5ccccc5c4)=c4cc5c(cc43)=C(c3ccc4ccccc4c3)N=C5c3ccc4ccccc4c3)ccc2c1] | −5.09, −3.50, ACN | n.d., n.d. |
| Q23 | 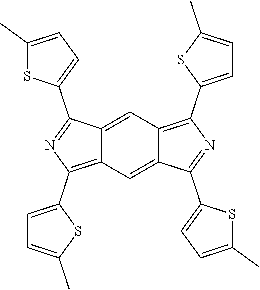 | −4.70, −3.34, ACN | n.d., n.d. |
| Q24 | 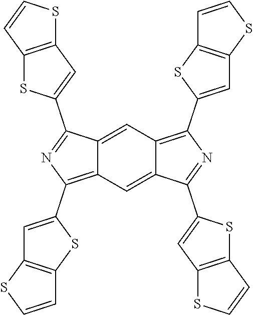 [SMILES: c1cc2sc(C3=NC(c4cc5sccc5s4)=c4cc5c(cc43)=C(c3cc4sccc4s3)N=C5c3cc4sccc4s3)cc2s1] | −4.87; −3.60 | n.d., n.d. |
| Q26 | 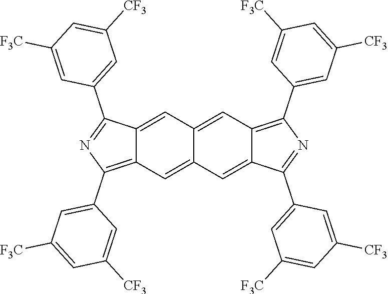 [SMILES: FC(F)(F)c1cc(C2=NC(c3cc(C(F)(F)F)cc(C(F)(F)F)c3)=c3cc4cc5c(cc4cc32)=C(c2cc(C(F)(F)F)cc(C(F)(F)F)c2)N=C5c2cc(C(F)(F)F)cc(C(F)(F)F)c2)cc(C(F)(F)F)c1] | −6.01, −4.67, ACN | n.d., n.d. |
| Q27 | 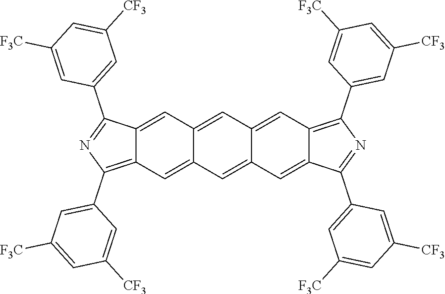 [SMILES: FC(F)(F)c1cc(C2=NC(c3cc(C(F)(F)F)cc(C(F)(F)F)c3)=c3cc4cc5cc6c(cc5cc4cc32)=C(c2cc(C(F)(F)F)cc(C(F)(F)F)c2)N=C6c2cc(C(F)(F)F)cc(C(F)(F)F)c2)cc(C(F)(F)F)c1] | −5.71, −4.63, ACN | n.d., n.d. |
| Q28 | 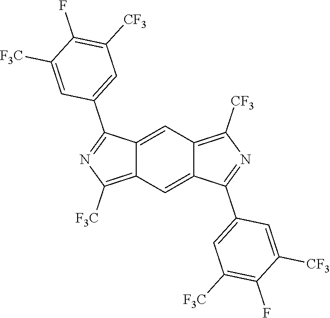 [SMILES: Fc1c(C(F)(F)F)cc(C2=NC(C(F)(F)F)=c3cc4c(cc32)=C(C(F)(F)F)N=C4c2cc(C(F)(F)F)c(F)c(C(F)(F)F)c2)cc1C(F)(F)F] | −6.82, −4.99, ACN | n.d., n.d. |
| Q29 | 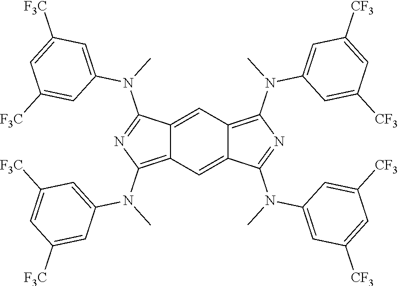 [SMILES: CN(C1=NC(N(C)c2cc(C(F)(F)F)cc(C(F)(F)F)c2)=c2cc3c(cc21)=C(N(C)c1cc(C(F)(F)F)cc(C(F)(F)F)c1)N=C3N(C)c1cc(C(F)(F)F)cc(C(F)(F)F)c1)c1cc(C(F)(F)F)cc(C(F)(F)F)c1] | −3.16, −5.07, ACN | n.d., n.d. |
| Q30 | 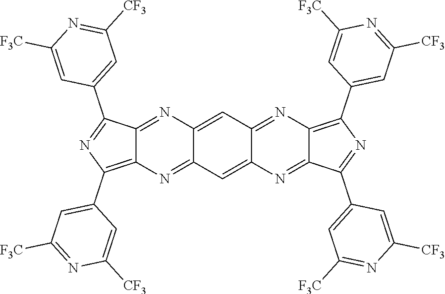 [SMILES: FC(F)(F)c1cc(C2=NC(c3cc(C(F)(F)F)nc(C(F)(F)F)c3)=c3nc4cc5nc6c(nc5cc4nc32)=C(c2cc(C(F)(F)F)nc(C(F)(F)F)c2)N=C6c2cc(C(F)(F)F)nc(C(F)(F)F)c2)cc(C(F)(F)F)n1] | −5.27, −6.09, ACN | n.d., n.d. |
| Q31 | 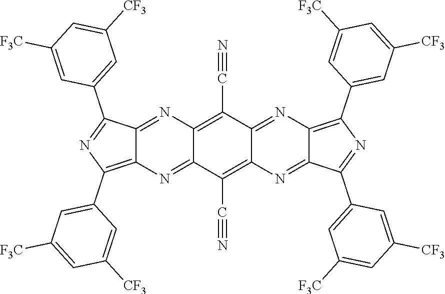 [SMILES: N#Cc1c2nc3c(nc2c(C#N)c2nc4c(nc12)=C(c1cc(C(F)(F)F)cc(C(F)(F)F)c1)N=C4c1cc(C(F)(F)F)cc(C(F)(F)F)c1)=C(c1cc(C(F)(F)F)cc(C(F)(F)F)c1)N=C3c1cc(C(F)(F)F)cc(C(F)(F)F)c1] | −5.15, −5.81, ACN | n.d., n.d. |
| Q32 | 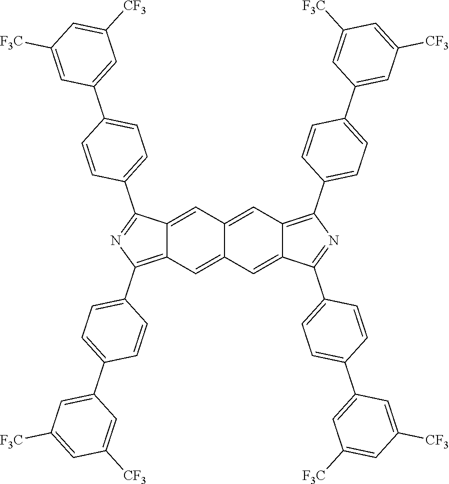 [SMILES: FC(F)(F)c1cc(-c2ccc(C3=NC(c4ccc(-c5cc(C(F)(F)F)cc(C(F)(F)F)c5)cc4)=c4cc5cc6c(cc5cc43)=C(c3ccc(-c4cc(C(F)(F)F)cc(C(F)(F)F)c4)cc3)N=C6c3ccc(-c4cc(C(F)(F)F)cc(C(F)(F)F)c4)cc3)cc2)cc(C(F)(F)F)c1] | −3.91, −5.18, ACN | n.d., n.d. |
| Q33 | 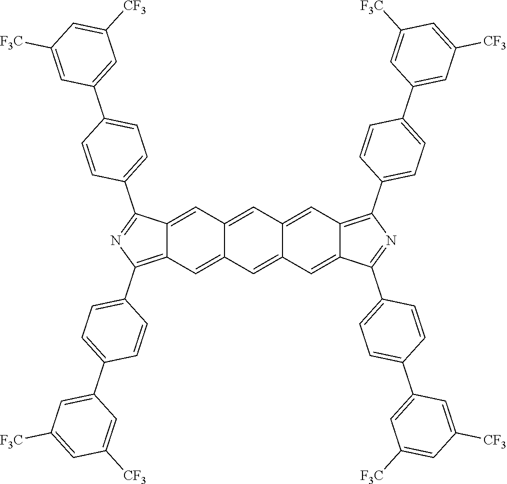 [SMILES: FC(F)(F)c1cc(-c2ccc(C3=NC(c4ccc(-c5cc(C(F)(F)F)cc(C(F)(F)F)c5)cc4)=c4cc5cc6cc7c(cc6cc5cc43)=C(c3ccc(-c4cc(C(F)(F)F)cc(C(F)(F)F)c4)cc3)N=C7c3ccc(-c4cc(C(F)(F)F)cc(C(F)(F)F)c4)cc3)cc2)cc(C(F)(F)F)c1] | −3.91, −4.93, ACN | n.d., n.d. |
| Q34 | 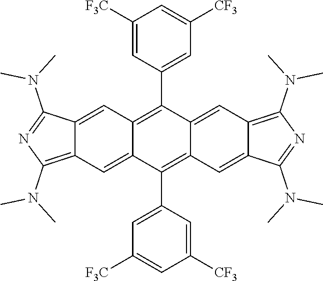 | −2.21, −3.43, ACN | n.d., n.d. |
| Q35 | 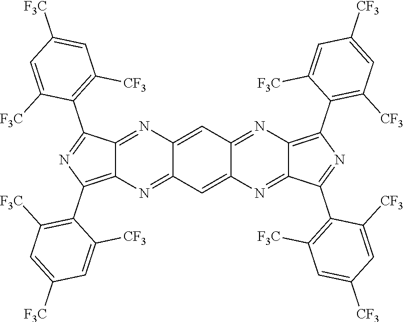 [SMILES: FC(F)(F)c1cc(C(F)(F)F)c(C2=NC(c3c(C(F)(F)F)cc(C(F)(F)F)cc3C(F)(F)F)=c3nc4cc5nc6c(nc5cc4nc32)=C(c2c(C(F)(F)F)cc(C(F)(F)F)cc2C(F)(F)F)N=C6c2c(C(F)(F)F)cc(C(F)(F)F)cc2C(F)(F)F)c(C(F)(F)F)c1] | −5.04 −6.25, ACN | n.d., n.d. |

1-13. (canceled)

14. An electronic component, comprising at least one compound of the formula (I): 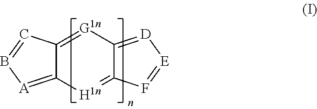
or their radical anions, radical anionic salts, radical cations, radical cationic salts, dianions, dianionic salts, dications, dicationic salts or their charge transfer complexes with donors or acceptors,
in which
n is 1,
A is C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—R¹ⁿ,
each H¹ⁿ is nitrogen or C—R²ⁿ,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹ and R²¹ are independently selected from hydrogen,
halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom,
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, Anisyl, Mesityl,
or R^{E} and R^{F} bound to the same or to different nitrogen atoms form a C₃-C₁₀ heterocycloalkyl,
with the proviso that 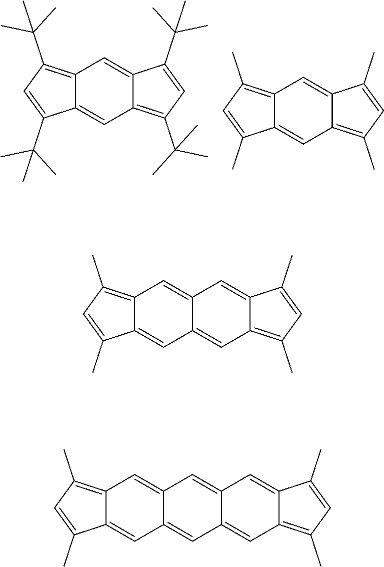
are excluded.

15. The electronic component according to claim 14, wherein in compounds of formula (I) each of R¹, R², R⁴, and R⁶ are independently selected from trifluoromethyl, pentafluoroethyl, NR^{X}R^{Y}, 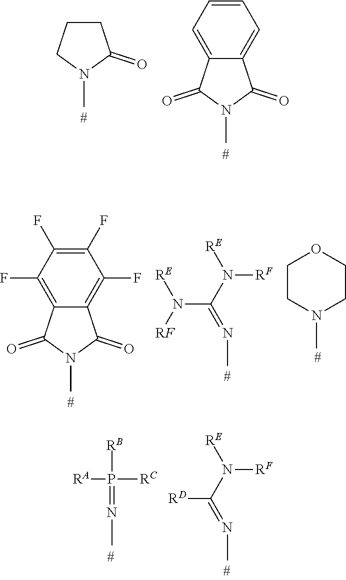
where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted is substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein in compounds of formula (I) each of R³ and R⁵ are independently selected from hydrogen, trifluoromethyl, pentafluoroethyl, NR^{X}R^{Y}, 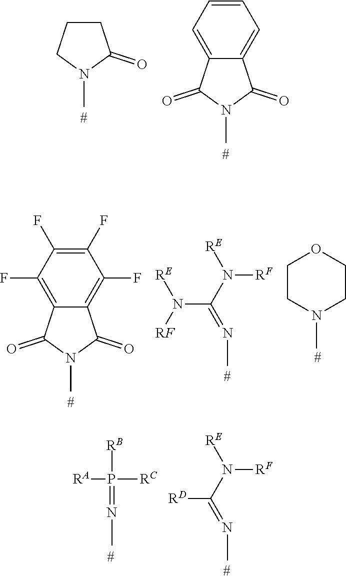
where # denotes the bond to the remaining molecule of formula (I),
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R^{A}, R^{B}, R^{C}, R^{D}, R^{E} and R^{F} are independently from each other selected from C₁-C₁₀-alkyl, phenyl, tolyl, anisyl, mesityl, R^{E} and R^{F} bound to the same or to different nitrogen atoms form a C₃-C₁₀ heterocycloalkyl,
C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino.

16. The electronic component according to claim 14, wherein in compounds of the formula (I) wherein R¹¹ and R²¹ are independently selected from hydrogen, trifluoromethyl, pentafluoroethyl, NR^{X}R^{Y}, 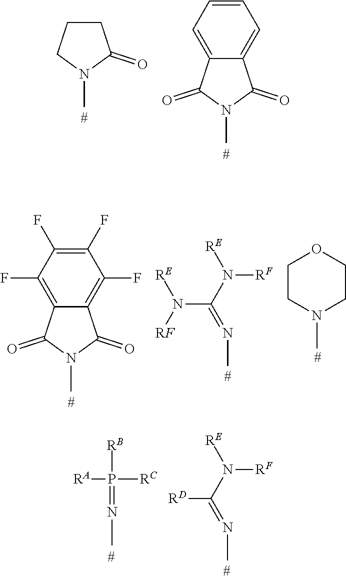
where # denotes the bond to the remaining molecule of formula (I),
wherein R^{A}, R^{B}, R^{C}, R^{D}, R^{E} and R^{F} are independently from each other selected from C₁-C₁₀-alkyl, phenyl, tolyl, anisyl, mesityl, or R^{E} and R^{F} bound to the same or to different nitrogen atoms form a C₃-C₁₀ heterocycloalkyl, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂,
wherein R^{X} and R^{Y} independently from each other selected from hydrogen, C₁-C₁₅-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino.

17. The electronic component according to claim 14, wherein in compounds of the formula (I) wherein R¹¹ and R²¹ are hydrogen.

18. The electronic component according to claim 14, wherein the compounds of formula (I) are selected from a compound of the following formulae: 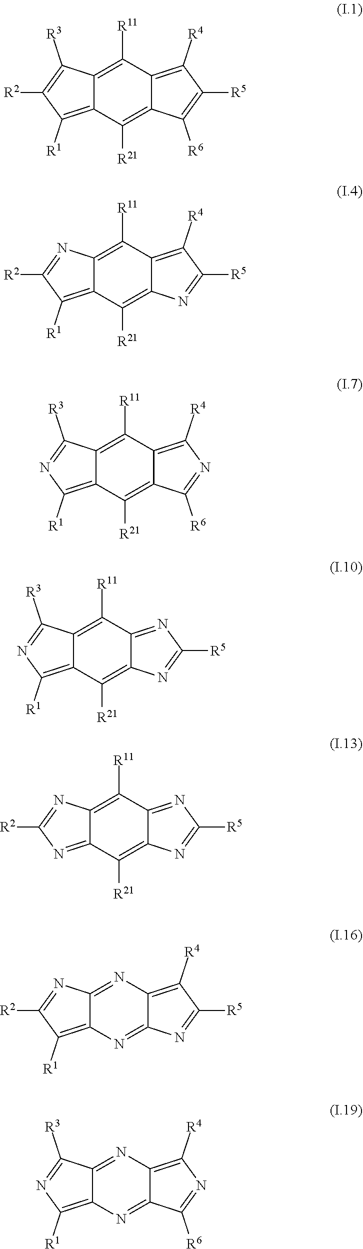 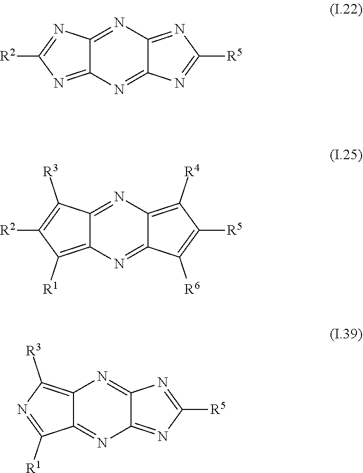
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹ and R²¹ are independently selected from hydrogen,
halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is unsubstituted or substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom,
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, anisyl, mesityl,
or R^{E} and R^{F} bound to the same or to different nitrogen atoms form a C₃-C₁₀ heterocycloalkyl.

19. The electronic component according to claim 14 in the form of an organic light-emitting diode, a photovoltaic cell, an organic solar cell, an organic diode, an organic sensor, an organic field effect transistor or an organic battery.

20. A compound of the formula (I), 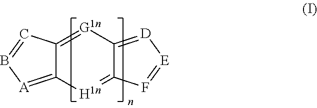
or their radical anions, radical anionic salts, radical cations, radical cationic salts, dianions, dianionic salts, dications, dicationic salts or their charge transfer complexes with donors or acceptors,
in which
n is 1,
A is C—R¹, B is nitrogen or C—R², C is nitrogen or C—R³, D is nitrogen or C—R⁴, E is nitrogen or C—R⁵ and F is nitrogen or C—R⁶,
each G¹ⁿ is nitrogen or C—R¹ⁿ,
each H¹ⁿ is nitrogen or C—R²ⁿ,
wherein 0, 1, 2, 3 or 4 non-adjacent groups A, B, C, D, E or F are a nitrogen atom,
wherein R¹ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R² is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R³ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁴ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁵ is selected from hydrogen, halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R⁶ is selected from halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein R¹¹ and R²¹ are independently selected from hydrogen,
halogen, cyano, perfluoro (C₁-C₅-alkyl), NR^{X}R^{Y}, C₁-C₁₅-alkoxy, C₃-C₁₀-cycloalkyloxy, C₆-C₁₄-aryloxy, C₁-C₁₅-alkyl, C₃-C₁₀-cycloalkyl, C₃-C₁₀-heterocycloalkyl comprising 1, 2 or 3 identical or different heteroatoms or heteroatom-containing group as ring members selected from N, NR⁷, O, S, SO and SO₂, C₆-C₁₄-aryl and heteroaryl having 4 to 13 carbon atoms, wherein hetaryl has 1, 2, 3 or 4 identical or different heteroatoms or heteroatom-containing groups as ring members, selected from N, NR⁷, O, S, SO and SO₂, N═P(R^{A}R^{B}R^{C}), N═C(R^{D})NR^{E}R^{F}), N—C(NR^{E}R^{F})NR^{E}R^{F},
wherein each C₆-C₁₄-aryl and heteroaryl is unsubstituted or substituted with either one or more than one electron acceptor group, which is selected from cyano, nitro, fluoro, perfluoro (C₁-C₅-alkyl), OCF₃, SF₅, SO₂CF₃, chloro, bromo and C₆-C₁₄-aryl, which is substituted by 1, 2, 3, or 4 electron acceptor group, which is selected from cyano, nitro, halogen, perfluoro (C₁-C₅-alkyl), OCF₃, SF₅, SO₂CF₃, or with either one or more than one electron donor group, which are selected from C₁-C₃₀-alkyl, C₃-C₁₀-cycloalkyl, C₁-C₁₅-alkoxy, C₆-C₁₄-aryloxy, di(C₆-C₁₄-aryl)amino, di(C₁-C₁₅-alkyl)amino and di(C₃-C₁₀-cycloalkyl)amino,
wherein heterocycloalkyl is unsubstituted or substituted with 1, 2, 3, 4 or 5 radicals R^{G} which is selected from halogen, cyano, OCF₃, SF₅, SO₂CF₃, ═O, or two adjacent R^{G} together with the carbon atoms, which they are attached to form a C₆-C₁₀ aryl, which is unsubstituted or substituted with 1, 2, 3 or 4 identical or different halogen, and wherein the heterocycloalkyl is connected with the remaining molecule via a heteroatom.
wherein R^{X} and R^{Y} independently from each other selected from hydrogen, C₁-C₁₅-alkyl, C₁-C₁₀-alkyl and C₆-C₁₄-aryl, wherein alky is unsubstituted or substituted by 1, 2, 3, 4 or 5 identical or different radicals selected from cyano and halogen, and cycloalyl and aryl are unsubstituted or substituted by 1, 2, 3, 4 or 5 identical or different radicals selected from cyano, halogen, C₁-C₄ alkyl and C₁-C₄ haloalkyl,
wherein R⁷ is selected from hydrogen, C₁-C₆-alkyl, C₁-C₆-haloalkyl or C₆-C₁₄-aryl, wherein aryl is unsubstituted or substituted by 1, 2, 3, 4 or 5 identical or different radicals CN, halogen, C₁-C₄-alkyl or C₁-C₄-haloalkyl,
wherein R^{A} is selected from C₁-C₁₀-alkyl, phenyl, tolyl, anisyl, mesityl,
wherein R^{B} is selected from C₁-C₁₀-alkyl, phenyl, tolyl, anisyl, mesityl,
wherein R^{C} is selected from C₁-C₁₀-alkyl, phenyl, tolyl, anisyl, mesityl,
wherein R^{D} is selected from C₁-C₁₀-alkyl, phenyl, tolyl, anisyl, mesityl,
wherein R^{E} is selected from C₁-C₁₀-alkyl, phenyl, tolyl, anisyl, mesityl,
wherein R^{F} is selected from C₁-C₁₀-alkyl, phenyl, tolyl, anisyl, mesityl,
or R^{E} and R^{F} bound to the same or to different nitrogen atoms form a C₃-C₁₀ heterocycloalkyl,
with the proviso that 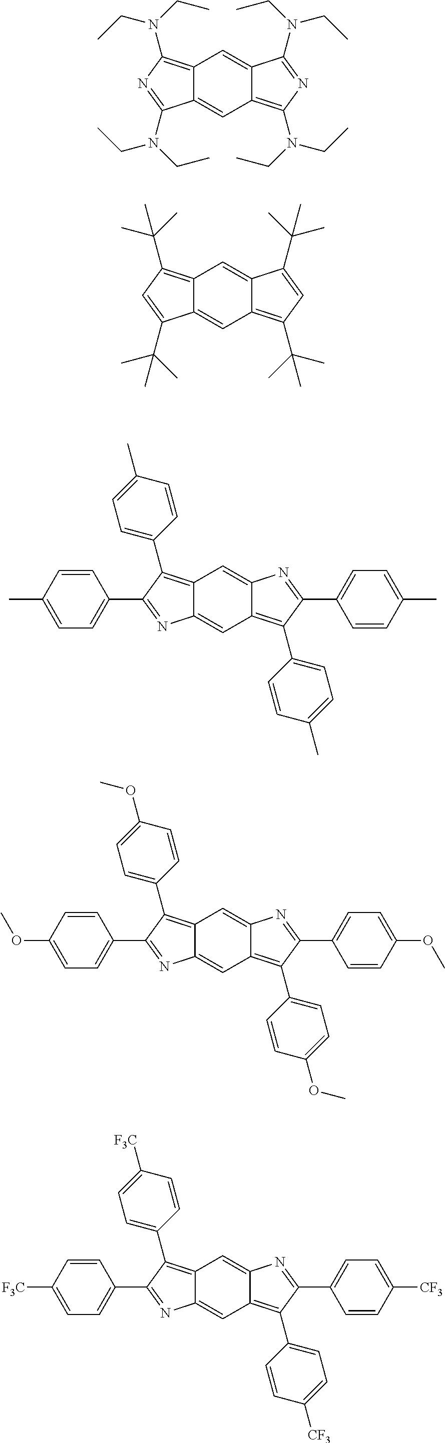 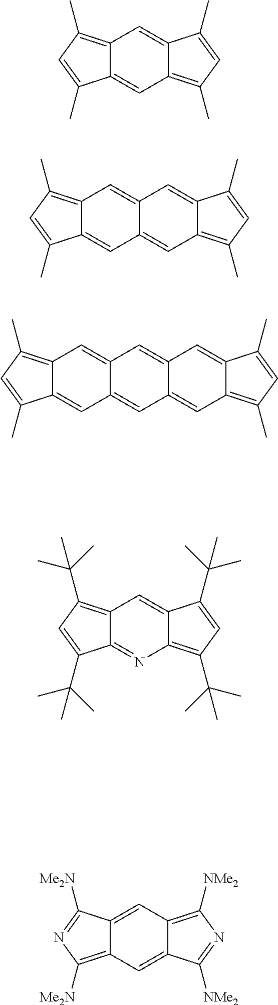
are excluded.

21. An organic semiconductive material containing at least one organic matrix compound and at least one doping agent, characterized in that the doping agent is one or more compounds of formula (I) according to claim 14.

22. An organic semiconductive material containing at least one organic matrix compound and at least one doping agent, characterized in that the matrix compound is one or more compounds of formula (I) according to claim 14.

23. An organic semiconductive material containing at least one organic matrix compound and at least one or more light-emitting materials, characterized in that the matrix compound is one or more compounds of formula (I) according to claim 14.

24. An organic doping agent for the doping of an organic semiconductive matrix material, as matrix layers, as transport layer, as blocker layer, as absorbing layer, as charge injection layer, as organic semiconductor itself, organic semiconductive matrix material, as electron transport or as hole transport layer or as emitter matrix layer, comprising at least one compound of formula (I) as defined in claim 14.

25. An electroluminescent arrangement comprising an upper electrode and a lower electrode, wherein at least one of said upper electrode or said lower electrode is transparent, an electroluminescent layer, and optionally an auxiliary layer, wherein the electroluminescent arrangement comprises at least one compound of formula (I) as defined in claim 14.

26. An absorber material comprising at least one compound of formula (I) as defined in claim 14.
